(19) United States
(12) Patent Application Publication
(10) Pub. No.: US 2026/0253623 A1
(43) Pub. Date: Aug. 27, 2026

(54) MEMORY CIRCUIT AND METHOD OF FORMING THE SAME

(71) Applicant: TAIWAN SEMICONDUCTOR MANUFACTURING COMPANY, LTD., Hsinchu (TW)

(72) Inventor: Meng-Sheng CHANG, Hsinchu (TW)

(21) Appl. No.: 19/307,680

(22) Filed: Aug. 22, 2025

Related U.S. Application Data
(60) Provisional application No. 63/764,447, filed on Feb. 27, 2025.

(51) Int. Cl. G11C 5/06; G11C 17/16; H10B 20/25; H10B 99/00

(52) U.S. Cl. CPC G11C 5/063; G11C 17/165; H10B 20/25; H10B 99/14

(57) ABSTRACT

A memory circuit includes a first memory cell. The first memory cell includes a first and a second storage element, a first and a second selection transistor and a first word line transistor. The first storage element is on a back-side of a substrate opposite from a front-side of the substrate. The second storage element is on the back-side of the substrate, and is separated from the first storage element in a first direction. The first selection transistor is coupled to the first storage element. The second selection transistor is coupled to the second storage element. The first word line transistor is coupled to the first or second selection transistor, and is on the front-side of the substrate. One of the first or second storage element is programmed during a programming operation, and another of the first or second storage element fails to be programmed during the programming operation.

### PRIORITY CLAIM

This application claims the benefit of U.S. Provisional Application No. 63/764,447, filed Feb. 27, 2025, which is incorporated herein by reference in its entirety.

### BACKGROUND

Manufacturing processes utilize fuses in an interconnect structure to selectively alter electrical connections within a semiconductor device. By blowing selected fuses within the semiconductor device, a function of the semiconductor device is tailored to a desired functionality. Utilizing fuses to adjust the functionality of the semiconductor device permits a manufacturer of the semiconductor device to form a same structure for a wide variety of products and then selectively blow the fuses in order to impart the desired functionality to the semiconductor device. This helps to increase production efficiency.

In some instances, a competitor may seek to reverse engineer a manufactured product by analyzing the functionality of the semiconductor device. During the attempted reverse engineering, a grinding or planarization process is performed on the semiconductor device to expose a conductive level having the fuses and identifying which of the fuses remain intact and which of the fuses are blown. Identifying the state of the fuses within the semiconductor device assists in reverse engineering of the semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a memory device, in accordance with some embodiments.

FIG. 2 is a block diagram of a memory cell array, in accordance with some embodiments.

FIG. 3 is a schematic diagram of a memory cell array, in accordance with some embodiments.

FIG. 4A is a cross-sectional view of a portion of a memory circuit, in accordance with some embodiments.

FIG. 4B is a top view of a portion of a memory circuit, in accordance with some embodiments.

FIG. 5 is a cross-sectional view of a memory circuit, in accordance with some embodiments.

FIG. 6A is a cross-sectional view of a portion of a memory circuit, in accordance with some embodiments.

FIG. 6B is a cross-sectional view of a portion of memory circuit, in accordance with some embodiments.

FIG. 6C is a top view of a portion of memory circuit, in accordance with some embodiments.

FIG. 6D is a perspective view of a portion of memory circuit, in accordance with some embodiments.

FIG. 7A is a cross-sectional view of a portion of a memory circuit, in accordance with some embodiments.

FIG. 7B is a cross-sectional view of a portion of memory circuit, in accordance with some embodiments.

FIG. 7C is a top view of a portion of memory circuit, in accordance with some embodiments.

FIG. 7D is a perspective view of a portion of memory circuit, in accordance with some embodiments.

FIG. 8 is a diagram of a memory cell array, in accordance with some embodiments.

FIG. 9 is a diagram of a memory cell array, in accordance with some embodiments.

FIG. 10A is a schematic diagram of a memory cell, in accordance with some embodiments.

FIG. 10B is a diagram of memory cell, in accordance with some embodiments.

FIG. 11 is a cross-sectional view of a memory circuit, in accordance with some embodiments.

FIG. 12A is a schematic diagram of a memory cell, in accordance with some embodiments.

FIG. 12B is a diagram of memory cell, in accordance with some embodiments.

FIG. 13 is a schematic diagram of a memory cell 1300, in accordance with some embodiments.

FIG. 14 is a schematic diagram of a memory cell, in accordance with some embodiments.

FIG. 15 is a schematic diagram of a memory cell, in accordance with some embodiments.

FIG. 16 is a schematic diagram of a memory cell, in accordance with some embodiments.

FIG. 17 is a cross-sectional view of a memory circuit, in accordance with some embodiments.

FIG. 18A is a cross-sectional view of a portion of a memory circuit, in accordance with some embodiments.

FIG. 18B is a cross-sectional view of a portion of memory circuit, in accordance with some embodiments.

FIG. 18C is a top view of a portion of memory circuit, in accordance with some embodiments.

FIG. 19 is a schematic diagram of a memory cell array, in accordance with some embodiments.

FIG. 20 is a cross-sectional view of a memory cell device, in accordance with some embodiments.

FIGS. 21A-21C are corresponding functional flow charts of a corresponding method of manufacturing an IC device, in accordance with some embodiments.

FIG. 22 is a functional flow chart of a method of a method of operating an IC device, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, a memory circuit includes a first memory cell.

In some embodiments, the first memory cell includes a first storage element. In some embodiments, the first storage element is on a back-side of a substrate opposite from a front-side of the substrate.

In some embodiments, the first memory cell further includes a second storage element. In some embodiments, the second storage element is on the back-side of the substrate. In some embodiments, the second storage element is separated from the first storage element in a first direction.

In some embodiments, the first memory cell further includes a first selection transistor coupled to the first storage element.

In some embodiments, the first memory cell further includes a second selection transistor coupled to the second storage element.

In some embodiments, the first memory cell further includes a first word line transistor. In some embodiments, the first word line transistor is coupled to at least the first selection transistor or the second selection transistor. In some embodiments, the first word line transistor is on the front-side of the substrate.

In some embodiments, one of the first storage element or the second storage element is programmed during a programming operation, and another of the first storage element or the second storage element fails to be programmed during the programming operation.

In some embodiments, by programming one of the first storage element or the second storage element in the first memory cell, the memory circuit increases the difficulty of decrypting codes associated with the first storage element and the second storage element in the first memory cell, thereby resulting in enhanced security of the locations of the first or second storage element in the first memory cell and corresponding codes associated with each storage element/bit cell compared to other approaches.

In some embodiments, by enhancing the security of the locations of the first or second storage element in the first memory cell, reverse engineering of the memory circuit becomes more difficult and increases the amount of time and money utilized to identify which of the storage elements are not programmed in the memory circuit resulting in enhanced security in physically unclonable function (PUF) applications.

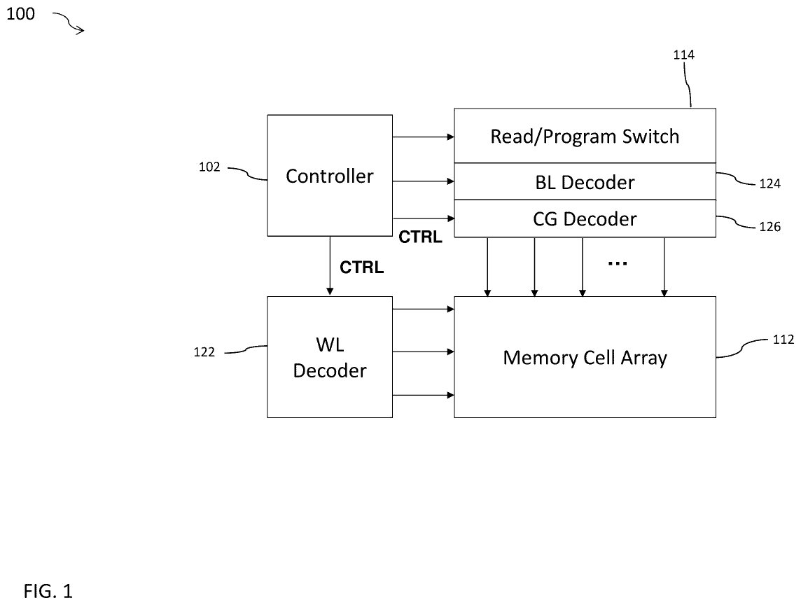

FIG. 1 is a block diagram of a memory device 100, in accordance with some embodiments. A memory device is a type of integrated circuit (IC) device. In at least one embodiment, a memory device is an individual IC device. In some embodiments, a memory device is included as a part of a larger IC device which comprises circuitry other than the memory device for other functionalities.

The memory device 100 comprises a memory controller 102 (hereinafter referred to as “controller 102”), a memory cell array 112, a read/program switch 114 (hereinafter referred to as “switch 114”), a word line (WL) driver 122, a bit line (BL) driver 124, a cascode gate (CG) driver 126.

In some embodiments, one or more elements of the memory device 100 are included in a memory macro. A macro has a reusable configuration and is usable in various types or designs of IC devices. In some embodiments, the macro is understood in the context of an analogy to the architectural hierarchy of modular programming in which subroutines/procedures are called by a main program (or by other subroutines) to carry out a given computational function. In this context, an IC device uses the macro to perform one or more given functions. Accordingly, in this context and in terms of architectural hierarchy, the IC device is analogous to the main program and the macro is analogous to subroutines/procedures. In some embodiments, the macro is a soft macro. In some embodiments, the macro is a hard macro. In some embodiments, the macro is a soft macro which is described digitally in register-transfer level (RTL) code. In some embodiments, synthesis, placement and routing have yet to have been performed on the macro such that the soft macro can be synthesized, placed and routed for a variety of process nodes. In some embodiments, the macro is a hard macro which is described digitally in a binary file format (e.g., Graphic Database System II (GDSII) stream format), where the binary file format represents planar geometric shapes, text labels, other information or the like of one or more layout-diagrams of the macro in hierarchical form. In some embodiments, synthesis, placement and routing have been performed on the macro such that the hard macro is specific to a particular process node.

A memory macro is a macro comprising memory cells which are addressable to permit data to be written to or read from the memory cells. In some embodiments, a memory macro further comprises circuitry configured to provide access to the memory cells and/or to perform a further function associated with the memory cells.

In some embodiments, one or more of the word line driver 122, the bit line driver 124, the cascode gate driver 126 or switch 114 are part of an input/output (IO) circuit (not labeled).

The memory cell array 112 comprises an array of memory cells MC. The memory cells MC are arranged in a plurality of columns and rows of the memory cell array 112.

The controller 102 is electrically coupled to one or more of the word line driver 122, the bit line driver 124, the cascode gate driver 126 or switch 114, and configured to control operations of the memory cells MC including, but not limited to, a read operation, a program operation, or the like.

The memory cell array 112 further comprises a plurality of word lines WL extending along the rows, a plurality of bit lines BL extending along the columns of the memory cells MC, and a plurality of cascode gates CG extending along the columns of the memory cells MC. In some embodiments, the memory cell array 112 does not include the plurality of cascode gates CG.

Other variations of memory cell array 112 are within the scope of the present disclosure. In some embodiments, the memory cell array 112 further comprises a plurality of source lines SL (not shown) extending along the columns of the memory cells MC.

Each of the memory cells MC is electrically coupled to the controller 102 by at least one of the word lines, at least one of the bit lines and at least one of the cascode gate lines. In some example operations, word lines are configured for transmitting addresses of the memory cells MC to be read from, or for transmitting addresses of the memory cells MC to be programmed to, or the like. In some embodiments, bit lines and cascode gate lines are used for transmitting data read from or programmed to the memory cells MC indicated by corresponding word lines, or the like.

In some embodiments, bit lines and/or cascode gate lines are configured for transmitting data read from the memory cells MC indicated by corresponding word lines, and bit lines and/or cascode gate lines are configured for transmitting data to be programmed to the memory cells MC indicated by corresponding word lines, or the like.

The word lines are commonly referred to herein as WL, the bit lines are commonly referred to herein as BL, and the cascode gate lines are referred to herein as CG. Various numbers of word lines, bit lines and/or cascode gate lines in the memory cell array 112 are within the scope of various embodiments.

In some embodiments, the memory cells MC are non-volatile memory (NVM). In some embodiments, the memory cells MC are one-time programmable (OTP) memory cells. In some embodiments, each OTP memory cell includes an eFuse Rfuse. Other memory types are within the scope of the present disclosure In some embodiments, each OTP memory cell includes an anti-Fuse OTP.

Other memory types of the memory cells MC include, but are not limited to, static random-access memory (SRAM), resistive RAM (RRAM), magnetoresistive RAM (MRAM), phase change RAM (PCRAM), spin transfer torque RAM (STTRAM), floating-gate metal-oxide-semiconductor field-effect transistors (FGMOS), spintronics, or the like. In one or more example embodiments described herein, the memory cells MC include SRAM memory cells.

In some embodiments, the memory cell array 112 includes memory cells that store a logic 0 or a logic 1.

In one or more example embodiments described herein, the memory cells MC are single-bit memory cells, i.e., each memory cell is configured to store a bit of data. In some embodiments, a single-bit memory cell is also referred to as a bitcell.

In one or more example embodiments described herein, the memory cells MC are multi-bit memory cells, i.e., each memory cell is configured to store more than one bit of data.

The controller 102 is configured to generate a set of control signals CTRL. In some embodiments, the set of control signal CTRL are configured to control one or more of the word line driver 122, the bit line driver 124, the cascode gate driver 126 or switch 114.

The controller 102 is coupled to one or more of the memory cells MC, the word line driver 122, the bit line driver 124, the cascode gate driver 126 or switch 114, to coordinate operations of these circuits, and/or drivers in the overall operation of the memory device 100. For example, the controller 102 is configured to generate various control signals for controlling operations of one or more of the memory cells MC, word line driver 122, bit line driver 124, cascode gate driver 126 or switch 114.

The controller 102 is configured to receive the input data from external circuitry outside the memory device 100, for example, a processor as described herein. The input data are received through one or more I/O circuits (not shown), and are forwarded by the controller 102 to the memory cell array 112.

In at least one embodiment, the controller 120 further includes one or more clock generators for providing clock signals for various components of the memory device 100, one or more input/output (I/O) circuits for data exchange with external devices, and/or one or more controllers for controlling various operations in the memory device 100.

In some embodiments, the switch 114 is configured to receive the set of control signals CTRL from the controller 102.

In some embodiments, the switch 114 includes a programming circuit configured to perform a programming operation of one or more memory cells MC of memory cell array 112.

In some embodiments, the switch 114 includes a read circuit configured to perform a read operation of one or more memory cells MC of memory cell array 112.

Switch 114 has outputs coupled to the bit lines BL/cascode gate lines CG to output data to be programmed to one or more of the memory cells MC.

Switch 114 has inputs coupled to the bit lines BL/cascode gate lines CG to receive output data read from one or more of the memory cells MC.

Examples of the switch 114 include registers, flip-flops, latches, or the like.

The word line driver 122 is configured to decode a row address of the memory cell MC selected to be accessed in a programming operation. The word line driver 122 is configured to supply a voltage to the selected word line WL corresponding to the decoded row address, and a different voltage to the other, unselected word lines WL. In some embodiments, each word line WL1, WL2, . . . , WLr of word lines WL has a corresponding input signal IN₀, IN₁, . . . , INᵣ of the input signal IN (not shown).

The word line driver 122 is coupled to the memory cell array 112 via the word lines WL. The word line driver 122 is configured to decode a row address of the memory cell MC selected to be accessed in a programming operation. The word line driver 122 is configured to supply a voltage to the selected word line WL corresponding to the decoded row address, and a different voltage to the other, unselected word lines WL. In some embodiments, each word line WL1, WL2, . . . , WLr of word lines WL has a corresponding input signal IN₀, IN₁, . . . , INᵣ of the input signal IN.

The bit line driver 124 is coupled to the memory cell array 112 via the bit lines BL. The bit line driver 124 is configured to decode a column address of the memory cell MC selected to be accessed in a programming operation. The bit line driver 124 is configured to supply a voltage to the selected write bit line WBL corresponding to the decoded column address, and a different voltage to the other, unselected bit lines BL.

The cascode gate driver 126 is coupled to the memory cell array 112 via the cascode gate lines CG. The cascode gate driver 126 is configured to decode a column address of the memory cell MC selected to be accessed in a read operation. The cascode gate driver 126 is configured to supply a voltage to the selected cascode gate line CG corresponding to the decoded column address, and a different voltage to the other, unselected cascode gate lines CG.

Other configurations or quantities of elements in memory device 100 are within the scope of the present disclosure.

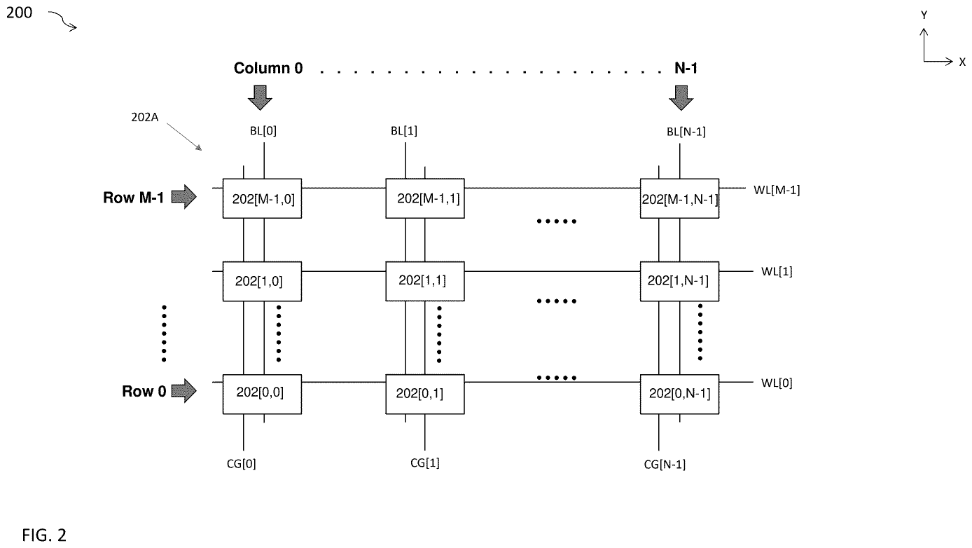

FIG. 2 is a block diagram of a memory cell array 200, in accordance with some embodiments. In some embodiments, memory cell array 200 is part of an integrated circuit.

Memory cell array 200 is an embodiment of memory cell array 112 of FIG. 1, and similar detailed description is therefore omitted.

In some embodiments, each memory cell in array of memory cells 202A is an embodiment of a corresponding memory cell MC of memory cell array 112 of FIG. 1, and similar detailed description is therefore omitted.

For ease of illustration, some of the labeled elements of one or more of FIGS. 1, 2, 3, 4A-4B, 5, 6A-6D, 7A-7D, 8, 9, 10A-10B, 11, 12A-12B, 13, 14, 15, 16, 17, 18A-18C, 19 and 20, are not labelled in one or more of 1, 2, 3, 4A-4B, 5, 6A-6D, 7A-7D, 8, 9, 10A-10B, 11, 12A-12B, 13, 14, 15, 16, 17, 18A-18C, 19 and 20. In some embodiments, memory cell array 200 includes additional elements not shown in FIG. 2.

Components that are the same or similar to those in one or more of FIGS. 1, 2, 3, 4A-4B, 5, 6A-6D, 7A-7D, 8, 9, 10A-10B, 11, 12A-12B, 13, 14, 15, 16, 17, 18A-18C, 19 and 20 (shown below) are given the same reference numbers, and detailed description thereof is thus omitted.

Memory cell array 200 comprises an array of memory cells 202[0,0], 202[0,1], . . . , 202[1,1], . . . , 202[M-1,N-1] (collectively referred to as “array of memory cells 202A”) having M rows and N columns, where N is a positive integer corresponding to the number of columns in array of memory cells 202A and M is a positive integer corresponding to the number of rows in array of memory cells 202A. The rows of cells in array of memory cells 202A are arranged in a first direction X. The columns of cells in array of memory cells 202A are arranged in a second direction Y. The second direction Y is different from the first direction X. In some embodiments, the second direction Y is perpendicular to the first direction X. Each memory cell 202[0,0], 202[0,1], . . . , 202[1,1], . . . , 202[M-1,N-1] in array of memory cells 202A is configured to store a corresponding bit of data.

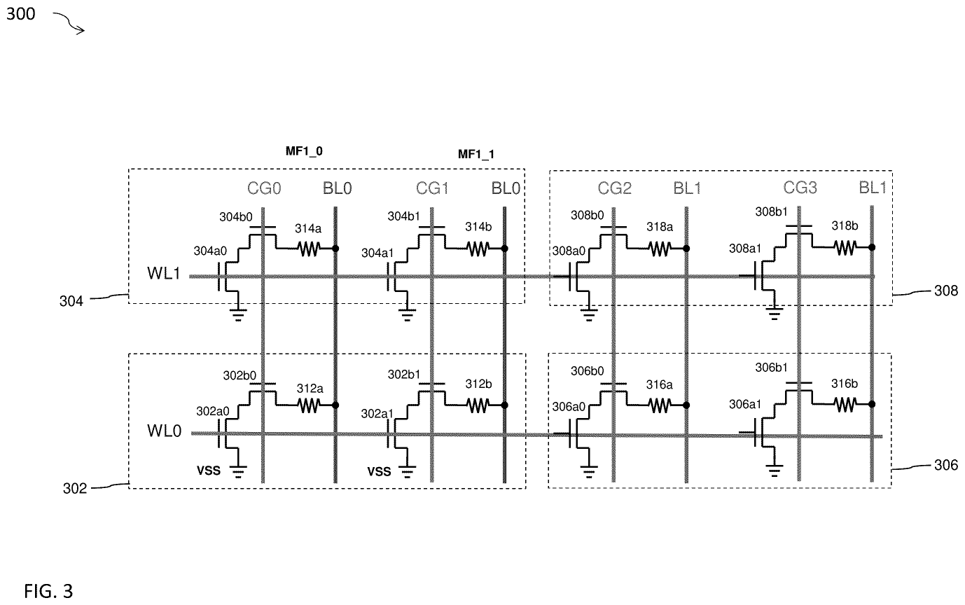

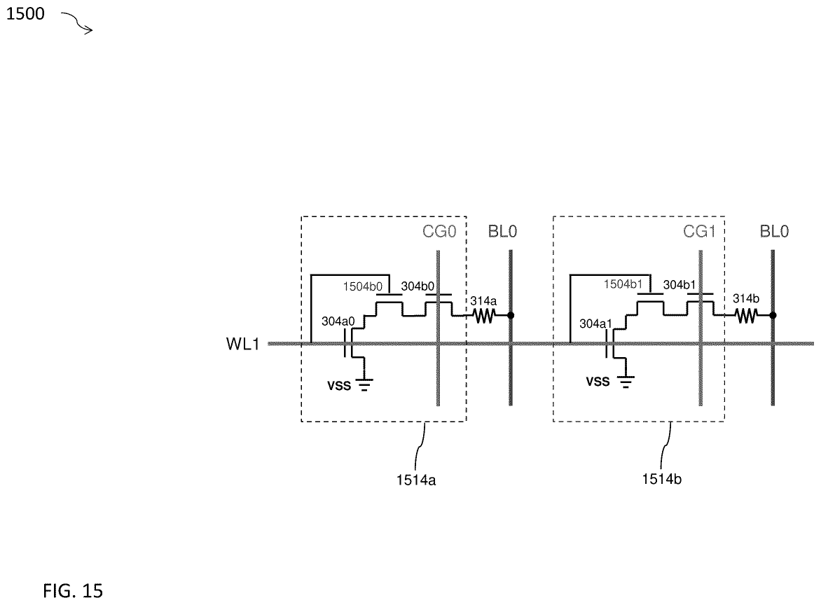

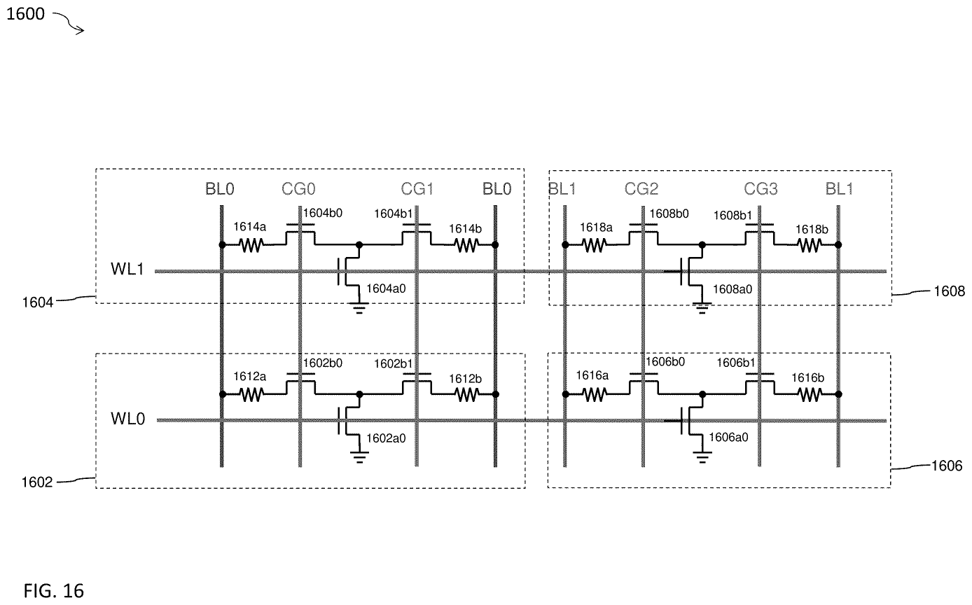

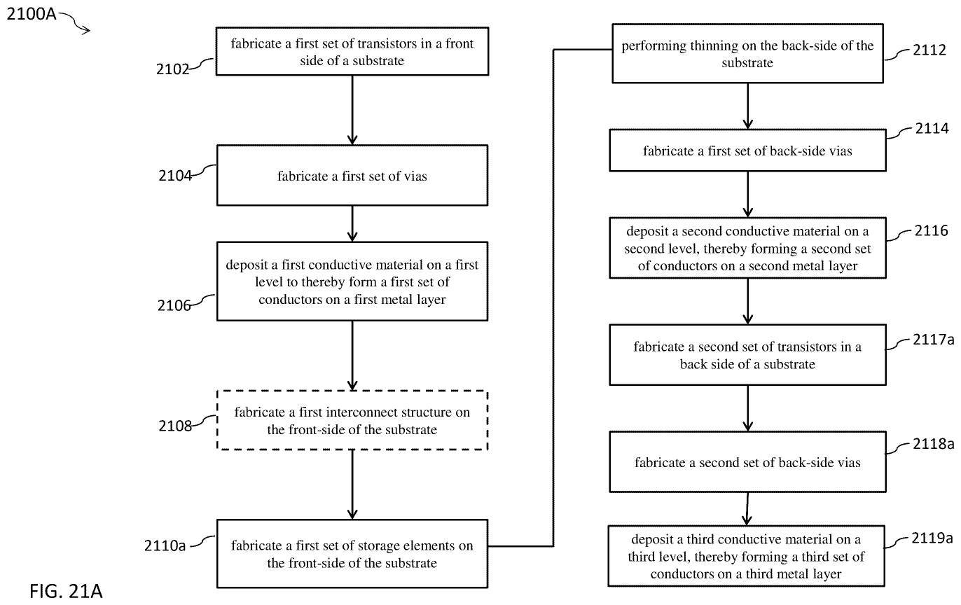

Array of memory cells 202A is a OTP array including OTP memory cells. In some embodiments, each memory cell in array of memory cells 202A corresponds to a two transistor (2T) and one resistor (1R) memory cell (e.g., 2T1R) as shown in FIG. 3. Other numbers of transistors or resistors in each memory cell in array of memory cells 202A are within the scope of the present disclosure. In some embodiments, each memory cell in array of memory cells 202A corresponds to a one transistor (1T) memory cell with one resistor (1R) memory cell (e.g., 1T1R) as shown in FIG. 13. In some embodiments, each memory cell in array of memory cells 202A corresponds to a three transistor (3T) memory cell with one resistor (1R) memory cell (e.g., 3T1R) as shown in FIG. 14. In some embodiments, each memory cell in array of memory cells 202A corresponds to a two transistor (2T) memory cell with one capacitor (1C) memory cell (e.g., 2T1C) as shown in FIG. 19.

Different types of memory cells in array of memory cells 202A are within the contemplated scope of the present disclosure. For example, in some embodiments, each memory cell in array of memory cells 202A is a static random access memory (SRAM). In some embodiments, each memory cell in array of memory cells 202A corresponds to a ferroelectric resistive random-access memory (FeRAM) cell. In some embodiments, each memory cell in array of memory cells 202A corresponds to a magneto-resistive random-access memory (MRAM) cell. In some embodiments, each memory cell in array of memory cells 202A corresponds to a resistive random-access memory (RRAM) cell. Other configurations of array of memory cells 202A are within the scope of the present disclosure.

Memory cell array 200 further includes M word lines WL[0], . . . WL[M-1] (collectively referred to as “word line WL”). Each row 1, . . . , M in array of memory cells 202A is associated with a corresponding word line WL[0], . . . , WL[M-1]. Each row of memory cells in array of memory cells 202A is coupled with a corresponding word line WL[0], . . . , WL[M-1]. For example, memory cells 202[0,0], 202[0,1], . . . , 202[0,N-1] in row 0 are coupled with word line WL[0]. Each word line WL extends in the first direction X.

Memory cell array 200 further includes N bit lines BL[0], . . . BL[N-1] (collectively referred to as “bit line BL”). Each column 0, . . . , N-1 in array of memory cells 202A is associated with a corresponding bit line BL[0], . . . , BL[N-1]. Each column of memory cells in array of memory cells 202A is coupled with a corresponding bit line BL[0], . . . , BL[N-1]. For example, memory cells 202[0,0], 202[1,0], . . . , 202[M-1,0] in column 0 are coupled with bit line BL[0]. Each bit line BL extends in the second direction Y.

Memory cell array 200 further includes N-1 cascode gate lines CG[0], . . . CG[N-1] (collectively referred to as “cascode gate line CG”). Each column 0, . . . , N-1 in array of memory cells 202A is associated with a corresponding cascode gate line CG[0], . . . , CG[N-1]. Each column of memory cells in array of memory cells 202A is coupled with a corresponding cascode gate line CG[O], . . . , CG[N-1]. For example, memory cells 202[0,0], 202[1,0], . . . , 202[M-1,0] in column 0 are coupled with cascode gate line CG[0]. Each cascode gate line CG extends in the second direction Y.

Different configurations of at least bit lines BL, word lines WL or cascode gate lines CG in memory cell array 200 are within the contemplated scope of the present disclosure.

Other configurations of memory cell array 200 are within the scope of the present disclosure.

FIG. 3 is a schematic diagram of a memory cell array 300, in accordance with some embodiments.

Memory cell array 300 is an embodiment of memory cell array 200 of FIG. 2, and similar detailed description is therefore omitted.

In some embodiments, memory cell array 300 is an array of eFuse Rfuse OTP memory cells.

Memory cell array 300 comprises a cell 302, a cell 304, a cell 306 and a cell 308. In some embodiments, memory cell array 300 has a baseline (BSL) configuration.

In some embodiments, each of cell 302, cell 304, cell 306 and cell 308 is a corresponding eFuse Rfuse OTP memory cell. In some embodiments, each of cell 302, cell 304, cell 306 and cell 308 is a corresponding memory cell.

In some embodiments, each cell 302, 304, 306 or 308 in memory cell array 300 corresponds to a four transistor (4T) and two resistor (2R) memory cell (e.g., 4T2R) as shown in FIG. 3. Other numbers of transistors or resistors in each memory cell in memory cell array 300 are within the scope of the present disclosure.

In some embodiments, each cell in memory cell array 300 is an embodiment of a corresponding memory cell MC of memory cell array 112 of FIG. 1, and similar detailed description is therefore omitted.

In some embodiments, each cell in memory cell array 300 is an embodiment of a corresponding memory cell of array of memory cells 202A of FIG. 2, and similar detailed description is therefore omitted.

In some embodiments, cell 302 is an embodiment of a portion of memory cells 202[0,0] and 202[0,1], and similar detailed description is therefore omitted.

In some embodiments, cell 304 is an embodiment of a portion of memory cells 202[1,0] and 202[1,1], and similar detailed description is therefore omitted.

In some embodiments, cell 306 is an embodiment of a portion of memory cells 202[0,1], 202[0,2] and 202[0,3], and similar detailed description is therefore omitted.

In some embodiments, cell 308 is an embodiment of a portion of memory cells 202[1,1], 202[1,2] and 202[1,3], and similar detailed description is therefore omitted.

In some embodiments, cell 302 includes a transistor 302a0, a transistor 302b0, a resistor 312a, a transistor 302a1, a transistor 302b1, a resistor 312b, word line WL0, bit line BLO, cascode gate line CGO and cascode gate line CG1.

In some embodiments, cell 302 includes a first memory cell (e.g., transistor 302a0, transistor 302b0, resistor 312a) and a second memory cell (e.g., transistor 302a1, transistor 302b1, resistor 312b). In some embodiments, while cell 302 includes two memory cells, during programming and/or read operations of cell 302, only a single cell within cell 302 is configured to store data as a security mechanism associated with physically uncountable function (PUF). For example, as part of a PUF system, one of the first memory cell (e.g., transistor 302a0, transistor 302b0, resistor 312a) or second memory cell (e.g., transistor 302a1, transistor 302b1, resistor 312b) is configured to store a logic 1, and the other of the first memory cell (e.g., transistor 302a0, transistor 302b0, resistor 312a) or second memory cell (e.g., transistor 302a1, transistor 302b1, resistor 312 b) is configured to store a logic 0.

In some embodiments, one of the first memory cell (e.g., transistor 302a0, transistor 302b0, resistor 312a) or second memory cell (e.g., transistor 302a1, transistor 302b1, resistor 312b) is programmed during a programming operation, and another of the first memory cell (e.g., transistor 302a0, transistor 302b0, resistor 312a) or second memory cell (e.g., transistor 302a1, transistor 302b1, resistor 312b) fails to be programmed during the programming operation.

In some embodiments, by programming one of the first memory cell (e.g., transistor 302a0, transistor 302b0, resistor 312a) or second memory cell (e.g., transistor 302a1, transistor 302b1, resistor 312b), the memory cell array increases the difficulty of decrypting codes associated with the first memory cell (e.g., transistor 302a0, transistor 302b0, resistor 312a) and the second memory cell (e.g., transistor 302a1, transistor 302b1, resistor 312b) in the memory cell array, thereby resulting in enhanced security of the locations of the first memory cell (e.g., transistor 302a0, transistor 302b0, resistor 312a) or second memory cell (e.g., transistor 302a1, transistor 302b1, resistor 312b) in the memory cell array and corresponding codes associated with each storage element/bit cell compared to other approaches.

In some embodiments, by enhancing the security of the locations of the first memory cell (e.g., transistor 302a0, transistor 302b0, resistor 312a) or second memory cell (e.g., transistor 302a1, transistor 302b1, resistor 312b) in the memory cell array, reverse engineering of the memory cell array becomes more difficult and increases the amount of time and money utilized to identify which of the memory cells are not programmed in the memory cell array resulting in enhanced security in PUF applications.

In some embodiments, each memory cell in the first memory cell or second memory cell of cell 302 is a 2T1R memory cell.

In some embodiments, cell 304 includes a transistor 304a0, a transistor 304b0, a resistor 314a, a transistor 304a1, a transistor 304b1, a resistor 314b, word line WL1, bit line BLO, cascode gate line CGO and cascode gate line CG1.

In some embodiments, cell 304 includes a third memory cell (e.g., transistor 304a0, transistor 304b0, resistor 314a) and a fourth memory cell (e.g., transistor 304a1, transistor 304b1, resistor 314b). In some embodiments, while cell 304 includes two memory cells, during programming and/or read operations of cell 304, only a single cell within cell 304 is configured to store data as a security mechanism associated with PUF.

In some embodiments, each memory cell in the third memory cell or fourth memory cell of cell 304 is a 2T1R memory cell.

In some embodiments, cell 306 includes a transistor 306a0, a transistor 306b0, a resistor 316a, a transistor 306a1, a transistor 306b1, a resistor 316b, word line WL0, bit line BL1, cascode gate line CG2 and cascode gate line CG3.

In some embodiments, cell 306 includes a fifth memory cell (e.g., transistor 306a0, transistor 306b0, resistor 316a) and a sixth memory cell (e.g., transistor 306a1, transistor 306b1, resistor 316b). In some embodiments, while cell 306 includes two memory cells, during programming and/or read operations of cell 306, only a single cell within cell 306 is configured to store data as a security mechanism associated with PUF.

In some embodiments, each memory cell in the fifth memory cell or sixth memory cell of cell 306 is a 2T1R memory cell.

In some embodiments, cell 308 includes a transistor 308a0, a transistor 308b0, a resistor 318a, a transistor 308a1, a transistor 308b1, a resistor 318b, word line WL1, bit line BL1, cascode gate line CG2 and cascode gate line CG3.

In some embodiments, cell 308 includes a seventh memory cell (e.g., transistor 308a0, transistor 308b0, resistor 318a) and an eighth memory cell (e.g., transistor 308a1, transistor 308b1, resistor 318b). In some embodiments, while cell 308 includes two memory cells, during programming and/or read operations of cell 308, only a single cell within cell 308 is configured to store data as a security mechanism associated with PUF.

In some embodiments, each memory cell in the seventh memory cell or eighth memory cell of cell 308 is a 2T1R memory cell.

In some embodiments, at least one of resistor 312a, resistor 312b, resistor 314a, resistor 314b, resistor 316a, resistor 316b, resistor 318a or resistor 318b is a corresponding EFuse Rfuse.

In some embodiments, an EFuse Rfuse is a circuit device including a conductive element capable of being sustainably altered, and thereby programmed, by a current Ifuse (not shown) having a magnitude that exceeds a predetermined current level. In some embodiments, in a non-programmed state, eFuse Rfuse has a small resistance relative to a resistance in a programmed state.

In some embodiments, one of resistor 312a or resistor 312b has a high resistance state that corresponds to a logic 1 or 0, and the other of at least one of resistor 312a or resistor 312b has a low resistance state that corresponds to a logic 0 or 1.

In some embodiments, one of resistor 314a or resistor 314b has a high resistance state that corresponds to a logic 1 or 0, and the other of at least one of resistor 314a or resistor 314b has a low resistance state that corresponds to a logic 0 or 1.

In some embodiments, one of resistor 316a or resistor 316b has a high resistance state that corresponds to a logic 1 or 0, and the other of at least one of resistor 316a or resistor 316b has a low resistance state that corresponds to a logic 0 or 1.

In some embodiments, one of resistor 318a or resistor 318b has a high resistance state that corresponds to a logic 1 or 0, and the other of at least one of resistor 318a or resistor 318b has a low resistance state that corresponds to a logic 0 or 1.

In some embodiments, at least one of transistor 302a0, a transistor 302b0, transistor 302a1, transistor 302b1, transistor 304a0, transistor 304b0, transistor 304a1, transistor 304b1, transistor 306a0, transistor 306b0, transistor 306a1, transistor 306b1, transistor 308a0, transistor 308b0, transistor 308a1 or transistor 308b1 is an N-type transistor. In some embodiments, at least one of transistor 302a0, a transistor 302b0, transistor 302a1, transistor 302b1, transistor 304a0, transistor 304b0, transistor 304a1, transistor 304b1, transistor 306a0, transistor 306b0, transistor 306al, transistor 306b1, transistor 308a0, transistor 308b0, transistor 308a1 or transistor 308b1 is an N-type Metal-Oxide-Semiconductor (NMOS) transistor.

In some embodiments, at least one of transistor 302a0, a transistor 302b0, transistor 302a1, transistor 302b1, transistor 304a0, transistor 304b0, transistor 304a1, transistor 304b1, transistor 306a0, transistor 306b0, transistor 306a1, transistor 306b1, transistor 308a0, transistor 308b0, transistor 308a1 or transistor 308b1 is a P-type transistor. In some embodiments, at least one of transistor 302a0, a transistor 302b0, transistor 302a1, transistor 302b1, transistor 304a0, transistor 304b0, transistor 304a1, transistor 304b1, transistor 306a0, transistor 306b0, transistor 306a1, transistor 306b1, transistor 308a0, transistor 308b0, transistor 308a1 or transistor 308b1 is a P-type Metal-Oxide-Semiconductor (PMOS) transistor.

In some embodiments, each of a drain of transistor 302a0 and a source of transistor 302b0 are coupled together. In some embodiments, each of a drain of transistor 302b0 and a first end of resistor 312a are coupled together.

In some embodiments, each of a drain of transistor 302a1 and a source of transistor 302b1 are coupled together. In some embodiments, each of a drain of transistor 302b1 and a first end of resistor 312b are coupled together.

In some embodiments, each of a drain of transistor 304a0 and a source of transistor 304b0 are coupled together. In some embodiments, each of a drain of transistor 304b0 and a first end of resistor 314a are coupled together.

In some embodiments, each of a drain of transistor 304a1 and a source of transistor 304b1 are coupled together. In some embodiments, each of a drain of transistor 304b1 and a first end of resistor 314b are coupled together.

In some embodiments, each of a drain of transistor 306a0 and a source of transistor 306b0 are coupled together. In some embodiments, each of a drain of transistor 306b0 and a first end of resistor 316a are coupled together.

In some embodiments, each of a drain of transistor 306a1 and a source of transistor 306b1 are coupled together. In some embodiments, each of a drain of transistor 306b1 and a first end of resistor 316b are coupled together.

In some embodiments, each of a drain of transistor 308a0 and a source of transistor 308b0 are coupled together. In some embodiments, each of a drain of transistor 308b0 and a first end of resistor 318a are coupled together.

In some embodiments, each of a drain of transistor 308a1 and a source of transistor 308b1 are coupled together. In some embodiments, each of a drain of transistor 308b1 and a first end of resistor 318b are coupled together.

In some embodiments, two or more of a source of transistor 302a0, a source of transistor 302a1, a source of transistor 306a0, a source of transistor 306a1, a source of transistor 304a0, a source of transistor 304a1, a source of transistor 308a0, a source of transistor 308a1 or a voltage reference supply VSS are coupled together.

Each of a gate of transistor 302a0, a gate of transistor 302a1, a gate of transistor 306a0, a gate of transistor 306a1, and the word line WL0 are coupled together.

Each of a gate of transistor 304a0, a gate of transistor 304a1, a gate of transistor 308a0, a gate of transistor 308a1, and the word line WL1 are coupled together.

Each of a gate of transistor 302b0, a gate of transistor 304b0 and the cascode gate line CG0 are coupled together.

Each of a gate of transistor 302b1, a gate of transistor 304b1 and the cascode gate line CG1 are coupled together.

Each of a gate of transistor 306b0, a gate of transistor 308b0 and the cascode gate line CG2 are coupled together.

Each of a gate of transistor 306b1, a gate of transistor 308b1 and the cascode gate line CG3 are coupled together.

Each of a second end of resistor 314a, a second end of resistor 312a, a second end of resistor 314b, a second end of resistor 312b and the bit line BLO are coupled together.

Each of a second end of resistor 318a, a second end of resistor 316a, a second end of resistor 318b, a second end of resistor 316b and the bit line BL1 are coupled together.

Other configurations of memory cell array 300 are within the scope of the present disclosure.

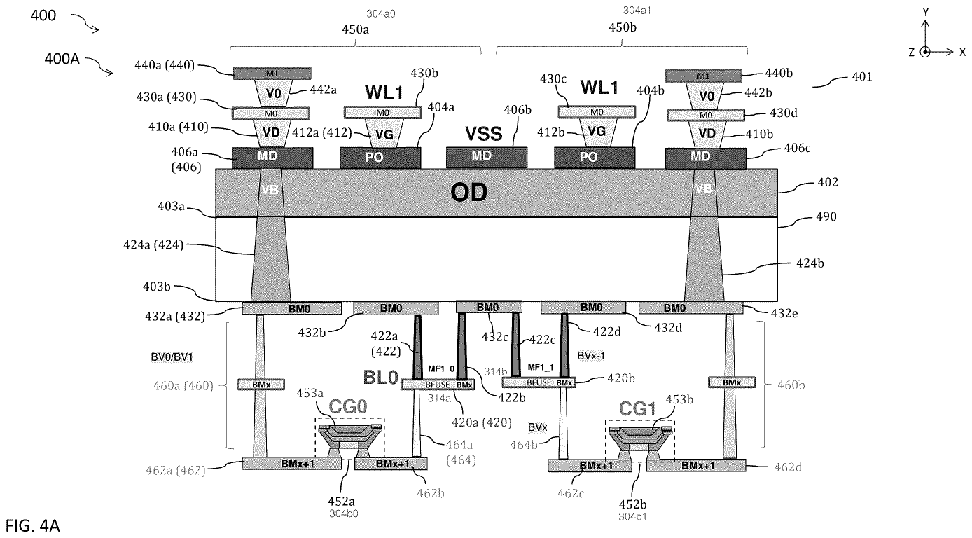

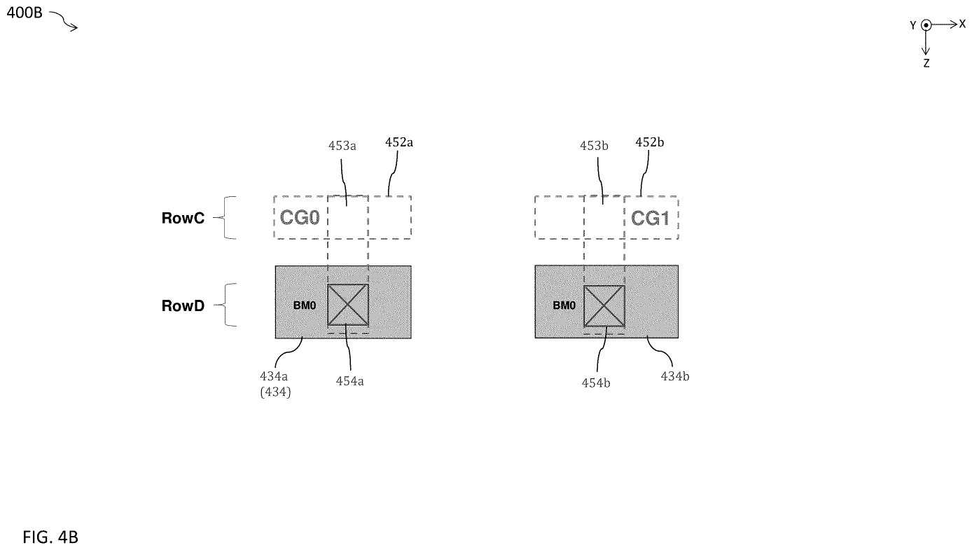

FIG. 4A is a cross-sectional view of a portion 400A of a memory circuit 400, in accordance with some embodiments.

FIG. 4B is a top view of a portion 400B of memory circuit 400, in accordance with some embodiments.

Portion 400A includes each of the elements of memory circuit 400, but the details of a connection between one or more conductors in a BM0 level and the gates 453a and 453b of corresponding select devices 452a and 452b are not shown in FIG. 4A, but are shown in FIG. 4B.

FIG. 4B is a top-down view of portion 400A of FIG. 4A, in accordance with some embodiments.

Portion 400B includes interconnect structures 454a and 454b, select device 452a, select device 452b, gate 453a, gate 453b, and conductors 434a and 434b.

In some embodiments, memory circuit 400 includes metal fuse devices MF1_0 and MF1_1 and select devices 452a and 452b located on a backside 403b of substrate 490, and WL devices 450a and 450b located on a front side 403a of substrate 490.

In some embodiments, WL device 450a is transistor 304a0, and WL device 450b is transistor 304a1, and similar detailed description is therefore omitted.

In some embodiments, select device 452a is transistor 304b0, and select device 452b is transistor 304b1, and similar detailed description is therefore omitted.

In some embodiments, metal fuse device MF1_0 is resistor 314a, and metal fuse device MF1_1 is resistor 314b, and similar detailed description is therefore omitted.

Memory circuit 400 is an embodiment of cell 304 of FIG. 3, and similar detailed description is therefore omitted. In some embodiments, memory circuit 400 is an embodiment of other cells of memory cell array 300, and similar detailed description is therefore omitted.

Memory circuit 400 includes a substrate 490.

Substrate 490 has a front-side 403a and a back-side 403b opposite from the front-side 403a. In some embodiments, at least active regions 402, a set of gates 406, a set of contacts 406, a set of conductors 430 or 440, or a set of vias 410 or 412 are formed in the front-side 403a of substrate 490.

In some embodiments, substrate 490 is a p-type substrate. In some embodiments, substrate 490 is an n-type substrate. In some embodiments, substrate 490 includes an elemental semiconductor including silicon or germanium in crystal, polycrystalline, or an amorphous structure; a compound semiconductor including silicon carbide, gallium arsenic, gallium phosphide, indium phosphide, indium arsenide, and indium antimonide; an alloy semiconductor including SiGe, GaAsP, AlInAs, AlGaAs, GaInAs, GaInP, and GaInAsP; any other suitable material; or combinations thereof. In some embodiments, the alloy semiconductor substrate has a gradient SiGe feature in which the Si and Ge composition change from one ratio at one location to another ratio at another location of the gradient SiGe feature. In some embodiments, the alloy SiGe is formed over a silicon substrate. In some embodiments, substrate 490 is a strained SiGe substrate. In some embodiments, the semiconductor substrate has a semiconductor on insulator structure, such as a silicon on insulator (SOI) structure. In some embodiments, the semiconductor substrate includes a doped epi layer or a buried layer. In some embodiments, the compound semiconductor substrate has a multilayer structure, or the substrate includes a multilayer compound semiconductor structure.

Memory circuit 400 further includes active regions 402 that have been doped.

In some embodiments, active regions 402 corresponds to source and drain regions of NMOS or PMOS transistors of one or more of memory cell array 300, memory cell 1300-1500, memory cell array 1600 or 1900.

In some embodiments, the WL devices 450a and 450b are corresponding NMOS devices and thus the active regions 402 are doped with n-type doping.

In some embodiments, the WL devices 450a and 450b are corresponding PMOS devices and thus the active regions 402 are doped with p-type doping.

In some embodiments, WL device 450a is transistor 304a0, and WL device 450b is transistor 304a1, and similar detailed description is therefore omitted.

In some embodiments, active regions 402 correspond to source and drain regions of transistors 304a0 and 304a1 of cell 304.

In some embodiments, the active regions 402 are sometimes referred to as oxide definition (OD) regions. Examples of circuit elements that may be formed include, but are not limited to, include transistors and diodes. Examples of transistors include, but are not limited to, metal oxide semiconductor field effect transistors (MOSFET), complementary metal oxide semiconductor (CMOS) transistors, bipolar junction transistors (BJT), high voltage transistors, high frequency transistors, P-channel and/or N-channel field effect transistors (PFETs/NFETs), etc.), gate all around (GAA) transistors, FinFETs, planar MOS transistors with raised source/drains, nanosheet FETs, nanowire FETs, complementary FETs (CFETs), or the like. In some embodiments, the active regions 402 and substrate 490 extend in a first direction X.

In some embodiments, the active regions 402 is located on a first level. In some embodiments, the first level corresponds to an active level or an OD level of one or more of memory circuit 400, 500, 600, 700, 1100, 1700, 1800 or 2000. In some embodiments, the OD level is above at least the BM0.

Other configurations, arrangements on other levels or quantities of structures in the active regions 402 are within the scope of the present disclosure.

Memory circuit 400 further includes an insulating region 401.

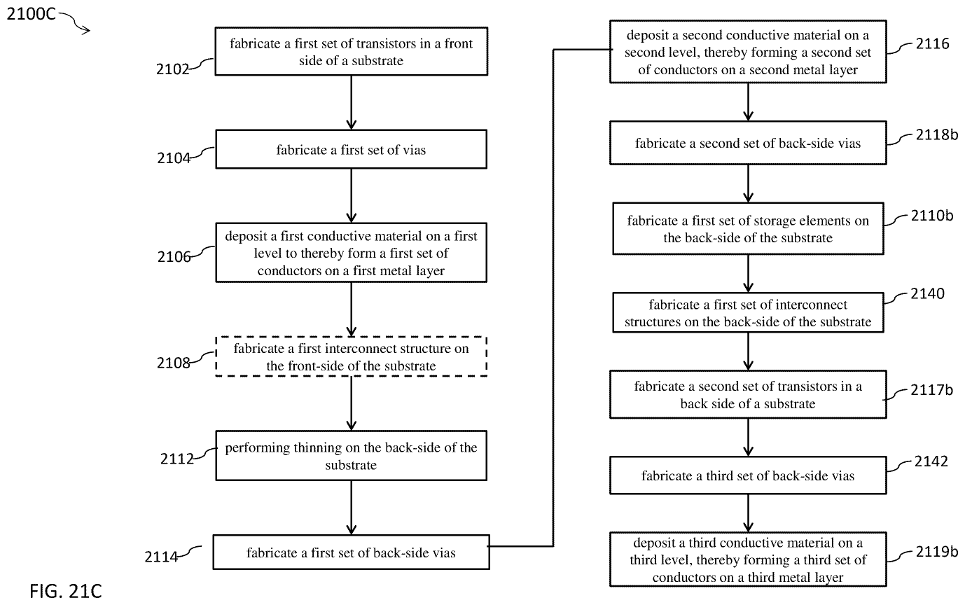

Insulating region 401 is configured to electrically isolate one or more elements of active regions 402, the set of gates 406, the set of contacts 406, the set of conductors 420, 430, 432 or 440, the set of vias 410, 412, 422, 424, 464 or 442 or the set of interconnects 460 from one another. In some embodiments, insulating region 401 includes multiple insulating regions deposited at different times from each other during method 2100 (FIG. 21). In some embodiments, insulating region is a dielectric material. In some embodiments, the dielectric material includes silicon dioxide, silicon oxy-nitride, or the like.

Other configurations, arrangements on other levels or other numbers of portions in insulating region 401 are within the scope of the present disclosure.

Memory circuit 400 further includes the set of gates 404.

The set of gates 404 includes one or more of gates 404a or 404b.

In some embodiments, gate 404a is a gate of transistor 304a0, and gate 404b is a gate of transistor 304a1. In some embodiments, at least one of the set of gates 404 is located on the front-side 403a of memory circuit 400, 500, 600, 700, 1100, 1700, 1800 or 2000.

The set of gates 404 is positioned on a second level. In some embodiments, the second level is different from the first level. In some embodiments, the second level corresponds to the POLY level (also referred to as PO level or MG level) of one or more of memory circuit 400, 500, 600, 700, 1100, 1700, 1800 or 2000. In some embodiments, the POLY level is above the OD and the BM0 level.

Other configurations, arrangements on other levels or quantities of gates in the set of gates 404 are within the scope of the present disclosure.

Memory circuit 400 further includes the set of contacts 406.

The set of contacts 406 includes one or more of contact 406a, 406b or 406c. The set of contacts 406 are located on the front-side 403a of memory circuit 400. The set of contacts 406 overlap the active regions 402.

Each contact of the set of contacts 406 corresponds to one or more drain or source terminals of transistors of memory cell array 300.

In some embodiments, contact 406a is a drain/source terminal of transistor 304a0, contact 406b is a source/drain terminal of transistor 304a0 and a source/drain terminal of transistor 304a1, and a contact 406c is drain/source terminal of transistor 304a1.

In some embodiments, contact 406b is configured as the supply reference voltage VSS.

The set of contacts 406 is located on a third level. In some embodiments, the third level corresponds to the contact level or an MD level of one or more of memory circuit 400, 500, 600, 700, 1100, 1700, 1800 or 2000. In some embodiments, the third level is different from at least one of the first level or the second level.

Other configurations, arrangements on other levels or quantities of conductors in the set of contacts 406 are within the scope of the present disclosure.

Memory circuit 400 further includes the set of conductors 430.

The set of conductors 430 includes one or more of conductors 430a, 430b, 430c or 430d. In some embodiments, the set of conductors 430 corresponds to a set of conductive structures. The set of conductors 430 is embedded in insulating region 401.

The set of conductors 430 overlap the active regions 402, the set of contacts 406 and the set of gates 404.

In some embodiments, the set of conductors 430 corresponds to 4 MO routing tracks. Other numbers of MO routing tracks are within the scope of the present disclosure.

In some embodiments, conductor 430b and conductor 430c are configured as word line WL1.

In some embodiments, conductors 430b and 430c are coupled to corresponding gates 404a and 404b by corresponding vias 412a and 412b.

In some embodiments, the set of conductors 430 is located on a fourth level. In some embodiments, the fourth level is different from at least one of the first level, the second level or the third level. In some embodiments, the fourth level corresponds to the MO level of one or more of memory circuit 400, 500, 600, 700, 1100, 1700, 1800 or 2000. In some embodiments, the MO level is above the OD level, the POLY level, the MD level and the BM0 level.

Other configurations, arrangements on other layout levels or quantities of conductors in the set of conductors 430 are within the scope of the present disclosure.

Memory circuit 400 further includes the set of vias 410.

The set of vias 410 includes one or more of vias 410a or 410b. In some embodiments, the set of vias 410 are between the set of contacts 406 and a set of conductors 430. The set of vias 410 is embedded in insulating region 401.

The set of vias 410 is located where the set of contacts 406 are overlapped by the set of conductors 430. Via 410a or 410b is located where corresponding contact 406a or 406c is overlapped by corresponding conductor 430a or 430b.

The set of vias 410 are configured to electrically couple the active regions 402 and the set of conductors 430 together by the set of contacts 406.

Via 410a electrically couples corresponding contact 406a and corresponding conductor 430a together. Via 410b electrically couples corresponding contact or 406c and corresponding conductor 430d together.

In some embodiments, the set of vias 410 are configured to electrically couple a corresponding source or drain region of the active regions 402 to the set of conductors 430.

The set of vias 410 is positioned at a via over diffusion (VD) level of one or more of memory circuit 400, 500, 600, 700, 1100, 1700, 1800 or 2000. In some embodiments, the VD level is above the OD level, the POLY level, the MD level, the BM0 level, the BMx level and the BMx+1 level. In some embodiments, the VD level is below the MO level. In some embodiments, the VD level is between the MD level and the MO level. In some embodiments, the VD level is between the third level and the fourth level. Other levels are within the scope of the present disclosure.

Other configurations, arrangements on other levels or quantities of vias in the set of vias 410 are within the scope of the present disclosure.

Memory circuit 400 further includes the set of vias 412.

The set of vias 412 includes one or more of vias 412a or 412b. In some embodiments, the set of vias 412 are between the set of gates 404 and the set of conductors 430. The set of vias 412 is embedded in insulating region 401.

The set of vias 412 is located where the set of gates 404 are overlapped by the set of conductors 430. Via 412a or 412b is located where corresponding gate 404a or 404b is overlapped by corresponding conductor 430b or 430c.

The set of vias 412 is configured to electrically couple the set of conductors 430 and the set of gates 404 together.

Via 412a electrically couples corresponding gate 404a and corresponding conductor 430b together. Via 412b electrically couples corresponding gate 404b and corresponding conductor 430c together.

In some embodiments, the set of vias 412 are configured to electrically couple a corresponding gate of the set of gates 404 to the set of conductors 430.

The set of vias 412 is positioned at a via over gate (VG) level of one or more of memory circuit 400, 500, 600, 700, 1100, 1700, 1800 or 2000. In some embodiments, the VG level is above the OD level, the POLY level, the MD level and the BM0 level. In some embodiments, the VG level is below the MO level. In some embodiments, the VG level is between the MD level and the MO level. In some embodiments, the VG level is between the second level and the fourth level. Other levels are within the scope of the present disclosure.

Other configurations, arrangements on other levels or quantities of vias in the set of vias 412 are within the scope of the present disclosure.

Memory circuit 400 further includes the set of conductors 440.

The set of conductors 440 includes one or more of conductors 440a or 440b. In some embodiments, the set of conductors 440 corresponds to a set of conductive structures. The set of conductors 440 is embedded in insulating region 401.

The set of conductors 440 overlap the active regions 402, the set of contacts 406, the set of gates 404 and the set of conductors 430.

In some embodiments, the set of conductors 440 corresponds to 2 M1 routing tracks. Other numbers of M1 routing tracks are within the scope of the present disclosure.

In some embodiments, conductors 440a and 440b are coupled to corresponding conductors 430a and 430d by corresponding vias 412a and 412b.

In some embodiments, the set of conductors 440 is located on a fifth level. In some embodiments, the fifth level is different from at least one of the first level, the second level, the third level or the fourth level. In some embodiments, the fifth level corresponds to the M1 level of one or more of memory circuit 400, 500, 600, 700, 1100, 1700, 1800 or 2000. In some embodiments, the M1 level is above the OD level, the POLY level, the MD level, the MO level and the BM0 level.

Other configurations, arrangements on other layout levels or quantities of conductors in the set of conductors 440 are within the scope of the present disclosure.

Memory circuit 400 further includes the set of vias 442.

The set of vias 442 includes one or more of vias 442a or 442b. In some embodiments, the set of vias 442 are between the set of conductors 440 and the set of conductors 430. The set of vias 442 is embedded in insulating region 401.

The set of vias 442 is located where the set of conductors 430 are overlapped by the set of conductors 440. Via 442a or 442b is located where corresponding conductor 430a or 430d is overlapped by corresponding conductor 440a or 440b.

The set of vias 442 is configured to electrically couple the set of conductors 430 and the set of conductors 440 together.

Via 442a electrically couples corresponding conductor 440a and corresponding conductor 430a together. Via 442b electrically couples corresponding conductor 440b and corresponding conductor 430d together.

The set of vias 442 is positioned at a via over MO (VO) level of one or more of memory circuit 400, 500, 600, 700, 1100, 1700, 1800 or 2000. In some embodiments, the VO level is above the OD level, the POLY level, the MO level, the MD level and the BM0 level. In some embodiments, the VO level is below the M1 level. In some embodiments, the VO level is above the MO level. In some embodiments, the VO level is between the M1 level and the MO level. In some embodiments, the VO level is between the fourth level and the fifth level. Other levels are within the scope of the present disclosure.

Other configurations, arrangements on other levels or quantities of vias in the set of vias 442 are within the scope of the present disclosure.

Memory circuit 400 further includes the set of conductors 432.

The set of conductors 432 includes one or more of conductors 432a, . . . , 432d or 432e. In some embodiments, the set of conductors 432 corresponds to a set of conductive structures. The set of conductors 432 is embedded in insulating region 401.

The set of conductors 432 are on the backside 403b of substrate 490.

The set of conductors 432 are overlapped by the active regions 402, the set of contacts 406, the set of gates 404 and the set of conductors 430.

In some embodiments, the set of conductors 432 corresponds to 5 BMO routing tracks. Other numbers of BMO routing tracks are within the scope of the present disclosure.

In some embodiments, conductor 432a is coupled to contact 406a by via 424a. In some embodiments, conductor 432a is further coupled to a source/drain of select device 452a by at least one or more of interconnect 460a or conductor 462a.

In some embodiments, each of a drain of transistor 304a0 and a source of transistor 304b0 are coupled together by at least one or more of via 424a, conductor 432a, interconnect 460 or conductor 462a.

In some embodiments, conductor 432b is coupled to a drain/source of select device 452a by at least one or more of via 422a, conductor 420a, via 464a or conductor 462b. In some embodiments, conductor 432b is further coupled to a first end of metal fuse device MF1_0 (e.g., first end of resistor 314a). In some embodiments, at least one of conductor 432b or via 422a are not in memory circuit 400.

In some embodiments, each of a drain of transistor 304b0 and a first end of resistor 314a (e.g., conductor 420a) are coupled together by via 464a and conductor 462b.

In some embodiments, conductor 432c is coupled to a second end of metal fuse device MF1_0 (e.g., second end of resistor 314a). In some embodiments, conductor 432c is further coupled to a second end of metal fuse device MF1_1 (e.g., second end of resistor 314b).

In some embodiments, each of a second end of resistor 314a (e.g., conductor 420a) and a second end of resistor 314b (e.g., conductor 420b) are coupled together by via 422b and 422c and conductor 432c.

In some embodiments, conductor 432d is coupled to a drain/source of select device 452b by at least one or more of via 422d, conductor 420b, via 464b or conductor 462c. In some embodiments, conductor 432d is further coupled to a first end of metal fuse device MF1_1 (e.g., first end of resistor 314b). In some embodiments, at least one of conductor 432d or via 422d is not in memory circuit 400.

In some embodiments, each of a drain of transistor 304b1 and a first end of resistor 314b (e.g., conductor 420b) are coupled together by via 464b and conductor 462c.

In some embodiments, conductor 432e is coupled to contact 406c by via 424b. In some embodiments, conductor 432e is further coupled to a source/drain of select device 452b by at least one or more of interconnect 460b or conductor 462d.

In some embodiments, each of a drain of transistor 304a1 and a source of transistor 304b1 are coupled together by at least one or more of via 424b, conductor 432e, interconnect 460b or conductor 462d.

In some embodiments, the set of conductors 432 is located on a sixth level. In some embodiments, the sixth level is different from at least one of the first level, the second level, the third level, the fourth level and the fifth level. In some embodiments, the sixth level corresponds to the BMO level of one or more of memory circuit 400, 500, 600, 700, 1100, 1700, 1800 or 2000. In some embodiments, the BMO level is below the OD level, the POLY level, the MD level, the MO level, the M1 level and the M2 level.

Other configurations, arrangements on other layout levels or quantities of conductors in the set of conductors 432 are within the scope of the present disclosure.

Memory circuit 400 further includes the set of conductors 434 (shown in FIG. 4B).

The set of conductors 434 includes one or more of conductors 434a or 434b. In some embodiments, the set of conductors 434 corresponds to a set of conductive structures. The set of conductors 434 is embedded in insulating region 401.

The set of conductors 434 is on the backside 403b of substrate 490.

In some embodiments, the set of conductors 434 is separated from the set of conductors 432 in the third direction Z.

The set of conductors 434 are overlapped by the active regions 402, the set of contacts 406, the set of gates 404 and the set of conductors 430.

In some embodiments, the set of conductors 434 corresponds to 2 BMO routing tracks. Other numbers of BMO routing tracks are within the scope of the present disclosure.

In some embodiments, conductor 434a is coupled to gate 453a of select transistor 452a by interconnect 454a. In some embodiments, conductor 434b is coupled to gate 453b of select transistor 452 by interconnect 454b.

In some embodiments, conductor 434a is configured as a cascode gate line, and is configured to receive a cascode gate line voltage CG0. In some embodiments, conductor 434b is configured as a cascode gate line, and is configured to receive a cascode gate line voltage CG1.

In some embodiments, conductor 434a is further coupled to other elements (not shown). In some embodiments, conductor 434b is further coupled to other elements (not shown).

In some embodiments, the set of conductors 434 is located on the sixth level.

Other configurations, arrangements on other layout levels or quantities of conductors in the set of conductors 434 are within the scope of the present disclosure.

As shown in FIG. 4B, one or more of select device 452a or select device 452b are positioned in a row ROWC, in accordance with some embodiments.

As shown in FIG. 4B, one or more of conductor 434a, conductor 434b, interconnect 454a or interconnect 454b are positioned in a row ROWD, in accordance with some embodiments.

As shown in FIG. 4B, one or more of conductors 432b or 432d are positioned in rows ROWC and ROWD, in accordance with some embodiments.

In some embodiments, row ROWC and row ROWD are separated from each other in the third direction Z.

In some embodiments, row ROWC and row ROWD are in adjacent rows from each other.

In some embodiments, row ROWC and row ROWD are separated from each other by one or more other rows.

Other configurations, arrangements on other levels or quantities of conductors or vias in at least one of the interconnect 454a or interconnect 454b are within the scope of the present disclosure.

In some embodiments, interconnect 454a comprises one or more vias similar to via 422a, 422b, 422c, 422d, 464a or 464b (described below), and similar detailed description is therefore omitted.

In some embodiments, interconnect 454b comprises one or more vias similar to via 422a, 422b, 422c, 422d, 464a or 464b (described below), and similar detailed description is therefore omitted.

In some embodiments, interconnect 454a is an interconnect similar to interconnect 460a or 460b (described below), and similar detailed description is therefore omitted.

In some embodiments, interconnect 454b is an interconnect similar to interconnect 460a or 460b, and similar detailed description is therefore omitted.

Other configurations, arrangements on other levels or quantities of conductors or vias in at least one of the interconnect 454a or interconnect 454b are within the scope of the present disclosure.

Memory circuit 400 further includes the set of vias 424.

The set of vias 424 includes one or more of vias 424a or 424b. In some embodiments, the set of vias 424 are between the set of contacts 406 and the set of conductors 432. The set of vias 424 is embedded in insulating region 401.

The set of vias 424 is located where the set of conductors 432 are overlapped by at least the set of contacts 406. Via 424a or 424b is located where corresponding conductor 432a or 432e is overlapped by corresponding contact 406a or 406c.

The set of vias 424 is configured to electrically couple together one or more elements from the frontside 403a to one or more elements from the backside 403b.

In some embodiments, the set of vias 424 extends in the second direction Y through the substrate 490.

The set of vias 424 is configured to electrically couple the set of conductors 432 and the set of contacts 406 together.

Via 424a electrically couples corresponding contact 406a and corresponding conductor 432a together. Via 424b electrically couples corresponding contact 406c and corresponding conductor 432e together.

The set of vias 424 is positioned at a via backside (VB) level of one or more of memory circuit 400, 500, 600, 700, 1100, 1700, 1800 or 2000. In some embodiments, the VB level is below the OD level, the POLY level, the MO level, the MD level, the MO level, and the M1 level.

In some embodiments, the VB level is above the BM0 level, the BMx level and the BMx+1 level. In some embodiments, the VO level is between the MD level and the BM0 level. In some embodiments, the VO level is between the third level and the sixth level. Other levels are within the scope of the present disclosure.

Other configurations, arrangements on other levels or quantities of vias in the set of vias 424 are within the scope of the present disclosure.

Memory circuit 400 further includes the set of conductors 420.

The set of conductors 420 includes one or more of conductors 420a or 420b. In some embodiments, the set of conductors 420 corresponds to a set of conductive structures. The set of conductors 420 is embedded in insulating region 401.

The set of conductors 420 are overlapped by the active regions 402, the set of contacts 406, the set of gates 404, the set of conductors 430, 432 and 440.

The set of conductors 420 overlap the set of conductors 462.

In some embodiments, the set of conductors 420 corresponds to metal fuse devices MF1_0 and MF1_1.

In some embodiments, conductor 420a is coupled to conductors 432b, 432c and 462b by corresponding vias 422a, 422b and 464a.

In some embodiments, conductor 420b is coupled to conductors 432c, 432d and 462c by corresponding vias 422c, 422d and 464b.

In some embodiments, conductor 420a is metal fuse device 420a, and conductor 420b is metal fuse device 420b, and similar detailed description is therefore omitted.

In some embodiments, conductor 420a is resistor 314a of FIG. 3, and conductor 420b is resistor 314b of FIG. 3, and similar detailed description is therefore omitted.

In some embodiments, conductor 420a and 420b are electrically coupled to the bit line BL0.

In some embodiments, the set of conductors 420 is located on a seventh level. In some embodiments, the seventh level is different from at least one of the first level, the second level, the third level, the fourth level, the fifth level or the sixth level. In some embodiments the seventh level is between the sixth level and the first level. In some embodiments, the seventh level corresponds to the BMx level of one or more of memory circuit 400, 500, 600, 700, 1100, 1700, 1800 or 2000, where x is an integer greater than 0. In some embodiments, the BMx level is below the OD level, the POLY level, the MD level, the MO level, the M1 level, the M2 level and the BM0 level. In some embodiments, the BM0 level is above the BMx+1 level.

Other configurations, arrangements on other layout levels or quantities of conductors in the set of conductors 420 are within the scope of the present disclosure.

Memory circuit 400 further includes the set of vias 422.

The set of vias 422 includes one or more of vias 422a, 422b, 422c or 422d. In some embodiments, the set of vias 422 are between the set of conductors 420 and the set of conductors 432. The set of vias 422 is embedded in insulating region 401.

The set of vias 422 is located where the set of conductors 432 are overlapped by the set of conductors 420. Via 422a or 422b is located where corresponding conductor 432b or 432c is overlapped by conductor 420a. Via 422c or 422d is located where corresponding conductor 432c or 432d is overlapped by conductor 420b.

The set of vias 422 is configured to electrically couple the set of conductors 432 and the set of conductors 420 together.

Via 422a electrically couples corresponding conductor 420a and corresponding conductor 432b together. Via 422b electrically couples corresponding conductor 420a and corresponding conductor 432c together. Via 422c electrically couples corresponding conductor 420b and corresponding conductor 432c together. Via 422d electrically couples corresponding conductor 420b and corresponding conductor 432d together.

The set of vias 422 is positioned between the sixth level and the seventh level. Other levels are within the scope of the present disclosure.

Other configurations, arrangements on other levels or quantities of vias in the set of vias 422 are within the scope of the present disclosure.

Memory circuit 400 further includes the set of conductors 462.

The set of conductors 462 includes one or more of conductors 462a, 462b, 462c or 462d. In some embodiments, the set of conductors 462 corresponds to a set of conductive structures. The set of conductors 462 is embedded in insulating region 401.

The set of conductors 462 are on the backside 403b of substrate 490.

The set of conductors 462 are overlapped by the active regions 402, the set of contacts 406, the set of gates 404 and the set of conductors 420, 430 and 432.

In some embodiments, the set of conductors 462 corresponds to 4 BMx+1 routing tracks. Other numbers of BMx+1 routing tracks are within the scope of the present disclosure.

In some embodiments, conductor 462a is coupled to interconnect 460a. In some embodiments, conductor 462a is further coupled to a source/drain of select device 452a.

In some embodiments, conductor 462b is coupled to via 464a. In some embodiments, conductor 462b is coupled to a drain/source of select device 452a. In some embodiments, conductor 462b is further coupled to a first end of metal fuse device MF1_0 (e.g., first end of resistor 314a) by via 464a.

In some embodiments, conductor 462c is coupled to via 464b. In some embodiments, conductor 462c is coupled to a drain/source of select device 452b. In some embodiments, conductor 462c is further coupled to a first end of metal fuse device MF1_1 (e.g., first end of resistor 314b) by via 464b.

In some embodiments, conductor 462d is coupled to interconnect 460b. In some embodiments, conductor 462d is further coupled to a source/drain of select device 452b.

In some embodiments, the set of conductors 462 is located on an eleventh level. In some embodiments, the eleventh level is different from at least one of the first level, the second level, the third level, the fourth level, the fifth level, the sixth level or the seventh level. In some embodiments the eleventh level is below the seventh level. In some embodiments, the eleventh level corresponds to the BMx+1 level of one or more of memory circuit 400, 500, 600, 700, 1100, 1700, 1800 or 2000, where x is an integer greater than 0. In some embodiments, the BMx+1 level is below the OD level, the POLY level, the MD level, the MO level, the M1 level, the M2 level, the BM0 level and the BMx level. In some embodiments, the BMx+1 level is below the BMx level.

Other configurations, arrangements on other layout levels or quantities of conductors in the set of conductors 462 are within the scope of the present disclosure.

Memory circuit 400 further includes the set of vias 464.

The set of vias 464 includes one or more of vias 464a or 464b. In some embodiments, the set of vias 464 are between the set of conductors 420 and the set of conductors 462. The set of vias 464 is embedded in insulating region 401.

The set of vias 464 is located where the set of conductors 462 are overlapped by the set of conductors 420. Via 464a or 464b is located where corresponding conductor 462b or 462c is overlapped by corresponding conductor 420a or 420b.

The set of vias 464 is configured to electrically couple the set of conductors 462 and the set of conductors 420 together.

Via 464a electrically couples corresponding conductor 420a and corresponding conductor 462b together. Via 464b electrically couples corresponding conductor 420b and corresponding conductor 462c together.

The set of vias 464 is positioned between the seventh level and the eleventh level. Other levels are within the scope of the present disclosure.

Other configurations, arrangements on other levels or quantities of vias in the set of vias 464 are within the scope of the present disclosure.

Memory circuit 400 further includes the set of interconnects 460.

The set of interconnects 460 includes one or more of interconnects 460a or 460b. In some embodiments, the set of interconnects 460 are between the set of conductors 432 and the set of conductors 462. The set of interconnects 460 is embedded in insulating region 401.

The set of interconnects 460 is located where the set of conductors 462 are overlapped by the set of conductors 432. Interconnect 460a or 460b is located where corresponding conductor 462a or 462d is overlapped by corresponding conductor 432a or 432e.

The set of interconnects 460 is configured to electrically couple the set of conductors 462 and the set of conductors 432 together.

Interconnect 460a electrically couples corresponding conductor 432a and corresponding conductor 462a together. Interconnect 460b electrically couples corresponding conductor 432e and corresponding conductor 462d together.

In some embodiments, the set of interconnects 460 includes one or more vias similar to one or more vias of the set of vias 464 or 422 and/or one or more conductors similar to the set of conductors 432 or 420.

The set of interconnects 460 is positioned between the seventh level and the eleventh level. Other levels are within the scope of the present disclosure.

Other configurations, arrangements on other levels or quantities of interconnects in the set of interconnects 460 are within the scope of the present disclosure.

Memory circuit 400 further includes the select devices 452a and 452b.

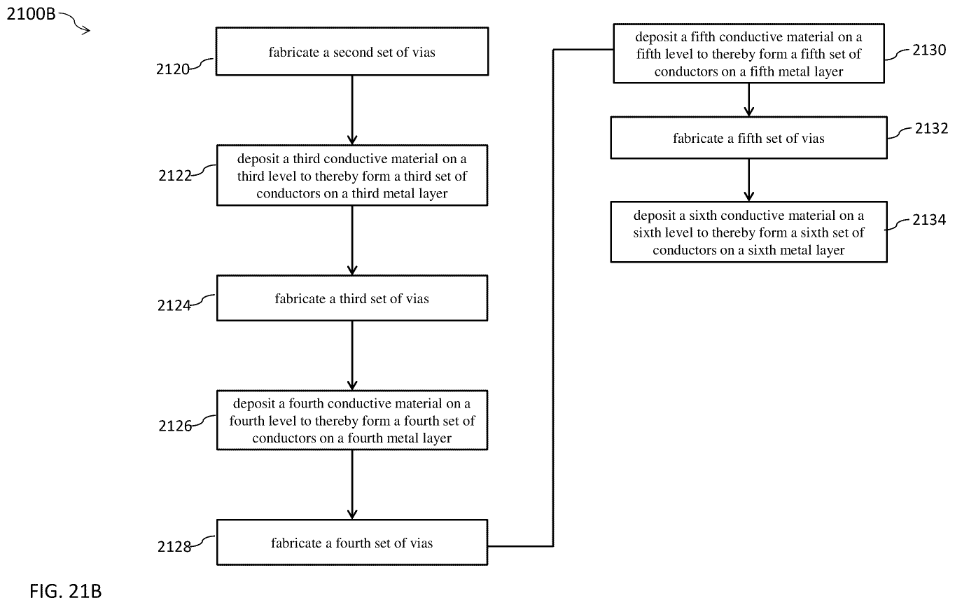

Select device 452a has a gate 453a extending in the third direction Z. Select device 452b has a gate 453b extending in the third direction Z. In some embodiments, at least one of gate 452a or 452b is similar to gate layer 2002 in FIG. 20, and similar detailed description is therefore omitted. In some embodiments, select devices 452a and 452b are between backside metallization layer BMx and backside metallization layer BMx+1. In some embodiments, select devices 452a and 452b are between other backside metallization layers. In some embodiments, select devices 452a and 452b are part of the set of interconnects 460. In some embodiments, select devices 452a and 452b and interconnect 460 are formed as part of a backside back end of line (BEOL) process. In some embodiments, at least a portion of backside metallization layer BMx or backside metallization layer BMx+1 extends in the first direction X and the second direction Y.

Other configurations and arrangements of the plurality of backside metallization layers BMO, . . . , BMx, BMx+1 are within the contemplated scope of the present disclosure.

Other configurations, arrangements on other levels or quantities of select devices are within the scope of the present disclosure.

Memory circuit 400 further includes the set of conductors 434 (shown in FIG. 4B).

The set of conductors 434 includes one or more of conductors 434a or 434b. In some embodiments, the set of conductors 434 corresponds to a set of conductive structures. The set of conductors 434 is embedded in insulating region 401.

The set of conductors 434 is on the backside 403b of substrate 490.

In some embodiments, the set of conductors 434 is separated from the set of conductors 432 in the third direction Z.

The set of conductors 434 are overlapped by gates 4532 and 453b.

In some embodiments, the set of conductors 434 corresponds to 2 BMO routing tracks. Other numbers of BMO routing tracks are within the scope of the present disclosure.

In some embodiments, conductor 434a is coupled to a gate 453a of select transistor 452a by interconnect 454a. In some embodiments, conductor 434b is coupled to a gate 453b of select transistor 452 by interconnect 454b.

In some embodiments, conductor 434a is configured as a cascode gate line, and is configured to receive a cascode gate line voltage CG0. In some embodiments, conductor 434b is configured as a cascode gate line, and is configured to receive a cascode gate line voltage CG1.

In some embodiments, conductor 434a is further coupled to other elements (not shown). In some embodiments, conductor 434b is further coupled to other elements (not shown).

In some embodiments, the set of conductors 434 is located on the sixth level.

Other configurations, arrangements on other layout levels or quantities of conductors in the set of conductors 434 are within the scope of the present disclosure.

As shown in FIG. 4B, one or more of select device 452a or select device 452b are positioned in a row ROWC, in accordance with some embodiments.

As shown in FIG. 4B, one or more of conductor 434a, conductor 434b, interconnect 454a or interconnect 454b are positioned in a row ROWD, in accordance with some embodiments.

As shown in FIG. 4B, one or more of conductors 432b or 432d are positioned in rows ROWC and ROWD, in accordance with some embodiments.

In some embodiments, row ROWC and row ROWD are separated from each other in the third direction Z.

In some embodiments, row ROWC and row ROWD are in adjacent rows from each other.

In some embodiments, row ROWC and row ROWD are separated from each other by one or more other rows.

Other configurations, arrangements on other levels or quantities of conductors or vias in at least one of the interconnect 454a or interconnect 454b are within the scope of the present disclosure.

In some embodiments, interconnect 454a comprises one or more vias similar to via 422a, 422b, 422c, 422d, 464a or 464b, and similar detailed description is therefore omitted.

In some embodiments, interconnect 454b comprises one or more vias similar to via 422a, 422b, 422c, 422d, 464a or 464b, and similar detailed description is therefore omitted.

In some embodiments, interconnect 454a is an interconnect similar to interconnect 460a or 460b (described below), and similar detailed description is therefore omitted.

In some embodiments, interconnect 454b is an interconnect similar to interconnect 460a or 460b, and similar detailed description is therefore omitted.

Other configurations, arrangements on other levels or quantities of conductors or vias in at least one of the interconnect 454a or interconnect 454b are within the scope of the present disclosure.

Other configurations or arrangements to connect at least one of gate 453a or 453b are within the scope of the present disclosure.

In some embodiments, gate 453a of select transistor 452a is coupled to a first conductor in the backside metallization layer BMx by an interconnect similar to interconnect 454a (e.g., in the manner shown in FIG. 4B, where conductor 434a is the first conductor and is part of the BMX metallization layer), and the first conductor in the backside metallization layer BMx is configured as the cascode gate line CG0.

In some embodiments, gate 453b of select transistor 452b is coupled to a second conductor in the backside metallization layer BMx by an interconnect similar to interconnect 454b (e.g., in the manner shown in FIG. 4B, where conductor 434b is the second conductor and is part of the BMX metallization layer), and the second conductor in the backside metallization layer BMx is configured as the cascode gate line CG1.

In some embodiments, at least one of the set of gates 404 are formed using a doped or non-doped polycrystalline silicon (or polysilicon). In some embodiments, at least one gate of the set of gates 404 include a metal, such as Al, Cu, W, Ti, Ta, TiN, TaN, NiSi, CoSi, other suitable conductive materials, or combinations thereof.

In some embodiments, at least one contact of the set of contacts 406 or 506, at least one conductor of the set of conductors 420, 430, 432, 440, 462, 530, 532, 620, 650, 660, 662, 720, 760, 1130, 1132, 1170, 1770, 2020 or 2022, at least one via of the set of vias 410, 412, 422, 424, 442, 464, 524, 622, 664, 722, 1172, 1174, or 1772 or the set of interconnects 460 includes one or more layers of a conductive material, a metal, a metal compound or a doped semiconductor.

In some embodiments, the conductive material includes Tungsten, Cobalt, Ruthenium, Copper, or the like or combinations thereof. In some embodiments, a metal includes at least Cu (Copper), Co, W, Ru, Al, or the like. In some embodiments, a metal compound includes at least AlCu, W-TiN, TiSix, NiSix, TiN, TaN, or the like. In some embodiments, a doped semiconductor includes at least doped silicon, or the like.

In some embodiments, by positioning the WL devices 450a and 450b on the front-side 403a of substrate 490, and by positioning the selection devices 452a and 452b on the back-side 403b as PUF cells as well as positioning the fuse devices MF1_0 and MF1_1 on the back-side 403b, memory circuit 400 has a higher density and/or smaller cell area than other approaches.

Other configurations of memory circuit 400 are within the scope of the present disclosure.

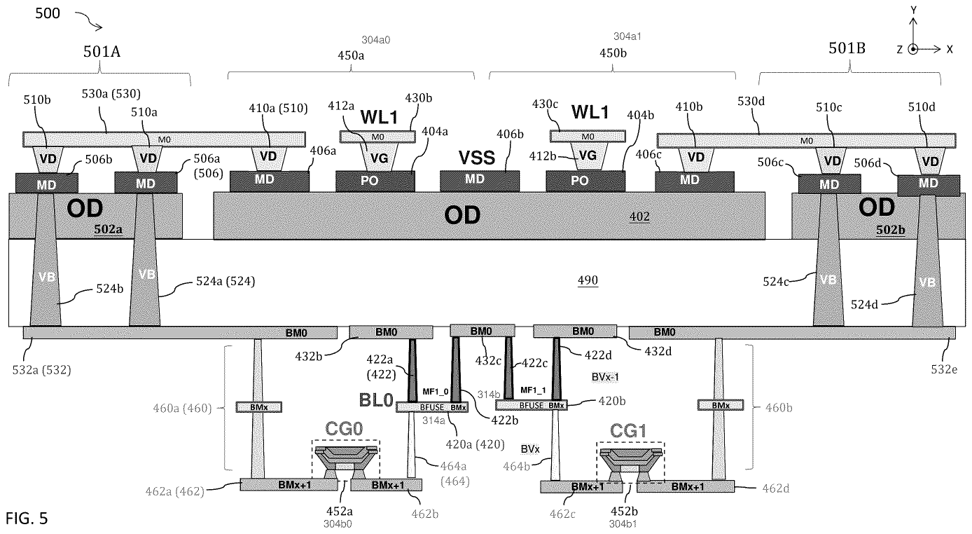

FIG. 5 is a cross-sectional view of a memory circuit 500, in accordance with some embodiments.

In some embodiments, memory circuit 500 includes metal fuse devices MF1_0 and MF1_1 and select devices 452a and 452b located on a backside 403b of substrate 490, and WL devices 450a and 450b located on a front side 403a of substrate 490.

Memory circuit 500 is a variation of memory circuit 400 of FIGS. 4A-4B, and similar detailed description is omitted for brevity. In comparison with memory circuit 400 of FIGS. 4A-4B, memory circuit 500 further includes an interconnect structure 501A and 501B configured to electrically couple the frontside 403a to the backside 403b together, and similar detailed description is therefore omitted.

In some embodiments, in one or more of FIGS. 5, 6A, 7A or 11, the gate 453a of select transistor 452a is coupled to conductor 434a by interconnect 454a as shown in FIG. 4B, and similar detailed description is therefore omitted.

In some embodiments, in one or more of FIGS. 5, 6A or 7A, the gate 453b of select transistor 452b is coupled to conductor 434b by interconnect 454b as shown in FIG. 4B, and similar detailed description is therefore omitted.

In some embodiments, in one or more of FIGS. 5, 6A or 7A, the gate 453a of select transistor 452a is coupled to a first conductor in the backside metallization layer BMx by an interconnect similar to interconnect 454a (e.g., in the manner shown in FIG. 4B, where conductor 434a is the first conductor and is part of the BMX metallization layer), and the first conductor in the backside metallization layer BMx is configured as the cascode gate line CG0, and similar detailed description is therefore omitted.

In some embodiments, in one or more of FIGS. 5, 6A or 7A, the gate 453b of select transistor 452b is coupled to a second conductor in the backside metallization layer BMx by an interconnect similar to interconnect 454b (e.g., in the manner shown in FIG. 4B, where conductor 434b is the second conductor and is part of the BMX metallization layer), and the second conductor in the backside metallization layer BMx is configured as the cascode gate line CG1, and similar detailed description is therefore omitted.

Interconnect structure 501A comprises active region 502a, contacts 506a and 506b, vias 510a and 510b, vias 524a and 524b and conductor 530a.

Interconnect structure 501B comprises active region 502b, contacts 506c and 506d, vias 510c and 510d, vias 524c and 524d and conductor 530d.

In some embodiments, interconnect structure 501A and interconnect structure 501B are separated from active region 402 in the second direction Y by one or more isolation structures (not shown).

In some embodiments, WL device 450a is transistor 304a0, and WL device 450b is transistor 304a1, and similar detailed description is therefore omitted.

In some embodiments, select device 452a is transistor 304b0, and select device 452b is transistor 304b1, and similar detailed description is therefore omitted.

In some embodiments, metal fuse device MF1_0 is resistor 314a, and metal fuse device MF1_1 is resistor 314b, and similar detailed description is therefore omitted.

Memory circuit 500 includes one or more of select device 452a, select device 452b, substrate 490, active regions 402, active regions 502a and 502b, insulating region 401, set of gates 404, a set of contacts 506, a set of conductors 530, a set of vias 510, set of vias 412, set of conductors 440, set of vias 442, a set of conductors 532, a set of vias 524, set of conductors 420, set of vias 422, set of conductors 462, set of vias 464 or set of interconnects 460.

In comparison with memory circuit 400 of FIGS. 4A-4B, set of contacts 506 of memory circuit 500 is similar to set of contacts 406, and active regions 502a and 502b of memory circuit 500 are similar to active regions 402, and similar detailed description is therefore omitted.

In comparison with memory circuit 400 of FIGS. 4A-4B, set of vias 510 of memory circuit 500 replaces set of vias 410, set of vias 524 of memory circuit 500 replaces set of vias 424, set of conductors 530 of memory circuit 500 replaces set of conductors 430, and set of conductors 532 of memory circuit 500 replaces set of conductors 432, and similar detailed description is therefore omitted.

Active regions 502a and 502b are separated from active region 402 in the first direction X. In some embodiments, active regions 5028 and 502B are part of a corresponding dummy transistor device configured as corresponding interconnect structure 501A and 501B.

The set of contacts 506 includes at least one of contact 506a, 506b, 506c or 506d. In some embodiments, at least one of contact 506a, 506b, 506c or 506d is similar to a contact in the set of contacts 406, and similar detailed description is therefore omitted.

Contacts 506a and 506b are on active region 502a.

Contacts 506c and 506d are on active region 502b.

Other configurations, arrangements on other layout levels or quantities of contacts in the set of contacts 506 are within the scope of the present disclosure.

The set of vias 510 includes at least one of via 410a, 410b, 510a, 510b, 510c or 510d. In some embodiments, at least one of via 510a, 510b, 510c or 510d is similar to a via in the set of vias 410, and similar detailed description is therefore omitted.

Via 410a is between and electrically couples corresponding contact 406a and corresponding conductor 530a together. Via 410b is between and electrically couples corresponding contact or 406c and corresponding conductor 530d together.

Via 510a is between and electrically couples corresponding contact 506a and corresponding conductor 530a together. Via 510b is between and electrically couples corresponding contact or 506b and corresponding conductor 530a together.

Via 510c is between and electrically couples corresponding contact 506c and corresponding conductor 530d together. Via 510d is between and electrically couples corresponding contact or 506d and corresponding conductor 530d together.

Other configurations, arrangements on other layout levels or quantities of vias in the set of vias 510 are within the scope of the present disclosure.

The set of conductors 530 includes one or more of conductors 530a, 430b, 430c or 530d.

In some embodiments, at least one of conductor 530a or 530d is similar to a conductor in the set of conductors 430d, and similar detailed description is therefore omitted.

The set of conductors 530 overlap the active regions 402, 502a and 502b, the set of contacts 406 and 506 and the set of gates 404.

In some embodiments, conductor 530a is electrically coupled to contact 506b, 506a and 406a by corresponding via 510b, 510a or 410a.

In some embodiments, conductor 530b is electrically coupled to contact 406c, 506c and 506d by corresponding via 410b, 510c or 510d.

Other configurations, arrangements on other layout levels or quantities of conductors in the set of conductors 530 are within the scope of the present disclosure.

The set of vias 524 includes one or more of vias 524a, 524b, 524c or 524d.

In some embodiments, at least one of via 524a, 524b, 524c or 524d is similar to a via in the set of vias 424, and similar detailed description is therefore omitted.

The set of vias 524 is configured to electrically couple the set of conductors 532 and the set of contacts 506 together.

Via 524a is between and electrically couples corresponding contact 506a and corresponding conductor 532a together.

Via 524b is between and electrically couples corresponding contact 506b and corresponding conductor 532a together.

Via 524c is between and electrically couples corresponding contact 506c and corresponding conductor 532e together.

Via 524d is between and electrically couples corresponding contact 506d and corresponding conductor 532e together.

Other configurations, arrangements on other levels or quantities of vias in the set of vias 524 are within the scope of the present disclosure.

The set of conductors 532 includes at least one of conductor 532a, 432b, 432c, 432d or 532e.

In some embodiments, at least one of conductor 532a or 532e is similar to corresponding conductor 432a or 432e in the set of conductors 432, and similar detailed description is therefore omitted.

Other configurations, arrangements on other layout levels or quantities of conductors in the set of conductors 532 are within the scope of the present disclosure.

In some embodiments, by including interconnect structure 501A and 501B in memory circuit 500, the frontside 403a and the backside 403b are electrically coupled together by the interconnect structures 501A and 501B without being coupled through active region 402 allowing memory circuit 500 to have more flexibility than other approaches.

In some embodiments, by including interconnect structure 501A in memory circuit 500, the source of transistor 304a0 is coupled to the drain of transistor 304b0 by one or more of contact 406a, via 410a, conductor 530a, via 510a, via 510b, via 524a, via 524b, conductor 532a, interconnect 460a or conductor 462a.

In some embodiments, by including interconnect structure 501B in memory circuit 500, the source of transistor 304a1 is coupled to the drain of transistor 304b1 by one or more of contact 406c, via 410b, conductor 530d, via 510c, via 510d, via 524c, via 524d, conductor 532e, interconnect 460b or conductor 462d.

In some embodiments, memory circuit 500 achieves one or more of the benefits described herein.

Other configurations of memory circuit 500 are within the scope of the present disclosure.

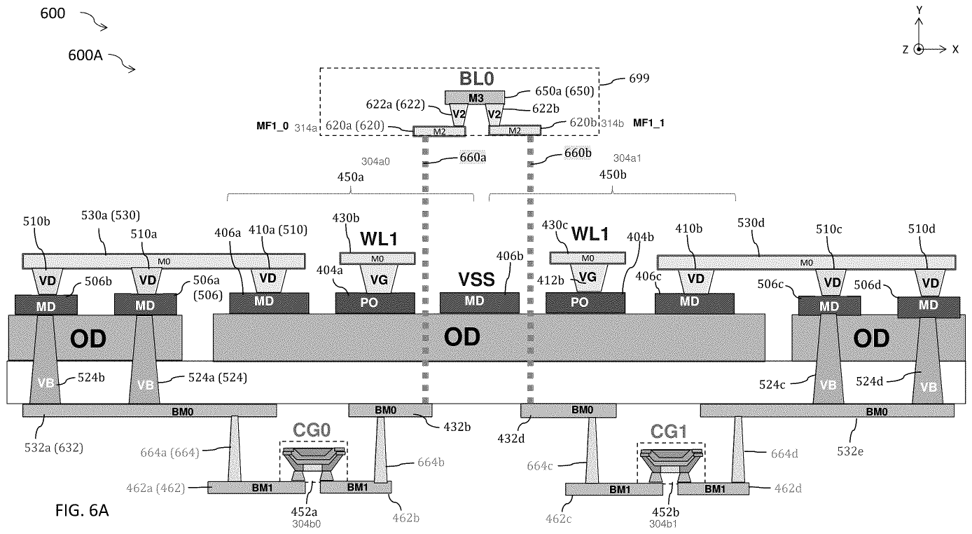

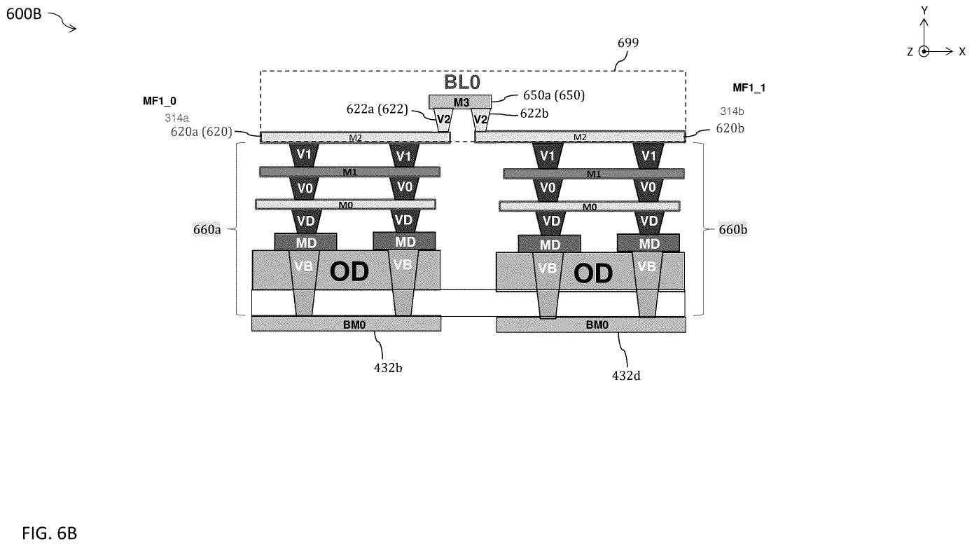

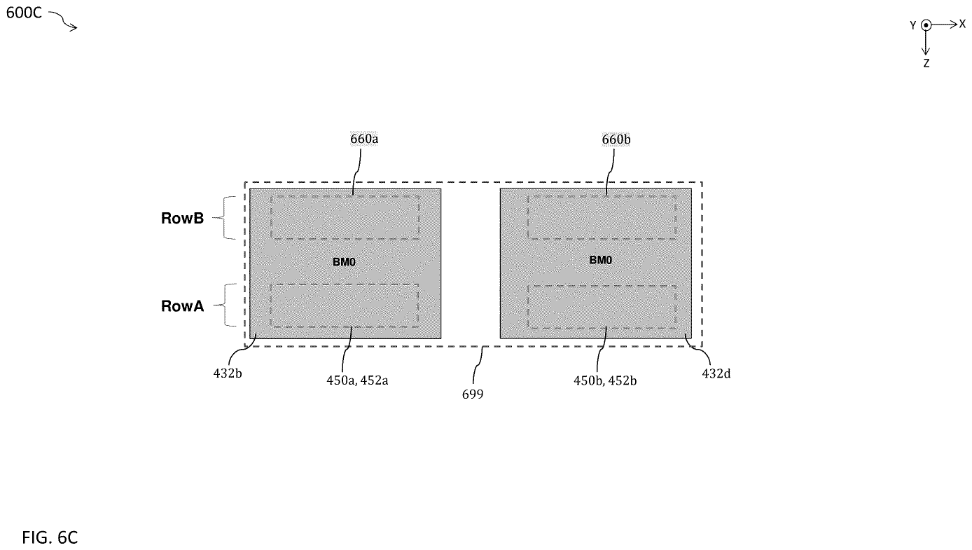

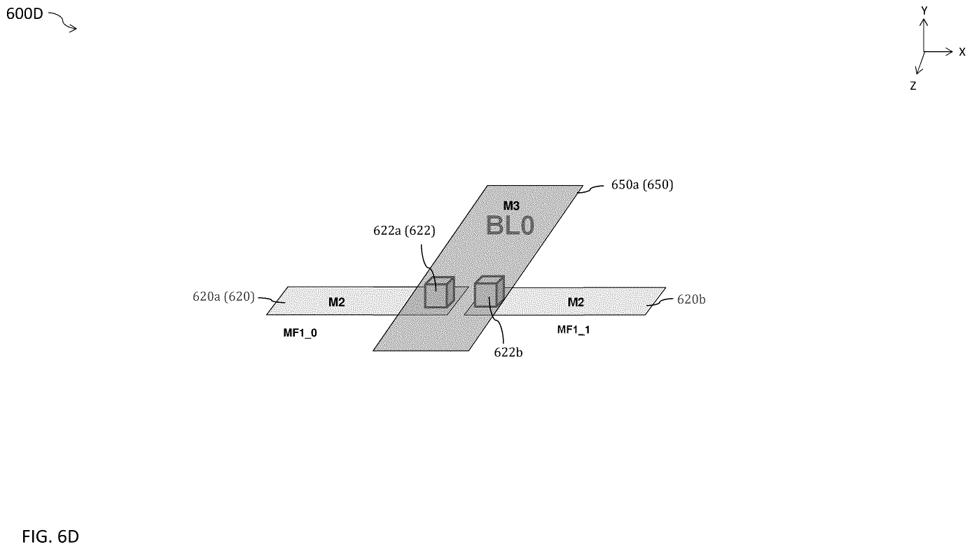

FIG. 6A is a cross-sectional view of a portion 600A of a memory circuit 600, in accordance with some embodiments.

FIG. 6B is a cross-sectional view of a portion 600B of memory circuit 600, in accordance with some embodiments.

FIG. 6C is a top view of a portion 600C of memory circuit 600, in accordance with some embodiments.

FIG. 6D is a perspective view of a portion 600D of memory circuit 600, in accordance with some embodiments.

Portion 600A includes each of the elements of memory circuit 600, but the details of interconnect structures 660a and 660b are not shown in FIG. 6A, but are shown in FIG. 6B.

Portion 600B includes interconnect structures 660a and 660b and fuse device 699.

FIG. 6C is a top-down view of portion 600A of FIG. 6A and portion 600B of FIG. 6B, in accordance with some embodiments.

Portion 600C includes interconnect structures 660a and 600b, fuse device 699, select device 452a, select device 452b, WL device 450a, WL device 450b, and conductors 432b and 432d.

Portion 600D includes conductor 620a, conductor 620b, conductor 650a, via 622a and via 622b.

In some embodiments, memory circuit 600 includes metal fuse devices MF1_0 and MF1_1, and WL devices 450a and 450b located on a front side 403a of substrate 490, and select devices 452a and 452b located on a backside 403b of substrate 490.

Memory circuit 600 is a variation of memory circuit 500 of FIG. 5, and similar detailed description is omitted for brevity. In comparison with memory circuit 500 of FIG. 5, metal fuse MF1_0 and MF1_1 of memory circuit 600 are positioned on the frontside 403a of substrate 490, and similar detailed description is therefore omitted.

Memory circuit 600 includes one or more of select devices 452a and 452b, substrate 490, active regions 402, active regions 502a and 502b, insulating region 401, set of gates 404, set of contacts 506, set of conductors 530, set of vias 510, set of vias 412, a set of conductors 632, a set of vias 524, a set of conductors 620, a set of vias 622, a set of conductors 650, an interconnect structure 660a, an interconnect structure 660b, set of conductors 462 or a set of vias 664.

In some embodiments, set of conductors 620, set of vias 622 and set of conductors 650 are part of fuse structures 699, and is positioned on the frontside 403a of the substrate 490.

In comparison with memory circuit 400 of FIGS. 4A-4B, set of vias 622 of memory circuit 600 replaces set of vias 422, set of conductors 620 of memory circuit 600 replaces set of conductors 420, set of conductors 632 of memory circuit 600 replaces set of conductors 532, and set of vias 664 of memory circuit 600 replaces set of vias 464 and set of interconnects 460, and similar detailed description is therefore omitted.

In comparison with memory circuit 400 of FIGS. 4A-4B, memory circuit 600 further includes set of conductors 620 of memory circuit 600, interconnect structure 660a and interconnect structure 660b, and similar detailed description is therefore omitted.

The set of conductors 620 includes one or more of conductors 620a or 620b. In some embodiments, the set of conductors 620 corresponds to a set of conductive structures. The set of conductors 620 is embedded in insulating region 401.

The set of conductors 620 is overlapped by the set of conductors 650.

The set of conductors 620 overlap the active regions 402, 502a and 502b, the set of contacts 406, the set of gates 404, the set of conductors 430, and interconnect structure 660a and interconnect structure 660b.

In some embodiments, the set of conductors 620 corresponds to metal fuse devices MF1_0 and MF1_1.

In some embodiments, conductor 620a is coupled to conductor 432b by interconnect structure 660a. In some embodiments, conductor 620a is coupled to conductor 650a by via 622a.

In some embodiments, conductor 620b is coupled to conductor 432d by interconnect structure 660b. In some embodiments, conductor 620b is coupled to conductor 650a by via 622b.

In some embodiments, conductor 620a is metal fuse device MF1_0, and conductor 620b is metal fuse device MF1_1, and similar detailed description is therefore omitted.

In some embodiments, conductor 620a is resistor 314a of FIG. 3, and conductor 620b is resistor 314b of FIG. 3, and similar detailed description is therefore omitted.

In some embodiments, conductor 620a and 620b are electrically coupled to the bit line BL0 by conductor 650a and vias 622a and 622b.

In some embodiments, the set of conductors 620 is located on an eighth level. In some embodiments, the eighth level is different from at least one of the first level, the second level, the third level, the fourth level, the fifth level, the sixth level or the sixth level. In some embodiments, the eighth level corresponds to the M2 level of one or more of memory circuit 400, 500, 600, 700, 1100, 1700, 1800 or 2000. In some embodiments, the M2 level is above the OD level, the POLY level, the MD level, the MO level, the M1 level and the BM0 level.

Other configurations, arrangements on other layout levels or quantities of conductors in the set of conductors 620 are within the scope of the present disclosure.

The set of conductors 650 includes one or more of conductor 650a. In some embodiments, the set of conductors 650 corresponds to a set of conductive structures. The set of conductors 650 is embedded in insulating region 401.

The set of conductors 650 overlap the active regions 402, 502a and 502b, the set of contacts 406, the set of gates 404, the set of conductors 430, the set of conductors 620, and interconnect structure 660a and interconnect structure 660b.

In some embodiments, conductor 650a is coupled to conductor 620a by via 622a, and is coupled to conductor 650b by via 622b.

In some embodiments, conductor 650a is configured as the bit line BLO.

In some embodiments, the set of conductors 650 is located on a ninth level. In some embodiments, the ninth level is different from at least one of the first level, the second level, the third level, the fourth level, the fifth level, the sixth level, the sixth level and the seventh level. In some embodiments, the ninth level corresponds to the M3 level of one or more of memory circuit 400, 500, 600, 700, 1100, 1700, 1800 or 2000. In some embodiments, the M3 level is above the OD level, the POLY level, the MD level, the MO level, the M1 level, the M2 level and the BM0 level.

Other configurations, arrangements on other layout levels or quantities of conductors in the set of conductors 650 are within the scope of the present disclosure.

The set of vias 622 includes one or more of vias 622a or 622b. In some embodiments, the set of vias 622 are between the set of conductors 620 and the set of conductors 650. The set of vias 622 is embedded in insulating region 401.

The set of vias 622 is located where the set of conductors 620 are overlapped by the set of conductors 650. Via 622a is located where corresponding conductor 620a is overlapped by conductor 650a. Via 622b is located where corresponding conductor 620b is overlapped by conductor 650a.

The set of vias 622 is positioned between the seventh level and the eighth level. Other levels are within the scope of the present disclosure.

Other configurations, arrangements on other levels or quantities of vias in the set of vias 622 are within the scope of the present disclosure.

The set of conductors 632 includes at least one of conductor 532a, 432b, 432d or 532e.

In comparison with set of conductors 532 of FIG. 5, the set of conductors 632 does not include conductor 432c, and similar detailed description is therefore omitted.

Other configurations, arrangements on other layout levels or quantities of conductors in the set of conductors 632 are within the scope of the present disclosure.

The set of conductors 632 is electrically coupled to the fuse structure 699 by interconnect structures 660a and 660b (described more with respect to FIG. 6B).

Conductor 620a is electrically coupled to conductor 432b by interconnect structure 660a.

Conductor 620b is electrically coupled to conductor 432d by interconnect structure 660b.

The set of vias 664 includes at least one of via 664a, 664b, 664c or 664d.

In some embodiments, at least one of via 664a, 664b, 664c or 664d is similar to via 422a, 422b, 422c or 422d of the set of vias 422, and similar detailed description is therefore omitted.

In some embodiments, at least one of via 664a, 664b, 664c or 664d is similar to via 464a, 464b of the set of vias 464, and similar detailed description is therefore omitted.

In some embodiments, at least one of via 664a, 664b, 664c or 664d is similar to interconnect 460a, 460b of the set of interconnects 460, and similar detailed description is therefore omitted.

The set of vias 664 are positioned between the set of conductors 532 and the set of conductors 662.

Other configurations, arrangements on other layout levels or quantities of vias in the set of vias 664 are within the scope of the present disclosure.

In comparison with the set of conductors 462 of FIG. 5, the set of conductors 462 of FIGS. 6A, 7A, 11, 18A are positioned on a BM1 metal level (e.g., the BMx level when x is equal to 1), and similar detailed description is therefore omitted. Other metal layers are within the scope of the present disclosure.

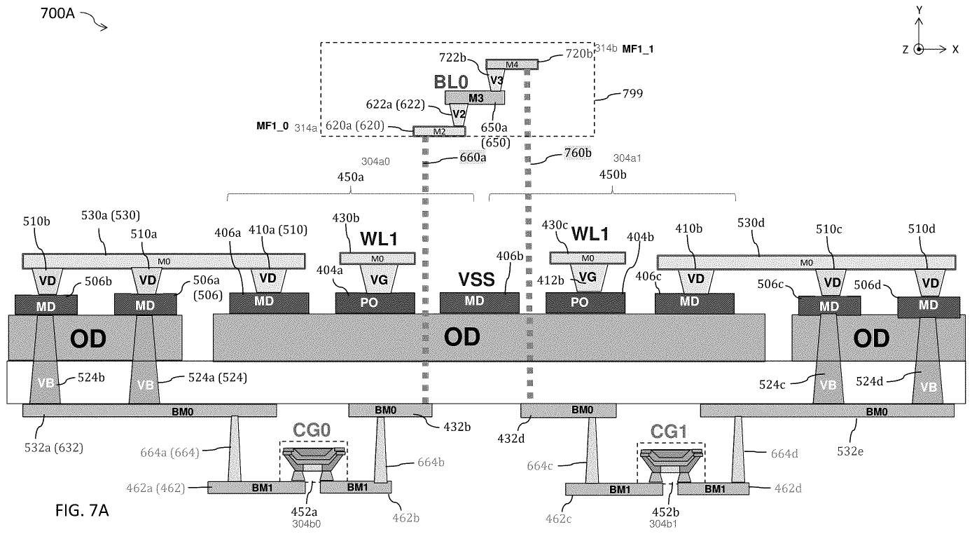

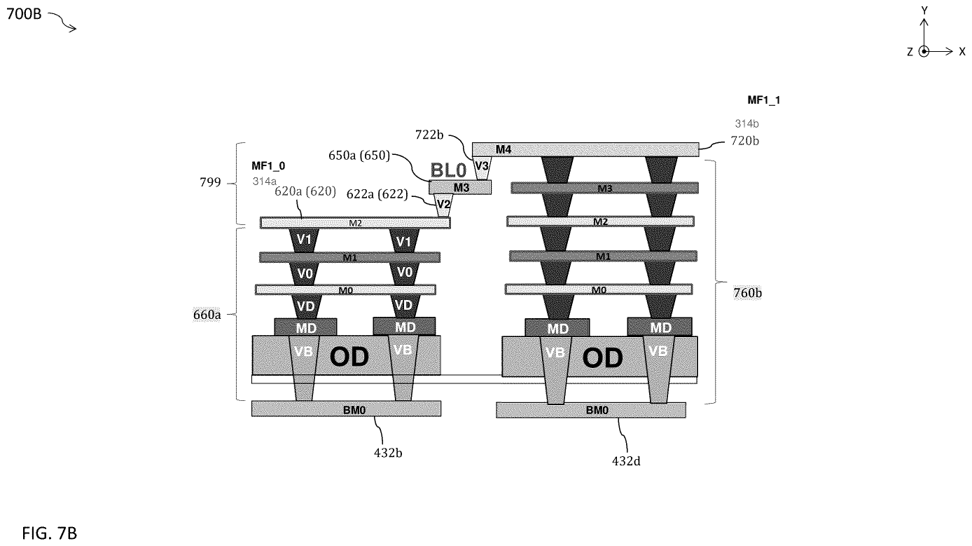

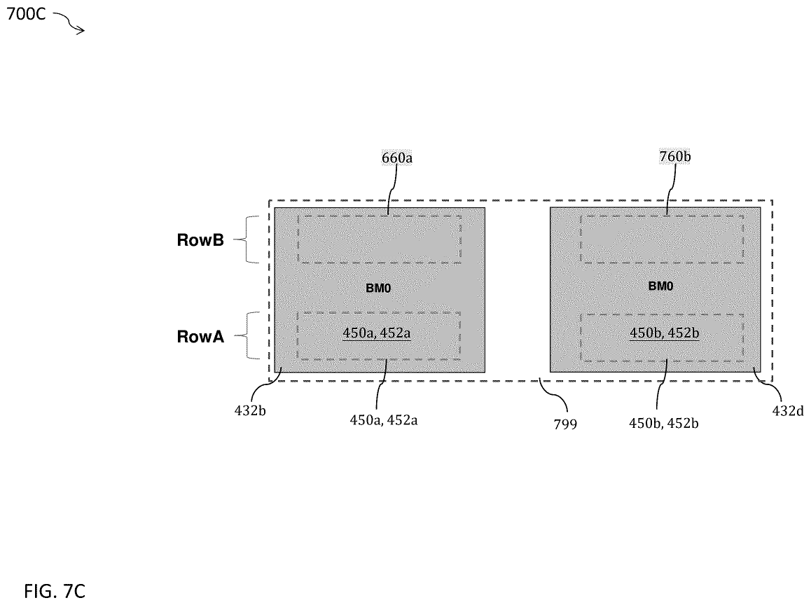

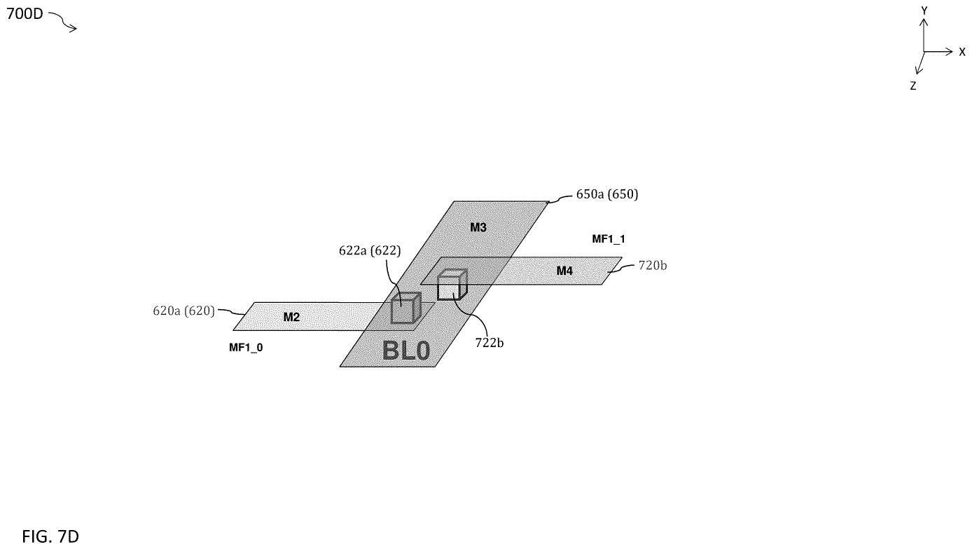

In comparison with the select device 452a and select device 452b of FIG. 5, the select device 452a and select device 452b of FIGS. 6A and 7A are positioned between the BM0 level and the BM1 metal level. Other metal layers are within the scope of the present disclosure.

Other configurations, arrangements on other layout levels or quantities of conductors in the set of conductors 462 are within the scope of the present disclosure.

Interconnect structure 660a is electrically coupled to conductor 620a and conductor 432b.

Interconnect structure 660b is electrically coupled to conductor 620b and conductor 432d.

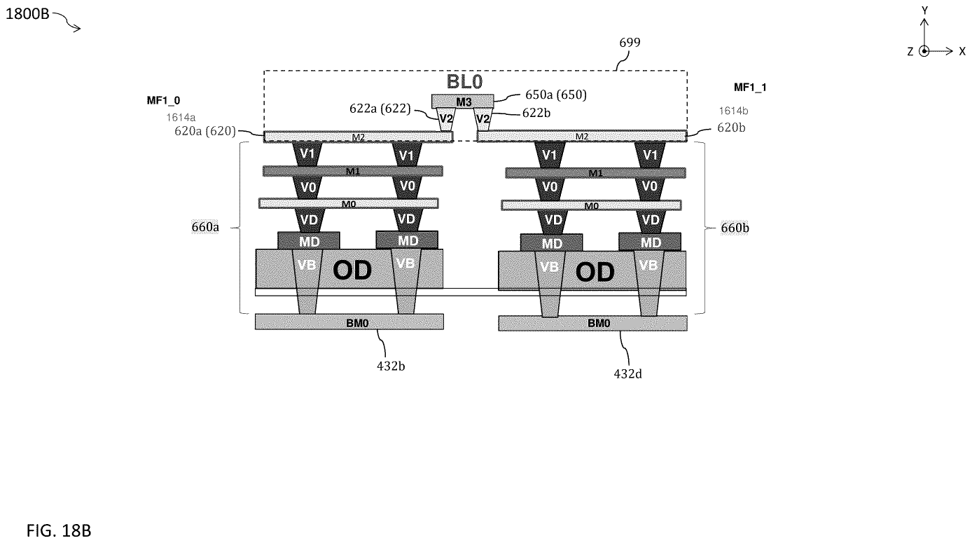

Interconnect structure 660a comprises an active region similar to active region 502a of FIG. 5, contacts similar to contacts 506a and 506b of FIG. 5, vias similar to vias 510a and 510b of FIG. 5, vias similar to vias 524a and 524b of FIG. 5, M1 layer conductors similar to conductor 1170a or 1170b of FIG. 17 (described below), or VO layer vias similar to vias 1172a, 1172b or 1172c of FIG. 17 (described below), and similar detailed description is therefore omitted.

As shown in FIG. 6C, one or more of select device 452a, select device 452b, WL device 450a or WL device 450b are positioned in a row ROWA of FIG. 6B, in accordance with some embodiments.

As shown in FIG. 6C, one or more of fuse structure 699, interconnect structure 660a or interconnect structure 660b are positioned in a row ROWB of FIG. 6B, in accordance with some embodiments.

As shown in FIG. 6C, one or more of conductors 432b or 432d are positioned in rows ROWA and ROWB of FIG. 6B, in accordance with some embodiments.

In some embodiments, row ROWA and row ROWB are in adjacent rows from each other. In some embodiments, adjacent elements are two elements directly next to each other.

In some embodiments, row ROWA and row ROWB are separated from each other by one or more other rows.

Other configurations, arrangements on other levels or quantities of conductors or vias in at least one of the interconnect structure 660a or interconnect structure 660b are within the scope of the present disclosure.

In some embodiments, by moving the fuse structure 699 to the frontside 403a of substrate 490, memory circuit 600 has additional flexibility compared to other approaches.

In some embodiments, by positioning the WL devices 450a and 450b on the front-side 403a of substrate 490, and by positioning the selection devices 452a and 452b on the back-side 403b as PUF cells as well as positioning the fuse devices MF1_0 and MF1_1 on the front-side 403a, memory circuit 400 has a higher density and/or smaller cell area than other approaches.

In some embodiments, memory circuit 600 achieves one or more of the benefits described herein.

Other configurations of memory circuit 600 are within the scope of the present disclosure.

FIG. 7A is a cross-sectional view of a portion 700A of a memory circuit 700, in accordance with some embodiments.

FIG. 7B is a cross-sectional view of a portion 700B of memory circuit 700, in accordance with some embodiments.

FIG. 7C is a top view of a portion 700C of memory circuit 700, in accordance with some embodiments.

FIG. 7D is a perspective view of a portion 700D of memory circuit 700, in accordance with some embodiments.

Portion 700A includes each of the elements of memory circuit 700, but the details of interconnect structures 660a and 760b are not shown in FIG. 7A, but are shown in FIG. 7B.

Portion 700B includes interconnect structures 660a and 760b and fuse device 799.

FIG. 7C is a top-down view of portion 700A of FIG. 7A and portion 700B of FIG. 7B, in accordance with some embodiments.

Portion 700C includes interconnect structures 660a and 760b, fuse device 799, select device 452a, select device 452b, WL device 450a, WL device 450b, and conductors 432b and 432d.

Portion 700D includes conductor 620a, conductor 620b, conductor 650a, via 622a and via 622b.

In some embodiments, memory circuit 700 includes metal fuse devices MF1_0 and MF1_1, and WL devices 450a and 450b located on a front side 403a of substrate 490, and select devices 452a and 452b located on a backside 403b of substrate 490.

Memory circuit 700 is a variation of memory circuit 600 of FIGS. 6A-6D, and similar detailed description is omitted for brevity. In comparison with memory circuit 600 of FIGS. 6A-6D, metal fuse MF1_0 and MF1_1 of memory circuit 700 are positioned on different metal layers (e.g., M2 and M4) of the frontside 403a of substrate 490 from each other, and similar detailed description is therefore omitted.

Memory circuit 700 includes one or more of select devices 452a and 452b, substrate 490, active regions 402, active regions 502a and 502b, insulating region 401, set of gates 404, set of contacts 506, set of conductors 530, set of vias 510, set of vias 412, set of conductors 440, set of vias 442, a set of conductors 632, a set of vias 524, conductors 620a and 720b, vias 622a and 722b, a set of conductors 650, an interconnect structure 660a, an interconnect structure 760b, set of conductors 462 or set of vias 664.

In some embodiments, conductors 620a and 720b, vias 622a and 722b and set of conductors 650 are part of fuse structures 799, and are positioned on the frontside 403a of the substrate 490.

In comparison with memory circuit 600 of FIGS. 6A-6D, via 722b of memory circuit 700 replaces via 622b, conductors 720b of memory circuit 700 replaces conductors 620b, and interconnect structure 760b replaces interconnect structure 660b, and similar detailed description is therefore omitted.

Conductor 720b overlaps the set of conductors 620 and 650, the active regions 402, 502a and 502b, the set of contacts 406, the set of gates 404, the set of conductors 430, and interconnect structure 660a and interconnect structure 760b.

In some embodiments, conductor 620a corresponds to metal fuse device MF1_0. In some embodiments, conductor 720b corresponds to metal fuse device MF1_1.

In some embodiments, conductor 720b is coupled to conductor 432d by interconnect structure 760b. In some embodiments, conductor 720b is coupled to conductor 650a by via 722b.

In some embodiments, conductor 620a is metal fuse device MF1_0, and conductor 720b is metal fuse device MF1_1, and similar detailed description is therefore omitted.

In some embodiments, conductor 620a is resistor 314a of FIG. 3, and conductor 720b is resistor 314b of FIG. 3, and similar detailed description is therefore omitted.

In some embodiments, conductor 620a and 720b are electrically coupled to the bit line BL0 by conductor 650a and vias 622a and 722b.

In some embodiments, conductor 720b is located on a tenth level. In some embodiments, the tenth level is different from at least one of the first level, the second level, the third level, the fourth level, the fifth level, the sixth level, the seventh level, the eighth level or the ninth level. In some embodiments, the tenth level corresponds to the M4 level of one or more of memory circuit 600, 600, 700, 700, 1100, 1700, 1800 or 2000. In some embodiments, the M4 level is above the OD level, the POLY level, the MD level, the MO level, the M1 level, the M2 level, the M3 level and the BM0 level.

Other configurations, arrangements on other layout levels or quantities of conductors in conductor 720a are within the scope of the present disclosure.

In some embodiments, the via 722b is between the set of conductors 620 and the set of conductors 650. The via 722b is embedded in insulating region 401.

Via 722b is located where conductor 720b overlaps conductor 650a.

Via 722b is positioned between the ninth level and the tenth level. Other levels are within the scope of the present disclosure.

Other configurations, arrangements on other levels or quantities of vias in via 722b are within the scope of the present disclosure.

Conductor 620a is electrically coupled to conductor 432b by interconnect structure 660a.

Conductor 720b is electrically coupled to conductor 432d by interconnect structure 760b.

Interconnect structure 660a is electrically coupled to conductor 620a and conductor 432b.

Interconnect structure 760b is electrically coupled to conductor 620b and conductor 432d.

In some embodiments, interconnect structure 760b includes interconnect structure 660b, but further comprises M3 layer conductors similar to conductor 650a, V2 layer vias similar to set of vias 622, V3 layer vias similar to vias 722b, and similar detailed description is therefore omitted.

As shown in FIG. 7C, one or more of select device 452a, select device 452b, WL device 450a or WL device 450b are positioned in a row ROWA, in accordance with some embodiments.

As shown in FIG. 7C, one or more of fuse structure 799, interconnect structure 660a or interconnect structure 760b are positioned in a row ROWB, in accordance with some embodiments.

As shown in FIG. 7C, one or more of conductors 432b or 432d are positioned in rows ROWA and ROWB, in accordance with some embodiments.

In some embodiments, row ROWA and row ROWB are in adjacent rows from each other.

In some embodiments, row ROWA and row ROWB are separated from each other by one or more other rows.

Other configurations, arrangements on other levels or quantities of conductors or vias in at least one of the interconnect structure 660a or interconnect structure 760b are within the scope of the present disclosure.

In some embodiments, by moving the fuse structure 799 to the frontside 403a of substrate 490, memory circuit 700 has additional flexibility compared to other approaches.

In some embodiments, memory circuit 700 achieves one or more of the benefits described herein.

Other configurations of memory circuit 700 are within the scope of the present disclosure.

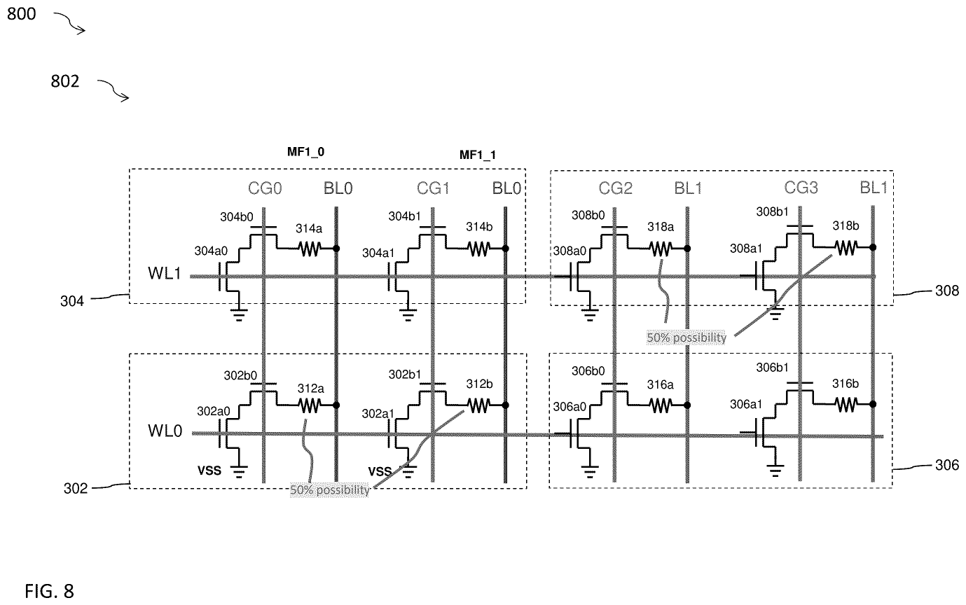

FIG. 8 is a diagram 800 of a memory cell array 802, in accordance with some embodiments.

In some embodiments, memory cell array 802 is memory cell array 300 of FIG. 3, and similar detailed description is therefore omitted.

Diagram 800 is an embodiment of a programming operation of one or more cells in memory cell array 802 of FIG. 8, and similar detailed description is therefore omitted.

In some embodiments, diagram 800 is an embodiment of a programming operation of cell 302 and 308 in memory cell array 802 of FIG. 8, and similar detailed description is therefore omitted.

In some embodiments during a programming operation of cell 302, the word line voltage WL0 is substantially equal to 0.75 volts (V), the word line voltage WL1 is substantially equal to OV, the cascode gate line voltage CG0 is substantially equal to 0.75V, the cascode gate line voltage CG1 is substantially equal to 0.75V, the bit line voltage BLO is substantially equal to voltage HV, the cascode gate line voltage CG2 is substantially equal to OV, the cascode gate line voltage CG3 is substantially equal to OV, the bit line voltage BL1 is substantially equal to 0V.

In some embodiments, a first element is substantially equal to the second element if the first element and second element are different from each other by +/-10%.

In some embodiments, voltage HV ranges from about 1.2V to about 1.5.

In some embodiments during a programming operation of cell 308, the word line voltage WL0 is substantially equal to OV, the word line voltage WL1 is substantially equal to 0.75V, the cascode gate line voltage CG0 is substantially equal to OV, the cascode gate line voltage CG1 is substantially equal to OV, the bit line voltage BLO is substantially equal to OV, the cascode gate line voltage CG2 is substantially equal to 0.75V, the cascode gate line voltage CG3 is substantially equal to 0.75V, the bit line voltage BL1 is substantially equal to voltage HV.

In some embodiments, during programming operations of cell 302, one of resistor 312a or 312b is programmed in an open circuit state, and the other of resistor 312a or 312b is identified and set as a short circuit state, to configure cell 302 to store data as a security mechanism associated with PUF.

In some embodiments, during programming operations of cell 308, one of resistor 318a or 318b is programmed in an open circuit state, and the other of resistor 318a or 318b is identified and set as a short circuit state, to configure cell 308 to store data as a security mechanism associated with PUF.

One or more programming operations of other cells in memory cell array 802 are within the scope of the present disclosure.

Other configurations of diagram 800 are within the scope of the present disclosure.

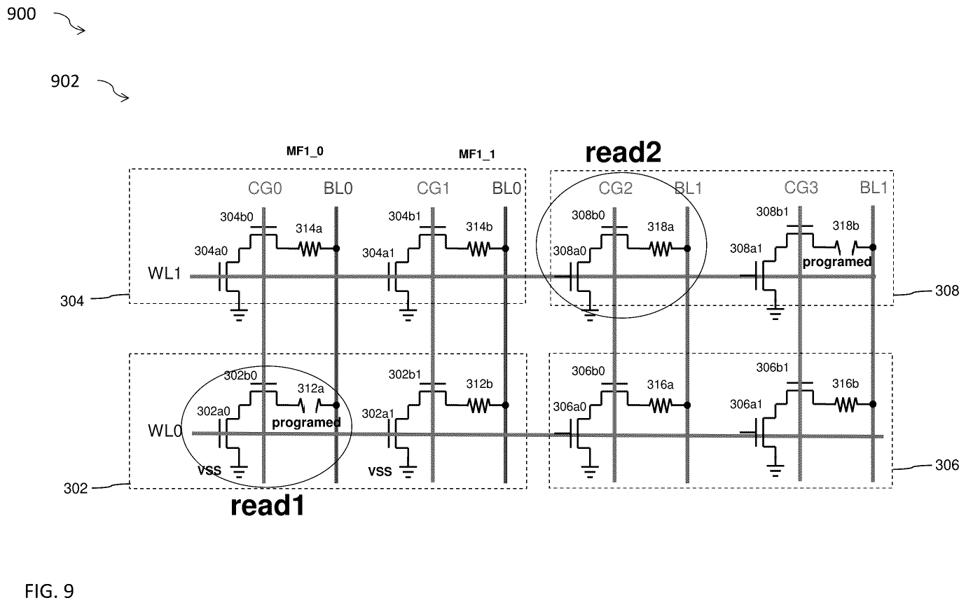

FIG. 9 is a diagram 900 of a memory cell array 902, in accordance with some embodiments.

In some embodiments, memory cell array 902 is memory cell array 300 of FIG. 3, and similar detailed description is therefore omitted.

Diagram 900 is an embodiment of a read operation of one or more cells in memory cell array 902 of FIG. 9, and similar detailed description is therefore omitted.

In some embodiments, diagram 900 is an embodiment of a read operation of cell 302 and 308 in memory cell array 902 of FIG. 9, and similar detailed description is therefore omitted.

In some embodiments during a read operation of cell 302, the word line voltage WL0 is substantially equal to 0.75V, the word line voltage WL1 is substantially equal to OV, the cascode gate line voltage CGO is substantially equal to 0.75V, the cascode gate line voltage CG1 is substantially equal to OV, the bit line voltage BLO is substantially equal to voltage Vread1, the cascode gate line voltage CG2 is substantially equal to OV, the cascode gate line voltage CG3 is substantially equal to OV, the bit line voltage BL1 is substantially equal to 0V.

In some embodiments, from FIG. 8, resistor 312a was previously programmed, and resistor 312b was not programmed. In some embodiments, the voltage Vreadl is a voltage of data stored in the cell 302 that is programmed. In some embodiments, the voltage Vread1 is a voltage read from the fuse (e.g., resistor 312a) in cell 302 that is programmed.

In some embodiments during a read operation of cell 308, the word line voltage WL0 is substantially equal to OV, the word line voltage WL1 is substantially equal to 0.75V, the cascode gate line voltage CGO is substantially equal to OV, the cascode gate line voltage CG1 is substantially equal to OV, the bit line voltage BLO is substantially equal to OV, the cascode gate line voltage CG2 is substantially equal to 0.75V, the cascode gate line voltage CG3 is substantially equal to 0.75V, the bit line voltage BL1 is substantially equal to voltage Vread2.

In some embodiments, from FIG. 8, resistor 318b was previously programmed, and resistor 318a was not programmed. In some embodiments, the voltage Vread2 is a voltage read from the fuse (e.g., resistor 318a) in cell 308 that is not programmed. Thus, in some embodiments, the voltage Vread2 is not the voltage of the data stored in the cell 308.

One or more read operations of other cells in memory cell array 902 are within the scope of the present disclosure.

Other configurations of diagram 900 are within the scope of the present disclosure.

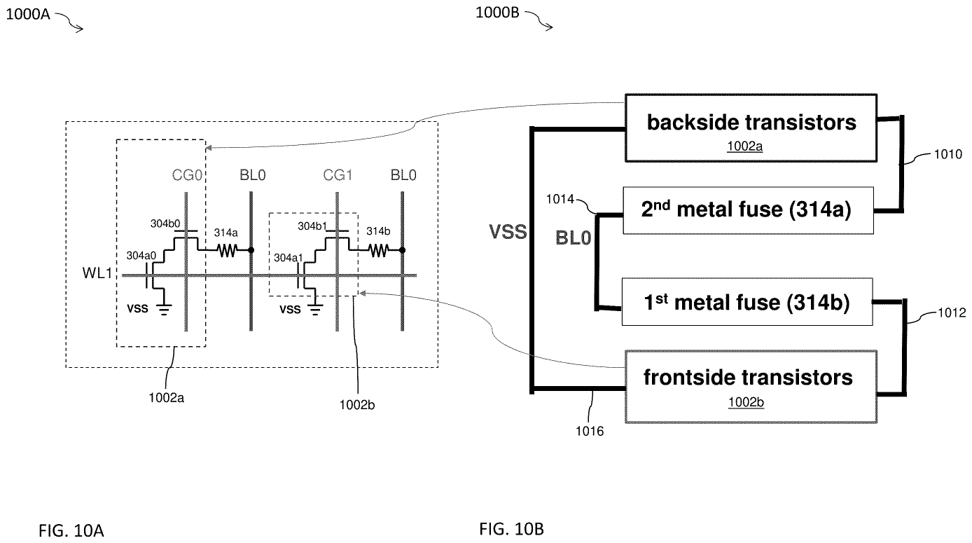

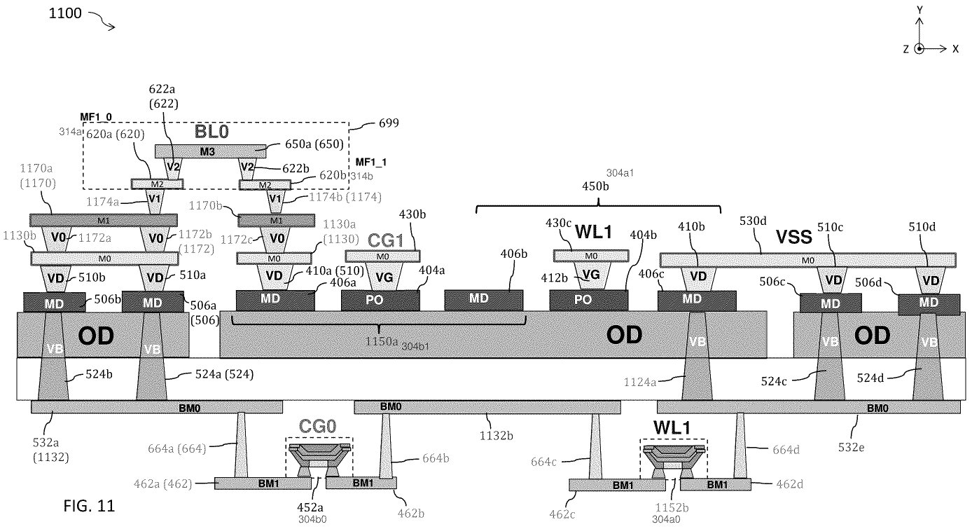

FIG. 10A is a schematic diagram of a memory cell 1000A, in accordance with some embodiments.

Memory cell 1000A is an embodiment of one or more memory cells of array of cells 202A of FIG. 2, and similar detailed description is therefore omitted.

Memory cell 1000A is a variation of at least one of cell 302, 304, 306 or 308 of FIG. 3, and similar detailed description is omitted for brevity. In comparison with cell 302 of FIG. 3, transistor 304a0 and transistor 304b0 are part of a device 1014a in memory cell 1000A, and transistor 304a1 and transistor 1404b1 are part of a device 1014b, and similar detailed description is therefore omitted.

Device 1014a includes transistor 304a0 and transistor 304b0.

Device 1014b includes transistor 304a1 and transistor 304b1.

In some embodiments, device 1014a is located on the backside 403b of the substrate 490, and device 1014b is located on the frontside 403a of the substrate 490.

In some embodiments, device 1014a is located on the frontside 403a of the substrate 490, and device 1014b is located on the backside 403b of the substrate 490.

Other numbers of transistors or resistors in memory cell 1000A are within the scope of the present disclosure.

FIG. 10B is a diagram 1000B of memory cell 1000A, in accordance with some embodiments.

Diagram 1000B is an embodiment of connections of memory cell 1000A of FIG. 10A, and similar detailed description is therefore omitted.

Diagram 1000B comprises a connection 1010, a connection 1012, a connection 1014, a connection 1016, device 1002a, device 1002b, resistor 314a and resistor 314b.

Connection 1010 is a connection between device 1002a and resistor 314a.

Connection 1012 is a connection between device 1002b and resistor 314b.

Connection 1014 is a connection between resistor 314a, resistor 314b and bit line BL0.

Connection 1016 is a connection between device 1002a, device 1002b and reference voltage supply VSS.

Other configurations of diagram 1000B are within the scope of the present disclosure.

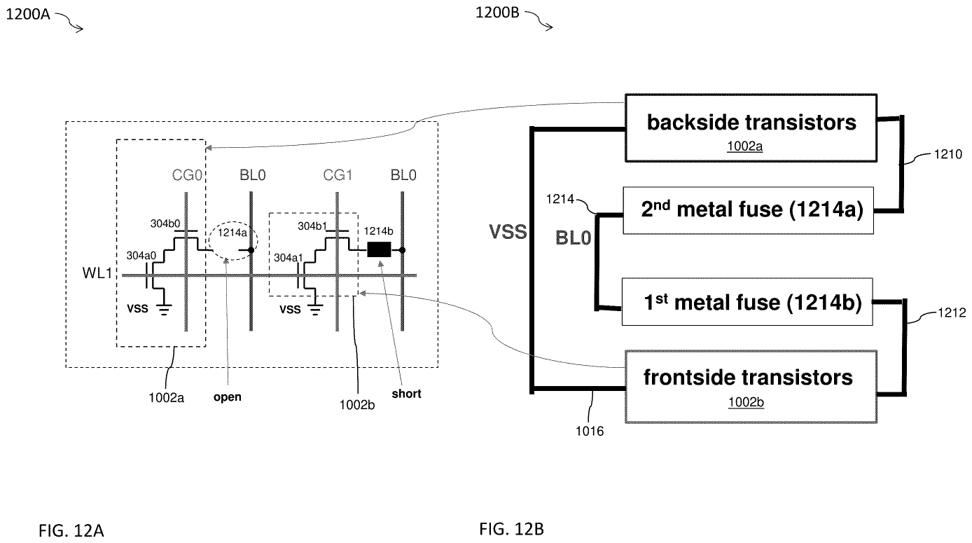

FIG. 11 is a cross-sectional view of a memory circuit 1100, in accordance with some embodiments.

Memory circuit 1100 is an embodiment of memory cell 1000A of FIG. 10A, and similar detailed description is therefore omitted. For example, in some embodiments, select device 452a and WL device 1152b on a backside 403b of substrate 490 of FIG. 11 are an embodiment of device 1002a of FIG. 10A, and select device 1150a and WL device 450b on a front side 403a of substrate 490 of FIG. 11 are an embodiment of device 1002b of FIG. 10A, and similar detailed description is omitted for brevity.

Memory circuit 1100 is a variation of memory circuit 600 of FIGS. 6A-6D, and similar detailed description is omitted for brevity. In comparison with memory circuit 600 of FIGS. 6A-6D, positions of WL device 450a (e.g., select device 1150a in FIG. 11) and select device 452b (e.g., WL device 1152b in FIG. 11) are switched, and similar detailed description is therefore omitted. In comparison with memory circuit 600 of FIGS. 6A-6D, WL device 1152b of FIG. 11 replaces select device 452b of FIGS. 6A-6D, and select device 1150a of FIG. 11 replaces WL device 450a of FIGS. 6A-6D, and similar detailed description is therefore omitted.

In comparison with memory circuit 600 of FIGS. 6A-6D, fuse device 699 of FIG. 11 is electrically connected to select device 1150a and select device 452b by at least a set of vias 1172 and 1174 and a set of conductors 1170 and 1130 compared to the interconnect structures 660a and 660b of FIGS. 6A-6D, and similar detailed description is therefore omitted. In some embodiments, the set of vias 1172 and 1174, and the set of conductors 1170 and 1130 replace the interconnect structures 660a and 660b of FIGS. 6A-6D, and similar detailed description is therefore omitted.

In some embodiments, in FIG. 11, the gate 453b of WL device 1152b is coupled to conductor 434b by interconnect 454b as shown in FIG. 4B, and similar detailed description is therefore omitted.

In some embodiments, in FIG. 11, the gate 453b of WL device 1152b is coupled to a second conductor in the backside metallization layer BMx by an interconnect similar to interconnect 454b (e.g., in the manner shown in FIG. 4B, where conductor 434b is the second conductor and is part of the BMX metallization layer), and the second conductor in the backside metallization layer BMx is configured as the word line WL1, and similar detailed description is therefore omitted.

In some embodiments, select device 1150a is transistor 304b1, WL device 450b is transistor 304a1, WL device 1152b is transistor 304a0, and select device 452a is transistor 304b0, and similar detailed description is therefore omitted. In some embodiments, metal fuse device MF1_0 is resistor 314a, and metal fuse device MF1_1 is resistor 314b, and similar detailed description is therefore omitted.

Memory circuit 1100 includes one or more of select device 452a, WL device 1152b, substrate 490, active regions 402, active regions 502a and 502b, insulating region 401, set of gates 404, set of contacts 506, set of vias 510, set of vias 412, set of vias 524, set of conductors 620, set of conductors 650, set of vias 622, a set of conductors 1132, a set of conductors 1130, a set of conductors 1170, a set of vias 1172, a set of vias 1174, set of conductors 462 or set of vias 664.

In comparison with memory circuit 600 of FIGS. 6A-6D, set of conductors 1132 of memory circuit 1100 replaces set of conductors 632, set of conductors 1130 of memory circuit 1100 replaces set of conductors 530, and similar detailed description is therefore omitted.

The set of conductors 1132 includes conductors 532a, 1132b, and 532e.

Conductor 1132b is electrically coupled to conductor 462b by via 664b. Conductor 1132b is further electrically coupled to conductor 462c by via 664c. At least conductor 1132b electrically couples select device 452a and WL device 1152b together. In some embodiments, at least conductor 1132b electrically couples the drain of transistor 304a0 and the source of transistor 304b0 together.

The set of conductors 1130 includes conductors 1130a and 1130b.

In some embodiments, conductors 1130a and 1130b are similar to conductor 530a, and similar detailed description is therefore omitted.

Conductor 1130a is electrically coupled to vias 510a and 510b.

Conductor 1130b is electrically coupled to via 410a.

The set of conductors 1170 includes conductors 1170a and 1170b.

In some embodiments, conductors 1170a and 1170b are similar to conductor 440a, and similar detailed description is therefore omitted.

The set of vias 1172 includes vias 1172a, 1172b and 1172c.

In some embodiments, vias 1172a, 1172b and 1172c are similar to via 442a, and similar detailed description is therefore omitted.

Via 1172a is between and electrically couples corresponding conductor 1130b and corresponding conductor 1170a together. Via 1172b is between and electrically couples corresponding conductor 1130b and corresponding conductor 1170a together. Via 1172c is between and electrically couples corresponding conductor 1130a and corresponding conductor 1170b together.

The set of vias 1174 includes vias 1174a and 1174b.

Via 1174a is between and electrically couples corresponding conductor 620a and corresponding conductor 1170a together.

Via 1174b is between and electrically couples corresponding conductor 620b and corresponding conductor 1170b together.

The set of vias 1174 is positioned at a via over M1 (V1) level of one or more of memory circuit 400, 500, 600, 700, 1100, 1700, 1800 or 2000. In some embodiments, the V1 level is above the OD level, the POLY level, the MO level, the M1 level, the MD level and the BM0 level. In some embodiments, the VO level is below the M1 level. In some embodiments, the V1 level is below the M2 level. In some embodiments, the VO level is between the M2 level and the M1 level. In some embodiments, the V1 level is between the fifth level and the eighth level. Other levels are within the scope of the present disclosure.

Other configurations, arrangements on other levels or quantities of vias in the set of vias 1174 are within the scope of the present disclosure.

In comparison with memory circuit 600 of FIGS. 6A-6D, conductor 430b of memory circuit 1100 is the cascode gate line CG1, and conductor 530d of memory circuit 1100 is the reference voltage supply VSS, and similar detailed description is therefore omitted.

In some embodiments, by positioning select device 452a and WL device 1152b on a backside 403b of substrate 490 of FIG. 11, and select device 1150a and WL device 450b on a front side 403a of substrate 490, as well as positioning the fuse devices MF1_0 and MF1_1 on the front-side 403a, memory circuit 1100 has a higher density, smaller cell area and/or additional flexibility compared to other approaches.

In some embodiments, by positioning the WL devices 450a and 450b on the front-side 403a of substrate 490, and by positioning the selection devices 452a and 452b on the back-side 403b as PUF cells as well as positioning the fuse devices MF1_0 and MF1_1 on the front-side 403a, memory circuit 400 has a higher density and/or smaller cell area than other approaches.

In some embodiments, memory circuit 1100 achieves one or more of the benefits described herein.

Other configurations of memory circuit 1100 are within the scope of the present disclosure.

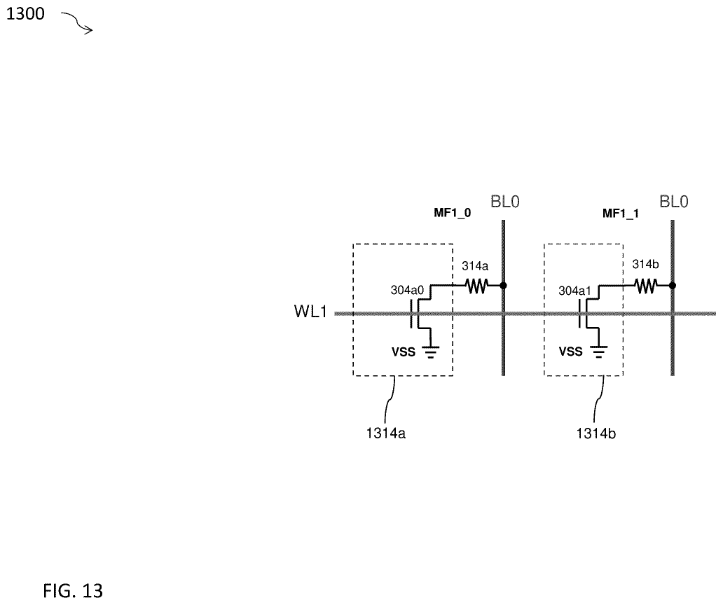

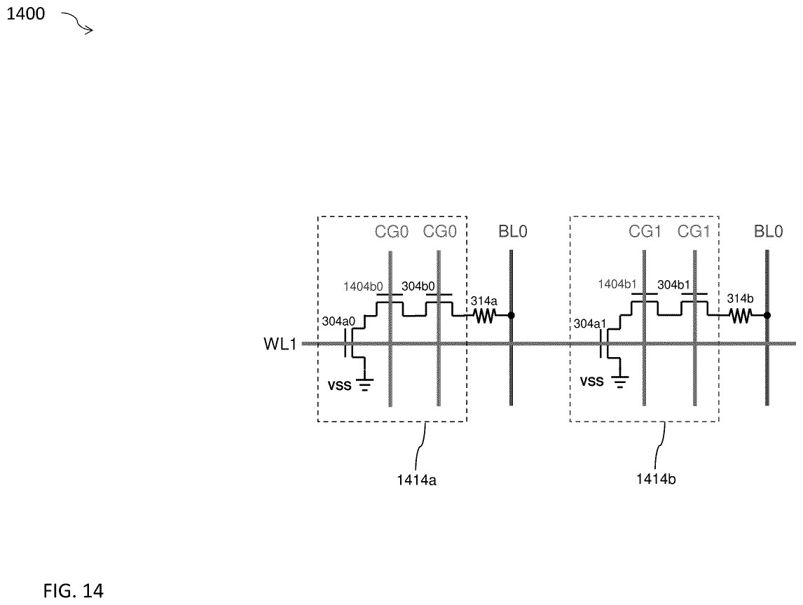

FIG. 12A is a schematic diagram of a memory cell 1200A, in accordance with some embodiments.

Memory cell 1200A is an embodiment of one or more memory cells of array of cells 202A of FIG. 2, and similar detailed description is therefore omitted.

Memory cell 1200A is a variation of memory cell 1000A of FIG. 10A, and similar detailed description is omitted for brevity. In comparison with memory cell 1000A of FIG. 10A, resistor 1214a of memory cell 1200A replaces resistor 314a, and resistor 1214b of memory cell 1200A replaces resistor 314b, and similar detailed description is therefore omitted.

In comparison with resistor 314a of FIG. 10A, resistor 1214a is configured as an open circuit (also referred to as a “open bit”'), and similar detailed description is therefore omitted.

In comparison with resistor 314b of FIG. 10A, resistor 1214b is configured as a short circuit (also referred to as a “short bit”), and similar detailed description is therefore omitted.

In some embodiments, resistor 1214a is configured as a short circuit, and resistor 1214b is configured as an open circuit.

Other numbers of transistors or resistors in memory cell 1200A are within the scope of the present disclosure.

FIG. 12B is a diagram 1200B of memory cell 1200A, in accordance with some embodiments.

Diagram 1200B is an embodiment of connections of memory cell 1200A of FIG. 12A, and similar detailed description is therefore omitted.

Diagram 1200B comprises a connection 1210, a connection 1212, a connection 1214, a connection 1016, device 1002a, device 1002b, resistor 1214a and resistor 1214b.

Connection 1210 is a connection between device 1002a and resistor 1214a.

Connection 1212 is a connection between device 1002b and resistor 1214b.

Connection 1214 is a connection between resistor 1214a, resistor 1214b and bit line BLO.

Connection 1016 is a connection between device 1002a, device 1002b and reference voltage supply VSS.

Other configurations of diagram 1200B are within the scope of the present disclosure.

FIG. 13 is a schematic diagram of a memory cell 1300, in accordance with some embodiments.

Memory cell 1300 is an embodiment of one or more memory cells of array of cells 202A of FIG. 2, and similar detailed description is therefore omitted.

Memory cell 1300 is a variation of at least one of cell 302, 304, 306 or 308 of FIG. 3, and similar detailed description is omitted for brevity. In comparison with cell 302 of FIG. 3, memory cell 1300 does not include transistor 304b0, transistor 304b1, cascode gate line CGO and cascode gate line CG1, and similar detailed description is therefore omitted.

In some embodiments, memory cell 1300 corresponds to a two transistor (2T) and two resistor (2R) memory cell (e.g., 2T2R) as shown in FIG. 13. Other numbers of transistors or resistors in each memory cell in memory cell 1300 are within the scope of the present disclosure.

Memory cell 1300 comprises a transistor 304a0, a resistor 314a, a transistor 304a1, a resistor 314b, word line WL1 and bit line BL0.

In some embodiments, memory cell 1300 includes a first memory cell (e.g., transistor 304a0 and resistor 314a) and a second memory cell (e.g., transistor 304al and resistor 314b).

In some embodiments, each memory cell in the first memory cell or second memory cell of memory cell 1300 is a 1T1R memory cell.

In some embodiments, transistor 304a0 is referred to as a select device 1314a.

In some embodiments, transistor 304al is referred to as a select device 1314b.

In some embodiments, select device 1314a is located on the backside 403b of the substrate 490, and select device 1314b is located on the frontside 403a of the substrate 490.

In some embodiments, select device 1314a is located on the frontside 403a of the substrate 490, and select device 1314b is located on the backside 403b of the substrate 490.

In some embodiments, each of a drain of transistor 304a0 and a first end of resistor 314a are coupled together.

In some embodiments, each of a drain of transistor 304a1 and a first end of resistor 314b are coupled together.

In some embodiments, two or more of a source of transistor 304a0, a source of transistor 304a1 or a voltage reference supply VSS are coupled together.

Each of a gate of transistor 304a0, a gate of transistor 304a1 and the word line WL1 are coupled together.

Each of a second end of resistor 314a, a second end of resistor 314b and the bit line BL0 are coupled together.

Other configurations of memory cell 1300 are within the scope of the present disclosure.

FIG. 14 is a schematic diagram of a memory cell 1400, in accordance with some embodiments.

Memory cell 1400 is an embodiment of one or more memory cells of array of cells 202A of FIG. 2, and similar detailed description is therefore omitted.

Memory cell 1400 is a variation of at least one of cell 302, 304, 306 or 308 of FIG. 3, and similar detailed description is omitted for brevity. In comparison with cell 302 of FIG. 3, memory cell 1400 does not include transistor 304b0, transistor 304b1, cascode gate line CGO and cascode gate line CG1, and similar detailed description is therefore omitted.

In some embodiments, memory cell 1400 corresponds to a six transistor (6T) and two resistor (2R) memory cell (e.g., 6T2R) as shown in FIG. 14. Other numbers of transistors or resistors in each memory cell in memory cell 1400 are within the scope of the present disclosure.

Memory cell 1400 comprises includes a transistor 304a0, a transistor 1404b0, a transistor 304b0, a resistor 314a, a transistor 304a1, a transistor 1404b1, a transistor 304b1, a resistor 314b, word line WL1, bit line BLO, two cascode gate lines CGO and two cascode gate lines CG1.

In some embodiments, cell 304 includes a first memory cell (e.g., transistor 304a0, transistor 1404b0, transistor 304b0, resistor 314a) and a second memory cell (e.g., transistor 304a1, transistor 1404b1, transistor 304b1, resistor 314b).

In some embodiments, each memory cell in the first memory cell or second memory cell of memory cell 1400 is a 3T1R memory cell.

In some embodiments, transistor 304a0, transistor 1404b0 and transistor 304b0 are referred to as a backside device 1414a.

In some embodiments, transistor 304a1, transistor 1404b1 and transistor 304b1 is referred to as a frontside device 1414b.

In some embodiments, backside device 1414a is located on the backside 403b of the substrate 490, and frontside device 1414b is located on the frontside 403a of the substrate 490.

In some embodiments, each of a drain of transistor 304a0 and a source of transistor 1404b0 are coupled together. In some embodiments, each of a drain of transistor 1404b0 and a source of transistor 304b0 are coupled together. In some embodiments, each of a drain of transistor 304b0 and a first end of resistor 314a are coupled together.

In some embodiments, each of a drain of transistor 304a1 and a source of transistor 1404b1 are coupled together. In some embodiments, each of a drain of transistor 1404b1 and a source of transistor 304b1 are coupled together. In some embodiments, each of a drain of transistor 304b1 and a first end of resistor 314b are coupled together.

In some embodiments, two or more of a source of transistor 304a0, a source of transistor 304a1 or a voltage reference supply VSS are coupled together.

Each of a gate of transistor 1404b0, a gate of transistor 304b0 and the cascode gate line CGO are coupled together.

Each of a gate of transistor 1404b1, a gate of transistor 304b1 and the cascode gate line CG1 are coupled together.

Each of a gate of transistor 304a0, a gate of transistor 304a1 and the word line WL1 are coupled together.

Other configurations of memory cell 1400 are within the scope of the present disclosure.

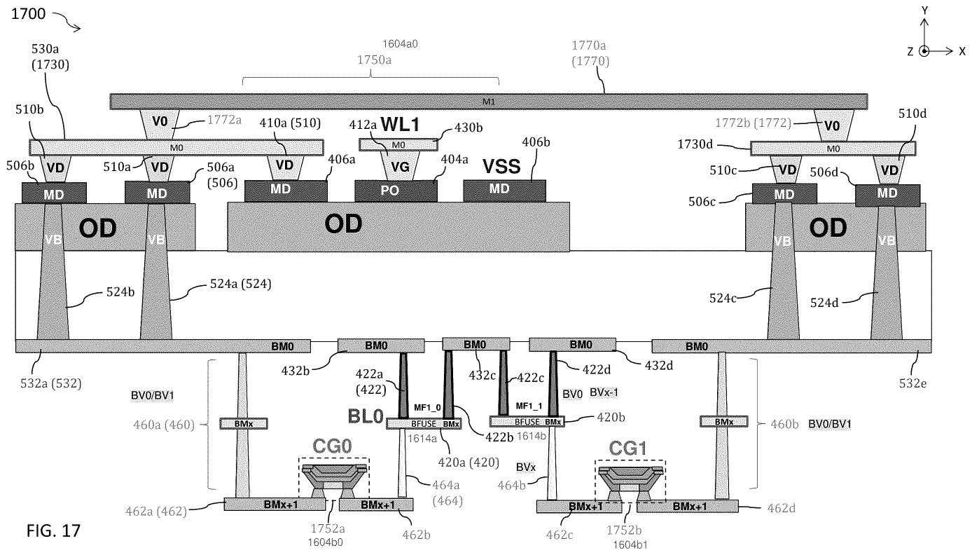

FIG. 15 is a schematic diagram of a memory cell 1500, in accordance with some embodiments.

Memory cell 1500 is an embodiment of one or more memory cells of array of cells 202A of FIG. 2, and similar detailed description is therefore omitted.

Memory cell 1500 is a variation of memory cell 1400 of FIG. 14, and similar detailed description is omitted for brevity. In comparison with memory cell 1400 of FIG. 14, memory cell 1500 includes a single cascode gate line CGO and a single cascode gate line CG1, and similar detailed description is therefore omitted.

In comparison with memory cell 1400 of FIG. 14, a gate of transistor 1504b0 is coupled to a gate of transistor 304a0, a gate of transistor 1504b1 is coupled to a gate of transistor 304a1, and similar detailed description is therefore omitted.

In some embodiments, transistor 1504b0 or 1504b1 is similar to corresponding transistor 1404b0 or 1404b1, and similar detailed description is therefore omitted.

Other numbers of transistors or resistors in each memory cell in memory cell 1500 are within the scope of the present disclosure.

Memory cell 1500 comprises includes a transistor 304a0, a transistor 1504b0, a transistor 304b0, a resistor 314a, a transistor 304a1, a transistor 1504b1, a transistor 304b1, a resistor 314b, word line WL1, bit line BLO, cascode gate line CGO and cascode gate line CG1.

In some embodiments, transistor 304a0, transistor 1504b0 and transistor 304b0 are referred to as a backside device 1514a.

In some embodiments, transistor 304a1, transistor 1504b1 and transistor 304b1 is referred to as a frontside device 1514b.

In some embodiments, backside device 1514a is located on the backside 403b of the substrate 490, and frontside device 1514b is located on the frontside 403a of the substrate 490.

Each of a gate of transistor 304b0 and the cascode gate line CGO are coupled together.

Each of a gate of transistor 304b1 and the cascode gate line CG1 are coupled together.

Each of a gate of transistor 304a0, a gate of transistor 1504b0, a gate of transistor 304a1, a gate of transistor 1504b1, and the word line WL1 are coupled together.

Other configurations of memory cell 1500 are within the scope of the present disclosure.

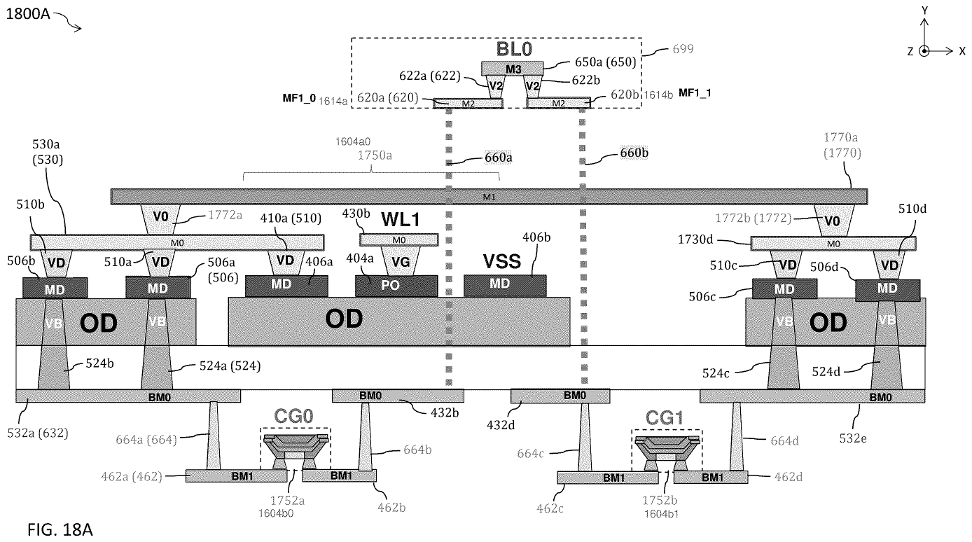

FIG. 16 is a schematic diagram of a memory cell array 1600, in accordance with some embodiments.

Memory cell array 1600 is an embodiment of memory cell array 200 of FIG. 2, and similar detailed description is therefore omitted.

In some embodiments, memory cell array 1600 is an array of eFuse Rfuse OTP memory cells.

Memory cell array 1600 comprises a cell 1602, a cell 1604, a cell 1606 and a cell 1608.

In some embodiments, each of cell 1602, cell 1604, cell 1606 and cell 1608 is a corresponding eFuse Rfuse OTP memory cell. In some embodiments, each of cell 1602, cell 1604, cell 1606 and cell 1608 is a corresponding memory cell.

Memory cell array 1600 is a variation of memory cell array 300 of FIG. 3, and similar detailed description is omitted for brevity. For example, in comparison with FIG. 3, memory cell array 1600 has a common word line (CWL) configuration, and similar detailed description is therefore omitted.

In some embodiments, each cell 1602, 1604, 1606 or 1608 in memory cell array 1600 corresponds to a three transistor (3T) and two resistor (2R) memory cell (e.g., 3T2R) as shown in FIG. 16. Other numbers of transistors or resistors in each memory cell in memory cell array 1600 are within the scope of the present disclosure.

In some embodiments, cell 1602, 1604, 1606 or 1608 is a variation of corresponding cell 302, 304, 306 or 308 of FIG. 3, and similar detailed description is omitted for brevity. In comparison with cell 302, 304, 306 or 308 of FIG. 3, corresponding cell 1602, 1604, 1606 or 1608 of memory cell array 1600 has a CWL configuration, and similar detailed description is therefore omitted.

In comparison with cell 302, 304, 306 or 308 of FIG. 3, the transistors and resistors of each corresponding cell 1602, 1604, 1606 or 1608 of memory cell array 1600 are similar with transistors and resistors of corresponding cell 302, 304, 306 or 308 of FIG. 3, and similar detailed description is therefore omitted.

In some embodiments, cell 1602 includes a transistor 1602a0, a transistor 1602b0, a resistor 1612a, a transistor 1602b1, a resistor 1612b, word line WL0, bit line BL0, cascode gate line CGO and cascode gate line CG1.

In some embodiments, cell 1602 includes a first memory cell (e.g., transistor 1602a0, transistor 1602b0, resistor 1612a) and a second memory cell (e.g., transistor 1602a0, transistor 1602b1, resistor 1612b). In some embodiments, while cell 1602 includes two memory cells, during programming and/or read operations of cell 1602, only a single cell within cell 1602 is configured to store data as a security mechanism associated with PUF.

In some embodiments, each memory cell in the first memory cell or second memory cell of cell 1602 is a 2T1R memory cell.

In some embodiments, cell 1604 includes a transistor 1604a0, a transistor 1604b0, a resistor 1614a, a transistor 1604b1, a resistor 1614b, word line WL1, bit line BL0, cascode gate line CGO and cascode gate line CG1.

In some embodiments, cell 1604 includes a third memory cell (e.g., transistor 1604a0, transistor 1604b0, resistor 1614a) and a fourth memory cell (e.g., transistor 1604a0, transistor 1604b1, resistor 1614b). In some embodiments, while cell 1604 includes two memory cells, during programming and/or read operations of cell 1604, only a single cell within cell 1604 is configured to store data as a security mechanism associated with PUF.

In some embodiments, each memory cell in the third memory cell or fourth memory cell of cell 1604 is a 2T1R memory cell.

In some embodiments, cell 1606 includes a transistor 1606a0, a transistor 1606b0, a resistor 1616a, a transistor 1606b1, a resistor 1616b, word line WL0, bit line BL1, cascode gate line CG2 and cascode gate line CG3.

In some embodiments, cell 1606 includes a fifth memory cell (e.g., transistor 1606a0, transistor 1606b0, resistor 1616a) and a sixth memory cell (e.g., transistor 1606a0, transistor 1606b1, resistor 1616b). In some embodiments, while cell 1606 includes two memory cells, during programming and/or read operations of cell 1606, only a single cell within cell 1606 is configured to store data as a security mechanism associated with PUF.

In some embodiments, each memory cell in the fifth memory cell or sixth memory cell of cell 1606 is a 2T1R memory cell.

In some embodiments, cell 1608 includes a transistor 1608a0, a transistor 1608b0, a resistor 1618a, a transistor 1608b1, a resistor 1618b, word line WL1, bit line BL1, cascode gate line CG2 and cascode gate line CG3.

In some embodiments, cell 1608 includes a seventh memory cell (e.g., transistor 1608a0, transistor 1608b0, resistor 1618a) and an eighth memory cell (e.g., transistor 1608a0, transistor 1608b1, resistor 1618b). In some embodiments, while cell 1608 includes two memory cells, during programming and/or read operations of cell 1608, only a single cell within cell 1608 is configured to store data as a security mechanism associated with PUF.

In some embodiments, each memory cell in the seventh memory cell or eighth memory cell of cell 1608 is a 2T1R memory cell.

In some embodiments, each of a drain of transistor 1602a0, a source of transistor 1602b0 and a source of transistor 1602b1 are coupled together. In some embodiments, each of a drain of transistor 1602b0 and a first end of resistor 1612a are coupled together. In some embodiments, each of a drain of transistor 1602b1 and a first end of resistor 1612b are coupled together.

In some embodiments, each of a drain of transistor 1604a0, a source of transistor 1604b0, and a source of transistor 1604b1 are coupled together. In some embodiments, each of a drain of transistor 160460 and a first end of resistor 1614a are coupled together. In some embodiments, each of a drain of transistor 1604b1 and a first end of resistor 1614b are coupled together.

In some embodiments, each of a drain of transistor 1606a0, a source of transistor 1606b0 and a source of transistor 1606b1 are coupled together. In some embodiments, each of a drain of transistor 1606b0 and a first end of resistor 1616a are coupled together. In some embodiments, each of a drain of transistor 1606b1 and a first end of resistor 1616b are coupled together.

In some embodiments, each of a drain of transistor 1608a0, a source of transistor 1608b0 and a source of transistor 1608b1 are coupled together. In some embodiments, each of a drain of transistor 1 608a1 and a source of transistor 1608b1 are coupled together. In some embodiments, each of a drain of transistor 1608b1 and a first end of resistor 1618b are coupled together.

In some embodiments, two or more of a source of transistor 1602a0, a source of transistor 1606a0, a source of transistor 1604a0, a source of transistor 1608a0 or a voltage reference supply VSS are coupled together.

Each of a gate of transistor 1602a0, a gate of transistor 1606a0 and the word line WL0 are coupled together.

Each of a gate of transistor 1604a0, a gate of transistor 1608a0 and the word line WL1 are coupled together.

Each of a gate of transistor 1602b0, a gate of transistor 1604b0 and the cascode gate line CG0 are coupled together.

Each of a gate of transistor 1602b1, a gate of transistor 1604b1 and the cascode gate line CG1 are coupled together.

Each of a gate of transistor 1606b0, a gate of transistor 1608b0 and the cascode gate line CG2 are coupled together.

Each of a gate of transistor 1606b1, a gate of transistor 1608b1 and the cascode gate line CG3 are coupled together.

Each of a second end of resistor 1614a, a second end of resistor 1612a, a second end of resistor 1614b, a second end of resistor 1612b and the bit line BL0 are coupled together.

Each of a second end of resistor 1618a, a second end of resistor 1616a, a second end of resistor 1618b, a second end of resistor 1616b and the bit line BL1 are coupled together.

Other configurations of memory cell array 1600 are within the scope of the present disclosure.

FIG. 17 is a cross-sectional view of a memory circuit 1700, in accordance with some embodiments.

Memory circuit 1700 is an embodiment of memory cell 1600 of FIG. 16, and similar detailed description is therefore omitted.

In some embodiments, memory circuit 1700 includes metal fuse devices MF1_0 and MF1_1, and WL device 1750a located on a frontside 403a of substrate 490, and select devices 1752a and 1752b located on a backside 403b of substrate 490.

Memory circuit 1700 is a variation of memory circuit 500 of FIG. 5, and similar detailed description is omitted for brevity. In comparison with memory circuit 500 of FIG. 5, memory circuit 1700 does not include WL device 450b (e.g., transistor 304a1), and similar detailed description is omitted for brevity.

In comparison with memory circuit 500 of FIG. 5, WL device 1750a replaces WL device 450a, select device 1752a replaces select device 452a, and select device 1752b replaces select device 452b, and similar detailed description is therefore omitted.

In some embodiments, WL device 1750a is transistor 1604a0, and similar detailed description is therefore omitted.

In some embodiments, select device 1752a is transistor 1604b0, and select device 1752b is transistor 1604b1, and similar detailed description is therefore omitted.

In some embodiments, metal fuse device MF1_0 is resistor 1614a, and metal fuse device MF1_1 is resistor 1614b, and similar detailed description is therefore omitted. In some embodiments, conductor 420a in FIG. 17 is resistor 1614a, and conductor 420b is resistor 1614b, and similar detailed description is therefore omitted.

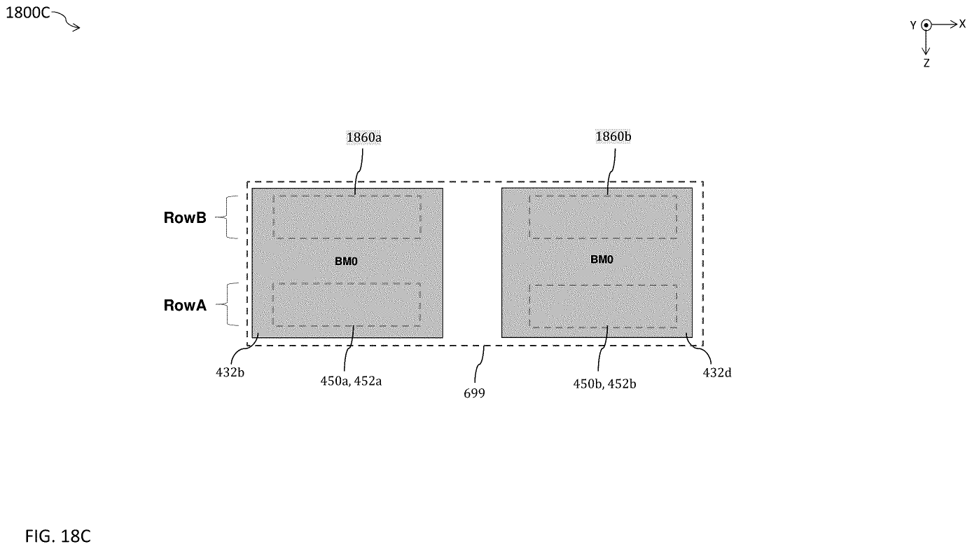

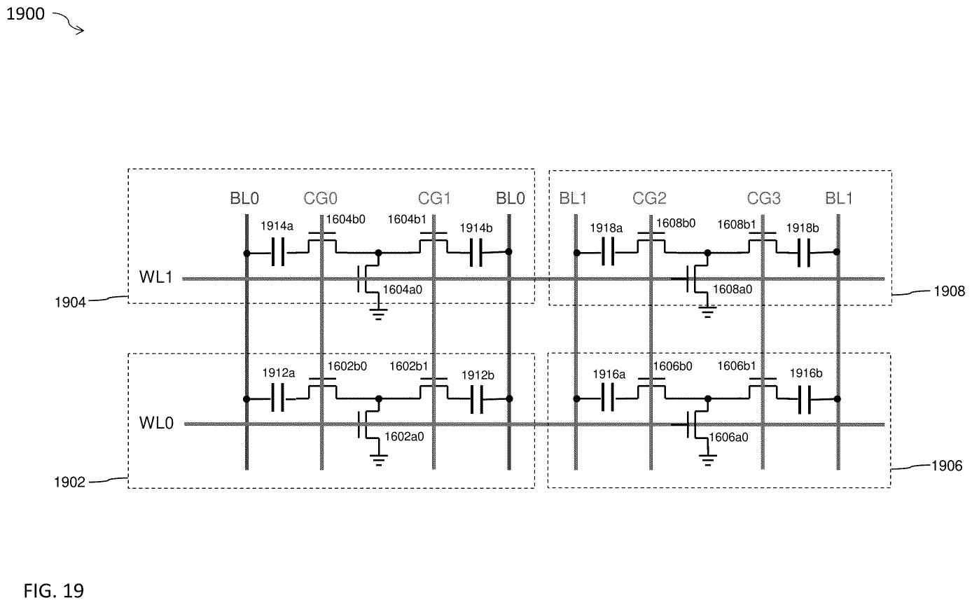

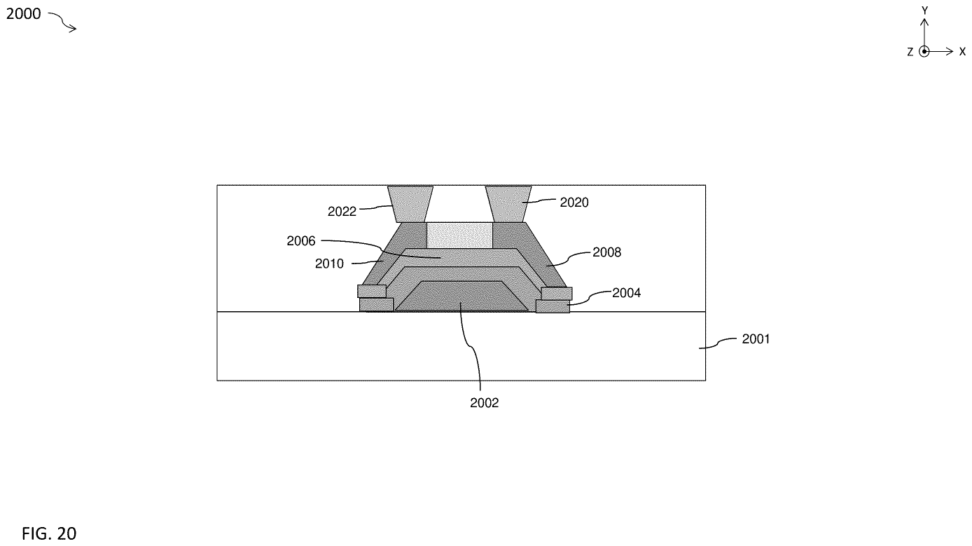

In some embodiments, in one or more of FIG. 17 or 18A, the gate 453a of select transistor 1752a is coupled to conductor 434a by interconnect 454a in a manner similar to that shown in FIG. 4B, and similar detailed description is therefore omitted.

In some embodiments, in one or more of FIG. 17 or 18A, the gate 453b of select transistor 1752b is coupled to conductor 434b by interconnect 454b in a manner similar to that shown in FIG. 4B, and similar detailed description is therefore omitted.

In some embodiments, in one or more of FIG. 17 or 18A, the gate 453a of select transistor 1752a is coupled to a first conductor in the backside metallization layer BMx by an interconnect similar to interconnect 454a (e.g., in the manner shown in FIG. 4B, where conductor 434a is the first conductor and is part of the BMX metallization layer), and the first conductor in the backside metallization layer BMx is configured as the cascode gate line CG0, and similar detailed description is therefore omitted.

In some embodiments, in one or more of FIG. 17 or 18A, the gate 453b of select transistor 1752b is coupled to a second conductor in the backside metallization layer BMx by an interconnect similar to interconnect 454b (e.g., in the manner shown in FIG. 4B, where conductor 434b is the second conductor and is part of the BMX metallization layer), and the second conductor in the backside metallization layer BMx is configured as the cascode gate line CG1, and similar detailed description is therefore omitted.

Memory circuit 1700 includes one or more of select device 1752a, select device 1752b, substrate 490, active regions 402, active regions 502a and 502b, insulating region 401, gate 404a, contacts 406a, 406b, 506a, 506b, 506c, 506d, a set of conductors 1730, vias 410a, 510a, 510b, 510c and 510d, via 412a, set of conductors 532, set of vias 524, set of conductors 420, set of vias 422, a set of conductors 1770, a set of vias 1772, set of conductors 462, set of vias 464 or set of interconnects 460.

In some embodiments, the active region 402 in FIG. 17 has a shorter length in the first direction X than the active region 402 in FIG. 5.

In comparison with memory circuit 500 of FIG. 5, memory circuit 1700 does not include gate 404b, contact 406c, conductor 410b, via 412b, conductor 430c, and similar detailed description is omitted for brevity.

In comparison with memory circuit 500 of FIG. 5, conductor 1730d replaces 530d, and similar detailed description is omitted for brevity.

The set of conductors 1730 includes conductors 530a, 430b and 1730d.

In some embodiments, conductor 1730d is similar to conductor 530d, and similar detailed description is therefore omitted.

Conductor 1730d is electrically coupled to vias 510c and 510d.

The set of conductors 1770 includes conductor 1770a.

In some embodiments, conductor 1770a is similar to conductor 1170a, and similar detailed description is therefore omitted.

Conductor 1770a is electrically coupled to conductors 530a and 1730d by corresponding vias 1772a and 1772b.

The set of vias 1772 includes vias 1772a and 1772b.

In some embodiments, vias 1772a and 1772b are similar to via 442a, and similar detailed description is therefore omitted.

Via 1772a is between and electrically couples corresponding conductor 530a and corresponding conductor 1770a together. Via 1772b is between and electrically couples corresponding conductor 1730d and corresponding conductor 1770a together.

Other configurations, arrangements on other layout levels or quantities of conductors in at least one of set of conductors 1730 or 1770 are within the scope of the present disclosure.

Other configurations, arrangements on other layout levels or quantities of conductors in at least one of set of vias 1772 are within the scope of the present disclosure.

In some embodiments, by positioning the WL device 1750a on the front-side 403a of substrate 490, and by positioning the selection devices 1752a and 1752b on the back-side 403b as PUF cells as well as positioning the fuse devices MF1_0 and MF1_1 on the back-side 403b, memory circuit 1700 has a higher density and/or smaller cell area than other approaches.

In some embodiments, memory circuit 1700 achieves one or more of the benefits described herein.

Other configurations of memory circuit 1700 are within the scope of the present disclosure.

FIG. 18A is a cross-sectional view of a portion 1800A of a memory circuit 1800, in accordance with some embodiments.

FIG. 18B is a cross-sectional view of a portion 1800B of memory circuit 1800, in accordance with some embodiments.

FIG. 18C is a top view of a portion 1800C of memory circuit 1800, in accordance with some embodiments.

Portion 1800A includes each of the elements of memory circuit 1800, but the details of interconnect structures 660a and 660b are not shown in FIG. 18A, but are shown in FIG. 18B.

Portion 1800B includes interconnect structures 660a and 660b and fuse device 699.

FIG. 18C is a top-down view of portion 1800A of FIG. 18A and portion 1800B of FIG. 18B, in accordance with some embodiments.

Portion 1800C includes interconnect structures 660a and 1800b, fuse device 699, select device 1752a, select device 1752b, WL device 1750a, and conductors 432b and 432d.

Portion 1800D includes conductor 620a, conductor 620b, conductor 650a, via 622a and via 622b.

In some embodiments, memory circuit 1800 includes metal fuse devices MF1_0 and MF1_1, and WL devices 1750a located on a front side 403a of substrate 490, and select devices 1752a and 1752b located on a backside 403b of substrate 490.

Memory circuit 1800 is a variation of memory circuit 600 of FIGS. 6A-6D, and memory circuit 1700 of FIG. 17, and similar detailed description is omitted for brevity. For example, memory circuit 1800 includes the features of memory circuit 1700 of FIG. 17 applied to memory circuit 600 of FIGS. 6A-6D and vice versa, and similar detailed description is omitted for brevity.

Memory circuit 1800 is an embodiment of memory cell 1600 of FIG. 16, and similar detailed description is therefore omitted.

Memory circuit 1800 is a variation of memory circuit 600 of FIGS. 6A-6D, and similar detailed description is omitted for brevity. In comparison with memory 600 of FIGS. 6A-6D, memory circuit 1800 does not include WL device 450b (e.g., transistor 304a1), and similar detailed description is omitted for brevity.

In comparison with memory circuit 600 of FIGS. 6A-6D, WL device 1750a replaces WL device 450a, select device 1752a replaces select device 452a, and select device 1752b replaces select device 452b, and similar detailed description is therefore omitted.

In some embodiments, metal fuse device MF1_0 is resistor 1614a, and metal fuse device MF1_1 is resistor 1614b, and similar detailed description is therefore omitted. In some embodiments, conductor 620a in FIG. 18 is resistor 1614a, and conductor 620b is resistor 1614b, and similar detailed description is therefore omitted.

Memory circuit 1800 includes one or more of select device 1752a, select device 1752b, substrate 490, active regions 402, active regions 502a and 502b, insulating region 401, gate 404a, contacts 406a, 406b, 506a, 506b, 506c, 506d, set of conductors 1730, vias 410a, 510a, 510b, 510c and 510d, via 412a, set of conductors 532, set of vias 524, set of conductors 620, set of vias 622, set of conductors 650, set of conductors 1770 and set of vias 1772, interconnect structure 660a, interconnect structure 660b, set of conductors 462 or set of vias 664.

In some embodiments, the active region 402 in FIG. 18A has a shorter length in the first direction X than the active region 402 in FIG. 5. In some embodiments, the active region 402 is separated from one or more of active regions 502a or 502b by a corresponding shallow trench isolation (STI) structure.

In comparison with memory circuit 600 of FIGS. 6A-6D, memory circuit 1800 does not include gate 404b, contact 406c, conductor 410b, via 412b, conductor 430c, and similar detailed description is omitted for brevity.

In comparison with memory circuit 600 of FIGS. 6A-6D, conductor 1730d replaces 530d, and similar detailed description is omitted for brevity.

In some embodiments, by moving the fuse structure 699 to the frontside 403a of substrate 490, memory circuit 1800 has additional flexibility compared to other approaches.

In some embodiments, memory circuit 1800 achieves one or more of the benefits described herein.

Other configurations of memory circuit 1800 are within the scope of the present disclosure.

FIG. 19 is a schematic diagram of a memory cell array 1900, in accordance with some embodiments.

Memory cell array 1900 is an embodiment of memory cell array 200 of FIG. 2, and similar detailed description is therefore omitted.

In some embodiments, memory cell array 1900 is an array of eFuse Rfuse OTP memory cells.

Memory cell array 1900 comprises a cell 1902, a cell 1904, a cell 1906 and a cell 1908.

In some embodiments, each of cell 1902, cell 1904, cell 1906 and cell 1908 is a corresponding eFuse Rfuse OTP memory cell. In some embodiments, each of cell 1902, cell 1904, cell 1906 and cell 1908 is a corresponding memory cell.

Memory cell array 1900 is a variation of memory cell array 1600 of FIG. 16, and similar detailed description is omitted for brevity. In comparison with FIG. 16, capacitors of memory cell array 1900 replace corresponding resistors of memory cell array 1600, and similar detailed description is therefore omitted.

In some embodiments, each cell 1902, 1904, 1906 or 1908 in memory cell array 1900 corresponds to a three transistor (3T) and two capacitor (2C) memory cell (e.g., 3T2C) as shown in FIG. 19. Other numbers of transistors or capacitors in each memory cell in memory cell array 1900 are within the scope of the present disclosure.

In some embodiments, cell 1902, 1904, 1906 or 1908 is a variation of corresponding cell 1602, 1604, 1606 or 1608 of FIG. 3, and similar detailed description is omitted for brevity. In comparison with FIG. 16, capacitors 1912a, 1912b, 1914a, 1914b, 1916a, 1916b, 1918a and 1918b of memory cell array 1900 replace corresponding resistors 1612a, 1612b, 1614a, 1614b, 1616a, 1616b, 1618a and 1618b of memory cell array 1600, and similar detailed description is therefore omitted.

In comparison with cell 1602, 1604, 1606 or 1608 of FIG. 16, the transistors of each corresponding cell 1902, 1904, 1906 or 1908 of memory cell array 1900 are similar with transistors and resistors of corresponding cell 1602, 1604, 1606 or 1608 of FIG. 16, and similar detailed description is therefore omitted.

In some embodiments, cell 1902 includes a transistor 1602a0, a transistor 1602b0, a capacitor 1912a, a transistor 1602b1, a capacitor 1912b, word line WL0, bit line BL0, cascode gate line CGO and cascode gate line CG1.

In some embodiments, cell 1902 includes a first memory cell (e.g., transistor 1602a0, transistor 1602b0, capacitor 1912a) and a second memory cell (e.g., transistor 1602a0, transistor 1602b1, capacitor 1912b). In some embodiments, while cell 1902 includes two memory cells, during programming and/or read operations of cell 1902, only a single cell within cell 1902 is configured to store data as a security mechanism associated with PUF.

In some embodiments, each memory cell in the first memory cell or second memory cell of cell 1902 is a 2T1C memory cell.

In some embodiments, cell 1904 includes a transistor 1604a0, a transistor 1604b0, a capacitor 1914a, a transistor 1604b1, a capacitor 1914b, word line WL1, bit line BL0, cascode gate line CGO and cascode gate line CG1.

In some embodiments, cell 1904 includes a third memory cell (e.g., transistor 1604a0, transistor 1604b0, capacitor 1914a) and a fourth memory cell (e.g., transistor 1604a0, transistor 1604b1, capacitor 1914b). In some embodiments, while cell 1904 includes two memory cells, during programming and/or read operations of cell 1904, only a single cell within cell 1904 is configured to store data as a security mechanism associated with PUF.

In some embodiments, each memory cell in the third memory cell or fourth memory cell of cell 1904 is a 2T1C memory cell.

In some embodiments, cell 1906 includes a transistor 1606a0, a transistor 1606b0, a capacitor 1916a, a transistor 1606b1, a capacitor 1916b, word line WL0, bit line BL1, cascode gate line CG2 and cascode gate line CG3.

In some embodiments, cell 1906 includes a fifth memory cell (e.g., transistor 1606a0, transistor 1606b0, capacitor 1916a) and a sixth memory cell (e.g., transistor 1606a0, transistor 1606b1, capacitor 1916b). In some embodiments, while cell 1906 includes two memory cells, during programming and/or read operations of cell 1906, only a single cell within cell 1906 is configured to store data as a security mechanism associated with PUF.

In some embodiments, each memory cell in the fifth memory cell or sixth memory cell of cell 1906 is a 2T1C memory cell.

In some embodiments, cell 1908 includes a transistor 1608a0, a transistor 1608b0, a capacitor 1918a, a transistor 1608b1, a capacitor 1918b, word line WL1, bit line BL1, cascode gate line CG2 and cascode gate line CG3.

In some embodiments, cell 1908 includes a seventh memory cell (e.g., transistor 1608a0, transistor 1608b0, capacitor 1918a) and an eighth memory cell (e.g., transistor 1608a0, transistor 1608b1, capacitor 1918b). In some embodiments, while cell 1908 includes two memory cells, during programming and/or read operations of cell 1908, only a single cell within cell 1908 is configured to store data as a security mechanism associated with PUF.

In some embodiments, each memory cell in the seventh memory cell or eighth memory cell of cell 1908 is a 2T1C memory cell.

In some embodiments, each of a drain of transistor 1602b0 and a first end of capacitor 1912a are coupled together. In some embodiments, each of a drain of transistor 1602b1 and a first end of capacitor 1912b are coupled together.

In some embodiments, each of a drain of transistor 1604b0 and a first end of capacitor 1914a are coupled together. In some embodiments, each of a drain of transistor 1604b1 and a first end of capacitor 1914b are coupled together.

In some embodiments, each of a drain of transistor 1606b0 and a first end of capacitor 1916a are coupled together. In some embodiments, each of a drain of transistor 1606b1 and a first end of capacitor 1916b are coupled together.

In some embodiments, each of a drain of transistor 1 608a1 and a source of transistor 1608b1 are coupled together. In some embodiments, each of a drain of transistor 1608b1 and a first end of capacitor 1918b are coupled together.

Each of a second end of capacitor 1914a, a second end of capacitor 1912a, a second end of capacitor 1914b, a second end of capacitor 1912b and the bit line BL0 are coupled together.

Each of a second end of capacitor 1918a, a second end of capacitor 1916a, a second end of capacitor 1918b, a second end of capacitor 1916b and the bit line BL1 are coupled together.

Other configurations of memory cell array 1900 are within the scope of the present disclosure.

FIG. 20 is a cross-sectional view of a memory cell device 2000, in accordance with some embodiments.

Memory circuit 2000 is an embodiment of memory cell 1600 of FIG. 16A, and similar detailed description is therefore omitted.

Memory cell device 2000 is usable as part or all of one or more of select devices 452a, 452b, 1752a or 1752b, or word line device 1152b discussed herein, and similar detailed description is therefore omitted.

Memory cell device 2000 is usable as part or all of one or more memory cells of the memory cell arrays discussed herein, and similar detailed description is therefore omitted.

In some embodiments, memory cell device is a 1-bit Indium Gallium Zinc Oxide (IGZO) thin film transistor (TFT). Other transistor types are within the scope of the present disclosure.

Memory cell device 2000 includes a gate layer 2002. In some embodiments, gate layer 2002 includes a conductive material.

In some embodiments, gate layer 2002 includes TiN or the like. In some embodiments, gate layer 2002 includes polysilicon, LTPS, a-Si TFT, IGZO or semiconductor material, or combinations thereof, or the like. In some embodiments, gate layer 2002 corresponds to word line WL0 or WL1. In some embodiments, word line WL0 or WL1 includes polysilicon, LTPS, a-Si TFT, IGZO or semiconductor material, or combinations thereof, or the like.

Memory cell device 2000 further includes an insulating layer 2001 below gate layer 2002. In some embodiments, the insulating layer 2001 is an oxide or the like.

Memory cell device 2000 further includes an insulating layer 2004. In some embodiments, the insulating layer 2004 is over the gate layer 2002. In some embodiments, insulating layer 2004 includes a High-K dielectric. In some embodiments, the High-K dielectric includes HfO2, or the like.

Memory cell device 2000 further includes a channel 2006. In some embodiments, channel 2006 extends between the source 2008 and drain 2010. In some embodiments, at least channel 2006 includes a conductive material. In some embodiments, at least channel 2006 includes polysilicon, LTPS, a-Si TFT, IGZO or semiconductor material, or combinations thereof, or the like.

Memory cell device 2000 further includes a source 2008 and a drain 2010 on channel layer 2006. The source 2008 and drain 2010 are below channel layer 2006. In some embodiments, at least source 2008 or drain 2010 includes a conductive material. In some embodiments, a conductive material includes doped polysilicon, TiN, W, Cu, Co, Ru, or combinations thereof, or the like.

Memory cell device 2000 further includes a via 2020 and a via 2022.

Via 2020 is on and electrically connected to source 2008.

Via 2022 is on and electrically connected to drain 2010.

At least one of via 2020 or 2022 is a conductive material, a metal, a metal compound or a doped semiconductor. In some embodiments, the conductive material includes Tungsten, Cobalt, Ruthenium, Copper, or the like or combinations thereof. In some embodiments, a metal includes at least Cu (Copper), Co, W, Ru, Al, or the like. In some embodiments, a metal compound includes at least AlCu, W-TiN, TiSix, NiSix, TiN, TaN, or the like. In some embodiments, a doped semiconductor includes at least doped silicon, or the like.

In some embodiments, one or more layers of memory cell device 2000 are not included. In some embodiments, one or more layers of memory cell device 2000 are divided into multiple layers.

In some embodiments, memory cell device 2000 achieves one or more of the benefits described herein.

Other configurations of memory cell device 2000 are within the scope of the present disclosure.

FIGS. 21A-21C are corresponding functional flow charts of a corresponding method 2100A-2100C of manufacturing an IC device, in accordance with some embodiments. It is understood that additional operations may be performed before, during, and/or after the method 2100A depicted in FIG. 21A, and that some other processes may only be briefly described herein.

It is understood that additional operations may be performed before, during, and/or after the method 2100B depicted in FIG. 21B, and that some other processes may only be briefly described herein.

It is understood that additional operations may be performed before, during, and/or after the method 2100C depicted in FIG. 21C, and that some other processes may only be briefly described herein.

In some embodiments, other order of operations of method 2100A, 2100B, 2100C or 2200 is within the scope of the present disclosure. Method 2100A, 2100B, 2100C or 2200 includes exemplary operations, but the operations are not necessarily performed in the order shown. Operations may be added, replaced, changed order, and/or eliminated as appropriate, in accordance with the spirit and scope of disclosed embodiments. In some embodiments, one or more of the operations of at least method 2100A, 2100B, 2100C or 2200 is not performed.

In some embodiments, the methods 2100A and 2100B are usable to manufacture or fabricate one or more of memory device 100, memory cell array 200, 300, 802, 902, 1600 or 1900, memory cell 1000A, 1200A, 1300, 1400 or 1500 or memory circuit 400, 500, 600, 700, 1100, 1700, 1800 or 2000, or an integrated circuit with similar features.

In operation 2102 of method 2100A-2100B, a first set of transistors are fabricated on a front-side 403a of a semiconductor wafer 490 or substrate. In some embodiments, the first set of transistors of method 2100A-2100B includes one or more transistors in at least the active regions 402, 502a or 502b or the set of dummy transistors in the interconnect structure 660a, 660b or 760b. In some embodiments, the first set of transistors of method 2100A-2100B includes one or more of WL device 450a or 450b or 1750a or select device 1150a. In some embodiments, the first set of transistors of method 2100A-2100B includes one or more transistors described herein.

In some embodiments, operation 2102 includes fabricating source and drain regions of the set of transistors in a first well. In some embodiments, the first well comprises p-type dopants. In some embodiments, the p-dopants include boron, aluminum or other suitable p-type dopants. In some embodiments, the first well comprises an epi-layer grown over a substrate. In some embodiments, the epi-layer is doped by adding dopants during the epitaxial process. In some embodiments, the epi-layer is doped by ion implantation after the epi-layer is formed. In some embodiments, the first well is formed by doping the substrate. In some embodiments, the doping is performed by ion implantation. In some embodiments, the first well has a dopant concentration ranging from 1×2112 atoms/cm³ to 1×10¹⁴atoms/cm³.

In some embodiments, the first well comprises n-type dopants. In some embodiments, the n-type dopants include phosphorus, arsenic or other suitable n-type dopants. In some embodiments, the n-type dopant concentration ranges from about 1×2112 atoms/cm³ to about 1×10¹⁴ atoms/cm³.

In some embodiments, the formation of the source/drain features includes, a portion of the substrate is removed to form recesses at an edge of spacers, and a filling process is then performed by filling the recesses in the substrate. In some embodiments, the recesses are etched, for example, a wet etching or a dry etching, after removal of a pad oxide layer or a sacrificial oxide layer. In some embodiments, the etch process is performed to remove a top surface portion of the active region adjacent to an isolation region, such as an STI region. In some embodiments, the filling process is performed by an epitaxy or epitaxial (epi) process. In some embodiments, the recesses are filled using a growth process which is concurrent with an etch process where a growth rate of the growth process is greater than an etch rate of the etch process. In some embodiments, the recesses are filled using a combination of growth process and etch process. For example, a layer of material is grown in the recess and then the grown material is subjected to an etch process to remove a portion of the material. Then a subsequent growth process is performed on the etched material until a desired thickness of the material in the recess is achieved. In some embodiments, the growth process continues until a top surface of the material is above the top surface of the substrate. In some embodiments, the growth process is continued until the top surface of the material is co-planar with the top surface of the substrate. In some embodiments, a portion of the first well is removed by an isotropic or an anisotropic etch process. The etch process selectively etches the first well without etching a gate structure and any spacers. In some embodiments, the etch process is performed using a reactive ion etch (RIE), wet etching, or other suitable techniques. In some embodiments, a semiconductor material is deposited in the recesses to form the source/drain features. In some embodiments, an epi process is performed to deposit the semiconductor material in the recesses. In some embodiments, the epi process includes a selective epitaxy growth (SEG) process, CVD process, molecular beam epitaxy (MBE), other suitable processes, and/or combination thereof. The epi process uses gaseous and/or liquid precursors, which interacts with a composition of substrate. In some embodiments, the source/drain features include epitaxially grown silicon (epi Si), silicon carbide, or silicon germanium. Source/drain features of the IC device associated with the gate structure are in-situ doped or undoped during the epi process in some instances. When source/drain features are undoped during the epi process, source/drain features are doped during a subsequent process in some instances. The subsequent doping process is achieved by an ion implantation, plasma immersion ion implantation, gas and/or solid source diffusion, other suitable processes, and/or combination thereof. In some embodiments, source/drain features are further exposed to annealing processes after forming source/drain features and/or after the subsequent doping process.

In some embodiments, operation 2102 further includes operation 2102a. In some embodiments, operation 2102a includes forming a first gate region of the first set of transistors. In some embodiments, the first gate region of the first set of transistors of method 2100A-2100B includes gates 404, 404b, 453a or 453b.

In some embodiments, operation 2102 further includes operation 2102b. In some embodiments, operation 2102b includes forming a first insulating material on a first gate structure of the first set of transistors. In some embodiments, operation 2102b includes forming a first insulating material over at least the first gate structure of the first gate regions of the first set of transistors. In some embodiments, the first insulating material includes an insulating region similar to insulating region 401. In some embodiments, operation 2102b is not performed.

In some embodiments, operation 2102 further includes operation 2102c. In some embodiments, operation 2102c includes forming a second gate region of the first set of transistors. In some embodiments, the second gate regions of the first set of transistors of method 2100A-2100B include gates 404a, 404b, 453a or 453b. In some embodiments, operations 2102a and 2102c are performed at the same time.

In some embodiments, the first and second gate region is between the drain region and the source region. In some embodiments, the first and second gate region is over the first well and the substrate. In some embodiments, fabricating the first and second gate regions of operations 2102a and 2102c include performing one or more deposition processes to form one or more dielectric material layers. In some embodiments, a deposition process includes a chemical vapor deposition (CVD), a plasma enhanced CVD (PECVD), an atomic layer deposition (ALD), or other process suitable for depositing one or more material layers. In some embodiments, fabricating the first and second gate regions includes performing one or more deposition processes to form one or more conductive material layers. In some embodiments, fabricating the first and second gate regions includes forming gate electrodes or dummy gate electrodes. In some embodiments, fabricating the gate regions includes depositing or growing at least one dielectric layer, e.g., gate dielectric. In some embodiments, gate regions are formed using a doped or non-doped polycrystalline silicon (or polysilicon). In some embodiments, the first and second gate regions include a metal, such as Al, Cu, W, Ti, Ta, TiN, TaN, NiSi, CoSi, other suitable conductive materials, or combinations thereof.

In some embodiments, forming the first insulating material on the first gate structure of the first set of transistors of operation 2102b includes performing one or more deposition processes to form one or more dielectric material layers and/or insulating material layers. In some embodiments, the one or more deposition processes to form one or more dielectric material layers and/or insulating material layers includes CVD, a PECVD, ALD, or other process suitable for depositing one or more material layers. In some embodiments, forming the first insulating material on the first gate structure of the first set of transistors includes performing one or more deposition processes to form one or more insulating material layers. In some embodiments, the first insulating material is a dielectric material. In some embodiments, the dielectric material includes silicon dioxide, silicon oxy-nitride, or the like.

In some embodiments, operation 2102a, 2102b and 2102c are replaced by forming the first gate regions of the first set of transistors and the second gate regions of the first set of transistors, removing a portion of the first gate regions of the first set of transistors and the second gate regions of the first set of transistors, and forming the first insulating material between the first gate structure of the first set of transistors and the second gate structure of the first set of transistors. In some embodiments, the gate removal process is a POLY cut process that includes one or more etching processes. In some embodiments, the gate removal process includes one or more etching processes suitable to remove a portion of the gate structure. In some embodiments, a mask is used to specify portions of the gate structure that are to be cut or removed. In some embodiments the mask is a hard mask. In some embodiments, the mask is a soft mask. In some embodiments, etching corresponds to plasma etching, reactive ion etching, chemical etching, dry etching, wet etching, other suitable processes, any combination thereof, or the like.

In some embodiments, the gate removal process of operations 2102a, 2102b or 2102c also include the formation of the gates 404a or 404b, and the cut regions are identified by a set of cut feature patterns (not shown).

In some embodiments, the set of gates of method 2100A-2100B includes one or more portions of at least a gate of interconnect 660a, 660b or 760b.

In some embodiments, operation 2102 further includes operation 2102d. In some embodiments, operation 2102d includes depositing a conductive material on at least one of a first level, a second level or a third level thereby forming at least one of a corresponding set of contacts.

In some embodiments, the set of contacts are part of the first set of transistors.

In some embodiments, the set of contacts includes one or more contacts of the set of contacts 406 or 506.

In some embodiments, the set of contacts of method 2100A-2100B includes one or more portions of at least a contact of interconnect 660a, 660b or 760b.

In operation 2104 of method 2100A-2100B, a first set of vias are formed on the front-side 403a of the a wafer or substrate on a VD level or a VG level (e.g., VD or VG). In some embodiments, the first set of vias of method 2100A-2100B includes one or more portions of at least the set of vias 410, 412 or 510.

In some embodiments, the first set of vias of method 2100A-2100B includes one or more portions of at least a via of interconnect 660a, 660b or 760b.

In some embodiments, operation 2104 includes forming a first set of self-aligned contacts (SACs) in the insulating layer over the front-side 403a of the wafer. In some embodiments, the first set of vias is electrically coupled to at least the first set of transistors.

In operation 2106 of method 2100A-2100B, a first conductive material is deposited on the front-side 403a of the substrate on a first metal level thereby forming a first set of conductors on the front-side 403a of the wafer or substrate on a first metal level (e.g., MO).

In some embodiments, operation 2106 includes at least depositing a first set of conductive regions over the front-side 403a of the integrated circuit. In some embodiments, the first set of conductors of method 2100A-2100B includes one or more portions of at least the set of conductors 430, 530, 1130 or 1730.

In some embodiments, the first set of conductors includes a word line WL1, WL2 or a cascode gate line CG1.

In some embodiments, the first set of conductors of method 2100A-2100B includes one or more portions of at least a conductor of interconnect 660a, 660b or 760b.

In some embodiments, the first set of conductors is electrically coupled to at least the first set of transistors by the first set of vias. In some embodiments, the first set of transistors is configured to receive a first word line signal on the first word line or a first cascode gate line signal on the first cascode gate line from the front-side.

In operation 2108 of method 2100A-2100B, a first interconnect structure is formed on the front-side 403a of the substrate.

In some embodiments, the first interconnect structure is coupled to at least the first set of dummy transistors.

In some embodiments, the first interconnect structure of method 2100A-2100B includes one or more portions of at least interconnect 660a, 660b or 760b.

In some embodiments, the first interconnect structure of method 2100A-2100B includes one or more portions of elements in at least the V0, M1, V1, M2, V2, M3, V3 or M4.

In operation 2110a of method 2100A-2100B, a first set of storage elements is fabricated on the front-side of the substrate.

In some embodiments, the first set of storage elements of method 2100A-2100B includes a set of fuse elements or a set of capacitor elements. In some embodiments, the set of fuse elements includes metal fuse devices MF1_0 and MF1_1.

In some embodiments, the set of fuse elements includes the set of conductors 620 or 650 and are formed on the frontside of the substrate.

In some embodiments, the set of capacitor elements includes one or more of capacitors 1912a, 1912b, 1914a, 1914b, 1916a, 1916b, 1918a or 1918b.

In some embodiments, the first set of fuse elements is coupled to the first set of transistors.

In operation 2112 of method 2100A-2100B, thinning is performed on the back-side 403b of the wafer or substrate. In some embodiments, operation 2110 includes a thinning process performed on the back-side 403b of the semiconductor wafer or substrate. In some embodiments, the thinning process includes a grinding operation and a polishing operation (such as chemical mechanical polishing (CMP)) or other suitable processes. In some embodiments, after the thinning process, a wet etching operation is performed to remove defects formed on the back-side 403b of the semiconductor wafer or substrate.

In operation 2114 of method 2100A-2100B, a first set of back-side vias are formed through the back-side of the substrate to the front-side of the substrate on a BVD level or a BVG level (e.g., BVD or BVG) or a VB level.

In some embodiments, the first set of back-side vias of method 2100A-2100B includes one or more portions of at least the set of vias 424 or 524.

In some embodiments, the first set of back-side vias of method 2100A-2100B includes one or more portions of at least a via of interconnect 660a, 660b or 760b.

In some embodiments, the first set of back-side vias is electrically coupled to at least the first set of transistors or the first set of dummy transistors.

In some embodiments, operation 2114 includes forming a second set of self-aligned contacts (SACs) in the insulating layer through the back-side 403b of the wafer.

In operation 2116 of method 2100A-2100B, a second conductive material is deposited on the back-side 403b of the substrate on a second metal level thereby forming a second set of conductors on the back-side 403b of the wafer or substrate on a second metal level (e.g., BM0).

In some embodiments, operation 2116 includes at least depositing a second set of conductive regions over the back-side 403b of the integrated circuit. In some embodiments, the second set of conductors of method 2100A-2100B includes one or more portions of at least the set of conductors 432, 434, 532, 632 or 1132.

In some embodiments, the second set of conductors is electrically coupled to the second set of transistors, and to the first set of transistors by the first set of back-side vias.

In operation 2117a of method 2100A-2100B, a second set of transistors are fabricated on the back-side 403b of the semiconductor wafer 490 or substrate.

In some embodiments, the second set of transistors of method 2100A-2100B includes one or more transistors of select device 452a, 452b, 1752a or 1752b or WL device 1152b. In some embodiments, the second set of transistors of method 2100A-2100B includes one or more transistors described herein.

In some embodiments, the second set of transistors of method 2100A-2100B includes memory circuit 2000.

In operation 2118a of method 2100A-2100B, a second set of back-side vias are formed on the back-side of the substrate on a BV0 level or a BV1 or BV2 level.

In some embodiments, the second set of back-side vias of method 2100A-2100B includes one or more portions of at least the set of vias 664.

In some embodiments, the second set of back-side vias is electrically coupled to at least the second set of transistors.

In some embodiments, operation 2118a includes forming a third set of self-aligned contacts (SACs) in the insulating layer on the back-side 403b of the wafer.

In operation 2119a of method 2100A-2100B, a third conductive material is deposited on the back-side 403b of the substrate on a third metal level thereby forming a third set of conductors on the back-side 403b of the wafer or substrate on a third metal level (e.g., BM1, BM2 or BM3).

In some embodiments, operation 2119a includes at least depositing a third set of conductive regions over the back-side 403b of the integrated circuit. In some embodiments, the third set of conductors of method 2100A-2100B includes one or more portions of at least the set of conductors 462.

In some embodiments, the third set of conductors is electrically coupled to the second set of transistors by the second set of back-side vias.

FIG. 21B is a functional flow chart of method 2100B of manufacturing an IC device, in accordance with some embodiments.

In some embodiments, one or more operations of method 2100B is an embodiment of one or more operations of method 2100A of FIG. 21A, and similar detailed description is omitted for brevity. In some embodiments, method 2100B is usable to form one or more of V0, M1, V1, M2, V2, M3, V3 or M4 in combination with method 2100A, and similar detailed description is omitted for brevity.

It is understood that additional operations may be performed before, during, and/or after the method 2100B depicted in FIG. 21B, and that some other processes may only be briefly described herein.

In some embodiments, one or more of operations 2120-2134 of method 2100B is an embodiment of operation 2108 of method 1200.

In some embodiments, one or more of operations 2126-2134 of method 2100B is an embodiment of operation 2110 of method 1200.

In some embodiments, one or more of the operations of method 2100A-2100B or 2200 is not performed.

In operation 2120 of method 2100A-2100B, a second set of vias are formed on the front-side of the substrate on a VO level (e.g., VO).

In some embodiments, the second set of vias of method 2100A-2100B includes one or more portions of at least the set of vias 442, 1172 or 1772.

In some embodiments, the second set of vias of method 2100A-2100B includes one or more VO vias of interconnect 660a, 660b or 760b.

In some embodiments, the second set of vias is electrically coupled to at least the first set of conductors.

In some embodiments, operation 2120 includes forming a third set of SACs in the insulating layer on the front-side 403a of the wafer.

In operation 2122 of method 2100A-2100B, a third conductive material is deposited on the front-side 403a of the substrate on a third metal level thereby forming a third set of conductors on the front-side 403a of the wafer or substrate on a third metal level (e.g., M1).

In some embodiments, operation 2122 includes at least depositing a third set of conductive regions over the front-side 403a of the integrated circuit. In some embodiments, the third set of conductors of method 2100A-2100B includes one or more portions of at least the set of conductors 430, 530, 1130 or 1730.

In some embodiments, the third set of conductors of method 2100A-2100B includes one or more portions of at least a conductor of interconnect 660a, 660b or 760b.

In some embodiments, the third set of conductors is electrically coupled to at least the first set of conductors by the second set of vias.

In operation 2124 of method 2100A-2100B, a third set of vias are formed on the front-side of the substrate on a V1 level (e.g., V1).

In some embodiments, the third set of vias of method 2100A-2100B includes one or more portions of at least the set of vias 1174.

In some embodiments, the third set of vias of method 2100A-2100B includes one or more V1 vias of interconnect 660a, 660b or 760b.

In some embodiments, the third set of vias is electrically coupled to at least the third set of conductors.

In some embodiments, operation 2124 includes forming a fourth set of SACs in the insulating layer on the front-side 403a of the wafer.

In operation 2126 of method 2100A-2100B, a fourth conductive material is deposited on the front-side 403a of the substrate on a fourth metal level thereby forming a fourth set of conductors on the front-side 403a of the wafer or substrate on a fourth metal level (e.g., M2).

In some embodiments, operation 2126 includes at least depositing a fourth set of conductive regions over the front-side 403a of the integrated circuit. In some embodiments, the fourth set of conductors of method 2100A-2100B includes one or more portions of at least the set of conductors 620.

In some embodiments, the fourth set of conductors of method 2100A-2100B includes one or more portions of at least a conductor of interconnect 660a, 660b or 760b.

In some embodiments, the fourth set of conductors is electrically coupled to at least the third set of conductors by the third set of vias.

In operation 2128 of method 2100A-2100B, a fourth set of vias are formed on the front-side of the substrate on a V2 level (e.g., V2).

In some embodiments, the fourth set of vias of method 2100A-2100B includes one or more portions of at least the set of vias 622.

In some embodiments, the fourth set of vias of method 2100A-2100B includes one or more V2 vias of interconnect 660a, 660b or 760b.

In some embodiments, the fourth set of vias is electrically coupled to at least the fourth set of conductors.

In some embodiments, operation 2128 includes forming a fifth set of SACs in the insulating layer on the front-side 403a of the wafer.

In operation 2130 of method 2100A-2100B, a fifth conductive material is deposited on the front-side 403a of the substrate on a fifth metal level thereby forming a fifth set of conductors on the front-side 403a of the wafer or substrate on a fifth metal level (e.g., M3).

In some embodiments, operation 2130 includes at least depositing a fifth set of conductive regions over the front-side 403a of the integrated circuit. In some embodiments, the fifth set of conductors of method 2100A-2100B includes one or more portions of at least the set of conductors 650.

In some embodiments, the fifth set of conductors of method 2100A-2100B includes one or more portions of at least a conductor of interconnect 660a, 660b or 760b.

In some embodiments, the fifth set of conductors is electrically coupled to at least the fourth set of conductors by the fourth set of vias.

In operation 2132 of method 2100A-2100B, a fifth set of vias are formed on the front-side of the substrate on a V3 level (e.g., V3).

In some embodiments, the fifth set of vias of method 2100A-2100B includes one or more portions of via 722b.

In some embodiments, the fifth set of vias of method 2100A-2100B includes one or more V3 vias of interconnect 660a, 660b or 760b.

In some embodiments, the fifth set of vias is electrically coupled to at least the fifth set of conductors.

In some embodiments, operation 2132 includes forming a sixth set of SACs in the insulating layer on the front-side 403a of the wafer.

In operation 2134 of method 2100A-2100B, a sixth conductive material is deposited on the front-side 403a of the substrate on a sixth metal level thereby forming a sixth set of conductors on the front-side 403a of the wafer or substrate on a sixth metal level (e.g., M4).

In some embodiments, operation 2134 includes at least depositing a sixth set of conductive regions over the front-side 403a of the integrated circuit. In some embodiments, the sixth set of conductors of method 2100A-2100B includes one or more portions of conductor 720b.

In some embodiments, the sixth set of conductors of method 2100A-2100B includes one or more portions of at least a conductor of interconnect 660a, 660b or 760b.

In some embodiments, the sixth set of conductors is electrically coupled to at least the fifth set of conductors by the fifth set of vias.

In some embodiments, one or more of operations 2102, 2104, 2106, 2108, 2110, 2114, 2116, 2118, 2120, 2122, 2124, 2126, 2128, 2130 or 2134 of method 2100A-2100B include using a combination of photolithography and material removal processes to form openings in an insulating layer (not shown) over the substrate. In some embodiments, the photolithography process includes patterning a photoresist, such as a positive photoresist or a negative photoresist. In some embodiments, the photolithography process includes forming a hard mask, an antireflective structure, or another suitable photolithography structure. In some embodiments, the material removal process includes a wet etching process, a dry etching process, an RIE process, laser drilling or another suitable etching process. The openings are then filled with conductive material, e.g., copper, aluminum, titanium, nickel, tungsten, or other suitable conductive material. In some embodiments, the openings are filled using CVD, PVD, sputtering, ALD or other suitable formation process.

In some embodiments, the conductive material includes copper, aluminum, titanium, nickel, tungsten, or other suitable conductive material. In some embodiments, the openings and trench are filled using CVD, PVD, sputtering, ALD or other suitable formation process. In some embodiments, after conductive material is deposited in one or more of operations 2102, 2104, 2106, 2108, 2110, 2114, 2116, 2118, 2120, 2122, 2124, 2126, 2128, 2130 or 2134, the conductive material is planarized to provide a level surface for subsequent steps.

FIG. 21C is a functional flow chart of method 2100C of manufacturing an IC device, in accordance with some embodiments.

It is understood that additional operations may be performed before, during, and/or after the method 2100C depicted in FIG. 21C, and that some other processes may only be briefly described herein.

In some embodiments, the methods 2100B and 2100C are usable to manufacture or fabricate one or more of memory device 100, memory cell array 200, 300, 802, 902, 1600 or 1900, memory cell 1000A, 1200A, 1300, 1400 or 1500 or memory circuit 400, 500, 600, 700, 1100, 1700, 1800 or 2000, or an integrated circuit with similar features.

In operation 2102 of method 2100C & 2100B, a first set of transistors are fabricated on a front-side 403a of a semiconductor wafer 490 or substrate. In some embodiments, the first set of transistors of method 2100C & 2100B includes one or more transistors in at least the active regions 402, 502a or 502b or the set of dummy transistors in the interconnect structure 660a, 660b or 760b. In some embodiments, the first set of transistors of method 2100C & 2100B includes one or more of WL device 450a, 450b or 1750a. In some embodiments, the first set of transistors of method 2100C & 2100B includes one or more transistors described herein.

In some embodiments, operation 2102 of method 2100C & 2100B is similar to method 2100A-2100B, and similar detailed description is omitted.

In operation 2104 of method 2100C & 2100B, a first set of vias are formed on the front-side 403a of the a wafer or substrate on a VD level or a VG level (e.g., VD or VG). In some embodiments, the first set of vias of method 2100C & 2100B includes one or more portions of at least the set of vias 410, 412 or 510.

In some embodiments, the first set of vias of method 2100C & 2100B includes one or more portions of at least a via of interconnect 660a, 660b or 760b.

In some embodiments, operation 2104 of method 2100C & 2100B is similar to method 2100A-2100B, and similar detailed description is omitted.

In operation 2106 of method 2100C & 2100B, a first conductive material is deposited on the front-side 403a of the substrate on a first metal level thereby forming a first set of conductors on the front-side 403a of the wafer or substrate on a first metal level (e.g., MO).

In some embodiments, the first set of conductors of method 2100C & 2100B includes one or more portions of at least the set of conductors 430, 530, 1130 or 1730.

In some embodiments, the first set of conductors includes a word line WL1, WL2.

In some embodiments, the first set of conductors of method 2100C & 2100B includes one or more portions of at least a conductor of interconnect 660a, 660b or 760b.

In some embodiments, the first set of conductors is electrically coupled to at least the first set of transistors by the first set of vias. In some embodiments, the first set of transistors is configured to receive a first word line signal on the first word line or a first cascode gate line signal on the first cascode gate line from the front-side.

In some embodiments, operation 2106 of method 2100C & 2100B is similar to method 2100A-2100B, and similar detailed description is omitted.

In operation 2108 of method 2100C & 2100B, a first interconnect structure is formed on the front-side 403a of the substrate.

In some embodiments, the first interconnect structure is coupled to at least the first set of dummy transistors.

In some embodiments, the first interconnect structure of method 2100C & 2100B includes one or more portions of at least interconnect 660a, 660b or 760b. In some embodiments, the first interconnect structure of method 2100C & 2100B includes one or more portions of elements in at least the V0, M1, V1, M2, V2, M3, V3 or M4.

In some embodiments, operation 2108 of method 2100C & 2100B is similar to method 2100A-2100B, and similar detailed description is omitted.

In operation 2112 of method 2100C & 2100B, thinning is performed on the back-side 403b of the wafer or substrate. In some embodiments, operation 2110 includes a thinning process performed on the back-side 403b of the semiconductor wafer or substrate.

In some embodiments, operation 2112 of method 2100C & 2100B is similar to method 2100A-2100B, and similar detailed description is omitted.

In operation 2114 of method 2100C & 2100B, a first set of back-side vias are formed through the back-side of the substrate to the front-side of the substrate on a BVD level or a BVG level (e.g., BVD or BVG).

In some embodiments, the first set of back-side vias of method 2100C & 2100B includes one or more portions of at least the set of vias 424 or 524.

In some embodiments, the first set of back-side vias of method 2100C & 2100B includes one or more portions of at least a via of interconnect 660a, 660b or 760b.

In some embodiments, the first set of back-side vias is electrically coupled to at least the first set of transistors or the first set of dummy transistors.

In some embodiments, operation 2114 includes forming a second set of self-aligned contacts (SACs) in the insulating layer through the back-side 403b of the wafer.

In some embodiments, operation 2114 of method 2100C & 2100B is similar to method 2100A-2100B, and similar detailed description is omitted.

In operation 2116 of method 2100C & 2100B, a second conductive material is deposited on the back-side 403b of the substrate on a second metal level thereby forming a second set of conductors on the back-side 403b of the wafer or substrate on a second metal level (e.g., BM0).

In some embodiments, operation 2116 includes at least depositing a second set of conductive regions over the back-side 403b of the integrated circuit. In some embodiments, the second set of conductors of method 2100C & 2100B includes one or more portions of at least the set of conductors 432, 434, 532, 632 or 1132.

In some embodiments, the second set of conductors is electrically coupled to the first set of transistors by the first set of back-side vias.

In some embodiments, operation 2116 of method 2100C & 2100B is similar to method 2100A-2100B, and similar detailed description is omitted.

In operation 2118b of method 2100C & 2100B, a second set of back-side vias are formed on the back-side of the substrate on a BV0 level or a BV1 or BV2 level.

In some embodiments, the second set of back-side vias of method 2100C & 2100B includes one or more portions of at least the set of vias 422.

In some embodiments, the second set of back-side vias is electrically coupled to at least the second set of conductors.

In some embodiments, operation 2118b includes forming a third set of self-aligned contacts (SACs) in the insulating layer on the back-side 403b of the wafer.

In operation 2110b of method 2100C & 2100B, a first set of storage elements is fabricated on the back-side of the substrate opposite from the front-side.

In some embodiments, first set of storage elements is fabricated on the BMx level.

In some embodiments, the first set of storage elements of method 2100C & 2100B includes a set of fuse elements or a set of capacitor elements. In some embodiments, the set of fuse elements includes metal fuse devices MF1_0 and MF1_1.

In some embodiments, the set of fuse elements includes the set of conductors 420 and are formed on the backside of the substrate.

In some embodiments, the set of capacitor elements includes one or more of capacitors 1912a, 1912b, 1914a, 1914b, 1916a, 1916b, 1918a or 1918b.

In some embodiments, the first set of fuse elements is coupled to the first and second set of back-side vias.

In operation 2140 of method 2100C & 2100B, a first set of interconnect structures is formed on the back-side 403b of the substrate.

In some embodiments, the first set of interconnect structures is coupled to at least the first set of dummy transistors.

In some embodiments, the first set of interconnect structures of method 2100A-2100B includes one or more portions of at least interconnect 460, 454a or 454b.

In operation 2117b of method 2100C & 2100B, a second set of transistors are fabricated on the back-side 403b of the semiconductor wafer 490 or substrate.

In some embodiments, the second set of transistors of method 2100C & 2100B includes one or more transistors of select device 452a, 452b, 1752a or 1752b. In some embodiments, the second set of transistors of method 2100C & 2100B includes one or more transistors described herein.

In some embodiments, the second set of transistors of method 2100C & 2100B includes memory circuit 2000.

In operation 2142 of method 2100C & 2100B, a third set of back-side vias are formed on the back-side of the substrate on a BVx level, where x is an integer greater than 0.

In some embodiments, the third set of back-side vias of method 2100C & 2100B includes one or more portions of at least the set of vias 464.

In some embodiments, the third set of back-side vias is electrically coupled to at least the set of fuse elements.

In some embodiments, operation 2142 includes forming a fourth set of self-aligned contacts (SACs) in the insulating layer on the back-side 403b of the wafer.

In operation 2119b of method 2100A-2100B, a third conductive material is deposited on the back-side 403b of the substrate on a third metal level thereby forming a third set of conductors on the back-side 403b of the wafer or substrate on a third metal level (e.g., BMx+1).

In some embodiments, operation 2119b includes at least depositing a third set of conductive regions over the back-side 403b of the integrated circuit. In some embodiments, the third set of conductors of method 2100A-2100B includes one or more portions of at least the set of conductors 462.

In some embodiments, the third set of conductors is electrically coupled to the second set of transistors by the third set of back-side vias.

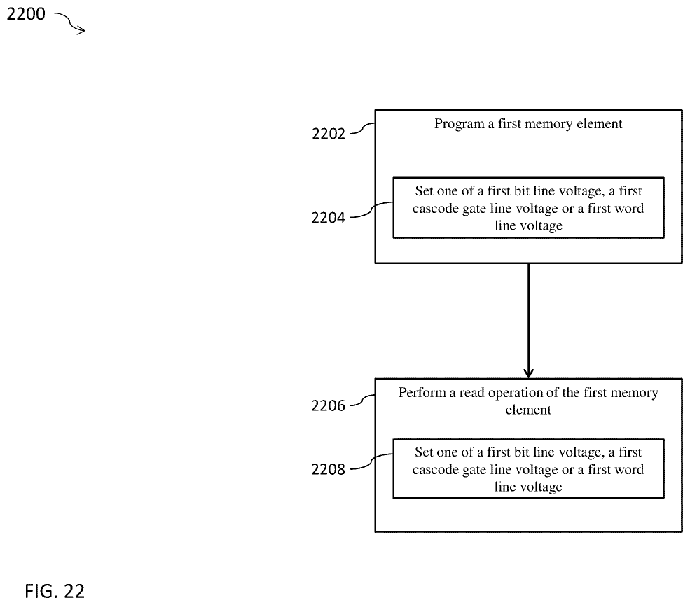

FIG. 22 is a functional flow chart of a method 2200 of a method of operating an IC device, in accordance with some embodiments.

It is understood that additional operations may be performed before, during, and/or after the method 2200 depicted in FIG. 22, and that some other processes may only be briefly described herein.

In some embodiments, the method 2200 is usable to operate one or more of memory device 100, memory cell array 200, 300, 802, 902, 1600 or 1900, memory cell 1000A, 1200A, 1300, 1400 or 1500 or memory circuit 400, 500, 600, 700, 1100, 1700, 1800 or 2000, or an integrated circuit with similar features.

In some embodiments, the method 2200 is usable to implement at least one of diagram 900 or 1100, and similar detailed description is therefore omitted.

In operation 2202 of method 2200, at least a first memory element is programmed.

In some embodiments, the first memory element includes one or more of metal fuse devices MF1_0 and MF1_1.

In some embodiments, the first memory element includes one or more of the set of conductors 420, 620 or 650.

In some embodiments, the first memory element includes one or more of capacitors 1912a, 1912b, 1914a, 1914b, 1916a, 1916b, 1918a or 1918b.

In some embodiments, the first memory element is programmed by applying a program word line voltage, a bit line voltage or a cascode gate line voltage sufficient to set the programming/resistance state of the first memory element.

In some embodiments, operation 2204 is an embodiment of operation 2202, and similar detailed description is therefore omitted.

In some embodiments, at least one of operation 2202 or 2204 is an embodiment of diagram 900, and similar detailed description is therefore omitted.

In some embodiments, at least one of operation 2202 or 2204 includes the details of diagram 900, and similar detailed description is therefore omitted.

In operation 2204 of method 2200, at least one of a first bit line voltage, a first cascode gate line voltage or a first word line voltage is set.

In some embodiments, the first bit line voltage includes a voltage of one or more of bit line BL0 or BL1.

In some embodiments, the first cascode gate line voltage includes a voltage of one or more of cascode gate line CG0 or CG1.

In some embodiments, the first word line voltage includes a voltage of one or more of word line WL0 or WL1.

In some embodiments, operation 2204 includes setting at least one of a first bit line voltage, a first cascode gate line voltage or a first word line voltage similar to the details of diagram 900, and similar detailed description is therefore omitted.

In operation 2206 of method 2200, at least a first memory element is read.

In some embodiments, the first memory element is read by applying a program word line voltage, a bit line voltage or a cascode gate line voltage sufficient to read the programming/resistance state of the first memory element.

In some embodiments, operation 2208 is an embodiment of operation 2206, and similar detailed description is therefore omitted.

In some embodiments, at least one of operation 2206 or 2208 is an embodiment of diagram 1100, and similar detailed description is therefore omitted.

In some embodiments, at least one of operation 2206 or 2208 includes the details of diagram 1100, and similar detailed description is therefore omitted.

In operation 2208 of method 2200, at least one of a first bit line voltage, a first cascode gate line voltage or a first word line voltage is set.

In some embodiments, operation 2208 includes setting at least one of a first bit line voltage, a first cascode gate line voltage or a first word line voltage similar to the details of diagram 1100, and similar detailed description is therefore omitted.

One aspect of this description relates to a memory circuit. In some embodiments, the memory circuit includes a first memory cell. In some embodiments, the first memory cell includes a first storage element on a back-side of a substrate opposite from a front-side of the substrate. In some embodiments, the first memory cell further includes a second storage element on the back-side of the substrate, and being separated from the first storage element in a first direction. In some embodiments, the first memory cell further includes a first selection transistor coupled to the first storage element. In some embodiments, the first memory cell further includes a second selection transistor coupled to the second storage element. In some embodiments, the first memory cell further includes a first word line transistor coupled to at least the first selection transistor or the second selection transistor, and being on the front-side of the substrate. In some embodiments, one of the first storage element or the second storage element is programmed during a programming operation, and another of the first storage element or the second storage element fails to be programmed during the programming operation.

Another aspect of this description relates to a memory circuit. In some embodiments, the memory circuit includes a first memory cell. In some embodiments, the first memory cell includes a first fuse element on a front-side of a substrate opposite from a back-side of the substrate. In some embodiments, the first memory cell further includes a second fuse element on the front-side of the substrate, and being separated from the first fuse element in a first direction. In some embodiments, the first memory cell further includes a first selection transistor coupled to the first fuse element. In some embodiments, the first memory cell further includes a second selection transistor coupled to the second fuse element. In some embodiments, the first memory cell further includes a first word line transistor coupled to at least the first selection transistor or the second selection transistor, and being on the front-side of the substrate. In some embodiments, one of the first fuse element or the second fuse element is programmed during a programming operation, and another of the first fuse element or the second fuse element fails to be programmed during the programming operation.

Still another aspect of this description relates to a method of fabricating a memory circuit. In some embodiments, the method includes fabricating a first set of transistors in a front-side of a substrate, the first set of transistors including a first word line transistor and a first set of dummy transistors. In some embodiments, the method further includes fabricating a first set of vias on the front-side of the substrate, the first set of vias being electrically coupled to at least the first set of transistors. In some embodiments, the method further includes depositing a first conductive material on the front-side of the substrate on a first metal level thereby forming a first set of conductors, the first set of conductors being electrically coupled to at least the first set of transistors by the first set of vias, the first set of conductors including a first word line or a first cascode gate line, the first set of transistors being configured to receive a first word line signal on the first word line or a first cascode gate line signal on the first cascode gate line from the front-side. In some embodiments, the method further includes fabricating a first interconnect structure on the front-side of the substrate, the first interconnect structure being coupled to at least the first set of dummy transistors. In some embodiments, the method further includes fabricating a first set of fuse elements on the front-side or a back-side of the substrate opposite from the front-side, the first set of fuse elements being coupled to the first set of transistors. In some embodiments, the method further includes performing thinning on the back-side of the substrate. In some embodiments, the method further includes fabricating a first set of back-side vias through the back-side of the substrate to the front-side of the substrate, the first set of back-side vias being electrically coupled to at least the first set of transistors. In some embodiments, the method further includes fabricating a second set of transistors in the back-side of the thinned substrate, the second set of transistors including a first selection transistor. In some embodiments, the method further includes depositing a second conductive material on the back-side of the substrate on a second metal level thereby forming a second set of conductors, the second set of conductors being electrically coupled to the second set of transistors, and to the first set of transistors by the first set of back-side vias. In some embodiments, the method further includes fabricating a second set of vias on the front-side of the substrate, the second set of vias being electrically coupled to at least the first set of conductors, depositing a third conductive material on the front-side of the substrate on a third metal level thereby forming a third set of conductors, the third set of conductors being electrically coupled to at least the first set of conductors by the second set of vias, fabricating a third set of vias on the front-side of the substrate, the third set of vias being electrically coupled to at least the third set of conductors, depositing a fourth conductive material on the front-side of the substrate on a fourth metal level thereby forming a fourth set of conductors, the fourth set of conductors being electrically coupled to at least the third set of conductors by the third set of vias, fabricating a fourth set of vias on the front-side of the substrate, the fourth set of vias being electrically coupled to at least the fourth set of conductors, depositing a fifth conductive material on the front-side of the substrate on a fifth metal level thereby forming a fifth set of conductors, the fifth set of conductors being electrically coupled to at least the fourth set of conductors by the fourth set of vias, fabricating a fifth set of vias on the front-side of the substrate, the fifth set of vias being electrically coupled to at least the fifth set of conductors, and depositing a sixth conductive material on the front-side of the substrate on a sixth metal level thereby forming a sixth set of conductors, the sixth set of conductors being electrically coupled to at least the fifth set of conductors by the fifth set of vias. In some embodiments, the method further includes depositing a fourth conductive material on the back-side of the substrate on a fourth metal level thereby forming a fourth set of conductors.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory circuit, comprising:
a first memory cell comprising:
a first storage element on a back-side of a substrate opposite from a front-side of the substrate;
a second storage element on the back-side of the substrate, and being separated from the first storage element in a first direction;
a first selection transistor coupled to the first storage element;
a second selection transistor coupled to the second storage element; and
a first word line transistor coupled to at least the first selection transistor or the second selection transistor, and being on the front-side of the substrate,
wherein one of the first storage element or the second storage element is programmed during a programming operation, and another of the first storage element or the second storage element fails to be programmed during the programming operation.

2. The memory circuit of claim 1, further comprising:
a first bit line coupled to the first storage element and the second storage element;
a first cascode gate line coupled to the first selection transistor;
a second cascode gate line coupled to the second selection transistor; and
a first word line coupled to the first word line transistor.

3. The memory circuit of claim 2, wherein
the first storage element comprises:
a first capacitor element; and
the second storage element comprises:
a second capacitor element.

4. The memory circuit of claim 2, wherein
the first storage element comprises:
a first fuse element; and
the second storage element comprises:
a second fuse element.

5. The memory circuit of claim 4, wherein
the first fuse element comprises:
a first resistor; and
the second fuse element comprises:
a second resistor.

6. The memory circuit of claim 5, wherein
the first fuse element is on a first metal layer below the substrate; and
the second fuse element is on the first metal layer.

7. The memory circuit of claim 6, further comprising:
a second word line transistor coupled to the second selection transistor, and being on the front-side of the substrate,
wherein the first word line transistor is coupled to the first selection transistor;
the first selection transistor is between the first word line transistor and the first fuse element; and
the second selection transistor is between the second word line transistor and the second fuse element.

8. The memory circuit of claim 7, wherein
the first selection transistor is on the back-side of the substrate; and
the second selection transistor is on the back-side of the substrate.

9. The memory circuit of claim 8, further comprising:
a first via extending in a second direction different from the first direction and through the substrate, and electrically coupling the first selection transistor and the first word line transistor together; and
a second via extending in the second direction and through the substrate, and electrically coupling the second selection transistor and the second word line transistor together.

10. A memory circuit, comprising:
a first memory cell comprising:
a first fuse element on a front-side of a substrate opposite from a back-side of the substrate;
a second fuse element on the front-side of the substrate, and being separated from the first fuse element in a first direction;
a first selection transistor coupled to the first fuse element;
a second selection transistor coupled to the second fuse element; and
a first word line transistor coupled to at least the first selection transistor or the second selection transistor, and being on the front-side of the substrate,
wherein one of the first fuse element or the second fuse element is programmed during a programming operation, and another of the first fuse element or the second fuse element fails to be programmed during the programming operation.

11. The memory circuit of claim 10, further comprising:
a first bit line coupled to the first fuse element and the second fuse element;
a first cascode gate line coupled to the first selection transistor;
a second cascode gate line coupled to the second selection transistor; and
a first word line coupled to the first word line transistor.

12. The memory circuit of claim 11, wherein
the first fuse element comprises:
a first resistor; and
the second fuse element comprises:
a second resistor.

13. The memory circuit of claim 11, wherein
the first fuse element is on a first metal layer above the substrate; and
the second fuse element is on the first metal layer.

14. The memory circuit of claim 11, wherein
the first fuse element is on a first metal layer above the substrate; and
the second fuse element is on a second metal layer above the first metal layer.

15. The memory circuit of claim 11, wherein
the first selection transistor is on the back-side of the substrate; and
the second selection transistor is on the back-side of the substrate.

16. The memory circuit of claim 15, further comprising:
a first interconnect extending in a second direction different from the first direction and through the substrate, and electrically coupling the first fuse element and the first selection transistor together; and
a second interconnect extending in the second direction and through the substrate, and electrically coupling the second fuse element and the second selection transistor together.

17. The memory circuit of claim 11, further comprising:
a second word line transistor coupled to the second selection transistor;
wherein the first word line transistor is coupled to the first selection transistor;
the first selection transistor is between the first word line transistor and the first fuse element; and
the second selection transistor is between the second word line transistor and the second fuse element.

18. The memory circuit of claim 17, further comprising:
a first interconnect extending in a second direction different from the first direction and through the substrate, and electrically coupling the first fuse element and the first selection transistor together; and
a second interconnect extending in the second direction and through the substrate, and electrically coupling the second fuse element and the second selection transistor together, wherein the second word line transistor is on the front-side of the substrate.

19. The memory circuit of claim 17, wherein
the second word line transistor is on the back-side of the substrate,
the first selection transistor is on the front-side of the substrate; and
the second selection transistor is on the back-side of the substrate.

20. A method of fabricating a memory circuit, the method comprising:
fabricating a first set of transistors in a front-side of a substrate, the first set of transistors including a first word line transistor and a first set of dummy transistors;
fabricating a first set of vias on the front-side of the substrate, the first set of vias being electrically coupled to at least the first set of transistors;
depositing a first conductive material on the front-side of the substrate on a first metal level thereby forming a first set of conductors, the first set of conductors being electrically coupled to at least the first set of transistors by the first set of vias, the first set of conductors including a first word line or a first cascode gate line, the first set of transistors being configured to receive a first word line signal on the first word line or a first cascode gate line signal on the first cascode gate line from the front-side;
fabricating a first interconnect structure on the front-side of the substrate, the first interconnect structure being coupled to at least the first set of dummy transistors;
fabricating a first set of fuse elements on the front-side of the substrate, the first set of fuse elements being coupled to the first set of transistors;
performing thinning on a back-side of the substrate opposite from the front-side;
fabricating a first set of back-side vias through the back-side of the substrate to the front-side of the substrate, the first set of back-side vias being electrically coupled to at least the first set of transistors;
depositing a second conductive material on the back-side of the substrate on a second metal level thereby forming a second set of conductors, the second set of conductors being electrically coupled to the first set of transistors by the first set of back-side vias; and
fabricating a second set of transistors on the back-side of the thinned substrate, the second set of transistors including a first selection transistor, the second set of transistors being electrically coupled to the second set of conductors.
